(19) United States
(12) Patent Application Publication
(10) Pub. No.: US 2024/0400892 A1
(43) Pub. Date: Dec. 5, 2024

(54) BORONIC HETEROCYCLIC COMPOUNDS FOR ORGANIC ELECTROLUMINESCENT DEVICES

(71) Applicant: Merck Patent GmbH, Darmstadt (DE)

(72) Inventor: Philipp STOESSEL, Darmstadt (DE)

(21) Appl. No.: 18/691,474

(22) PCT Filed: Sep. 12, 2022
(86) PCT No.: PCT/EP2022/075198

§ 371 Date: Mar. 13, 2024

(30) Foreign Application Priority Data
Sep. 14, 2021 (EP) 21196594.2

(51) Int. Cl. C09K 11/06

(52) U.S. Cl. CPC C09K 11/06; C09K 2211/1022; C09K 2211/1055

(57) ABSTRACT

The present invention relates to boronic heterocyclic compounds, which are suitable for use in electronic devices, and to electronic devices, in particular organic electroluminescent devices, containing said compounds.

The present invention relates to boron-containing heterocyclic compounds for use in electronic devices, especially in organic electroluminescent devices, and to electronic devices, especially organic electroluminescent devices comprising these heterocyclic compounds.

Emitting materials used in organic electroluminescent devices are frequently phosphorescent organometallic complexes or fluorescent compounds. There is generally still a need for improvement in electroluminescent devices.

U.S. Pat. No. 6,322,908 and WO 03/001569 A2 disclose polycyclic compounds that can be used in organic electroluminescent devices. There is no disclosure of compounds according to the present invention.

In general terms, there is still a need for improvement in these nitrogen-containing heterocyclic compounds, for example for use as emitters, especially as fluorescent emitters, particularly in relation to lifetime and color purity, but also in relation to the efficiency and operating voltage of the device.

It is therefore an object of the present invention to provide compounds which are suitable for use in an organic electronic device, especially in an organic electroluminescent device, and which lead to good device properties when used in this device, and to provide the corresponding electronic device.

More particularly, the object addressed by the present invention is that of providing compounds which lead to a high lifetime, good efficiency and low operating voltage.

In addition, the compounds should have excellent processability, and the compounds should especially show good solubility.

A further object of the present invention can be considered that of providing compounds suitable for use in phosphorescent or fluorescent electroluminescent devices, especially as emitter. A particular object of the present invention is that of providing emitters suitable for red, green or blue electroluminescent devices.

In addition, the compounds, especially when they are used as emitters in organic electroluminescent devices, should lead to devices having excellent color purity.

A further object of the present invention can be considered that of providing compounds suitable for use in phosphorescent or fluorescent electroluminescent devices, especially as a matrix material. A particular object of the present invention is that of providing matrix materials suitable for red-, yellow- and blue-phosphorescing electroluminescent devices.

In addition, the compounds, especially when they are used as matrix materials or as electron transport materials in organic electroluminescent devices, should lead to devices having excellent color purity.

A further object can be considered that of providing electronic devices having excellent performance very inexpensively and in constant quality.

Furthermore, it should be possible to use or adapt the electronic devices for many purposes. More particularly, the performance of the electronic devices should be maintained over a broad temperature range.

It has been found that, surprisingly, this object is achieved by particular compounds described in detail below that are of very good suitability for use in preferably electroluminescent devices and lead to organic electroluminescent devices that show very good properties, especially in relation to lifetime, color purity, efficiency and operating voltage. The present invention therefore provides these compounds and electronic devices, especially organic electroluminescent devices, comprising such compounds.

The present invention provides a compound comprising at least one structure of the formula (I), preferably a compound of the formula (I),

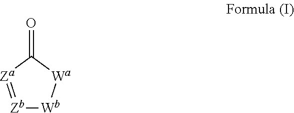

where the symbols used are as follows:
Z^{a}, Z^{b} is the same or different at each instance and is N, CR, or the Z^{a}, Z^{b} groups form a ring Ar^{a}, where the ring Ar^{a} is the same or different at each instance and is an aromatic or heteroaromatic ring system which has 5 to 60 aromatic ring atoms and may be substituted by one or more Ar or R^{a} radicals, where the ring Ar^{a} together with the CO group and the W^{a}, W^{b} groups forms a 5-membered ring;
W^{a}, W^{b} is the same or different at each instance and is NR, NAr, NB(R)₂ or NB(Ar)₂, where exactly one of the W^{a}, W^{b} groups is NB(R)₂, NB(Ar)₂, and exactly one of the W^{a}, W^{b} groups is NR, NAr, or the W^{a}, W^{b} groups form a ring of the formula

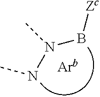

where Z^{c} is R or Ar, the ring Ar^{b} is the same or different at each instance and is an aromatic or heteroaromatic ring system which has 5 to 60 aromatic ring atoms and may be substituted by one or more Ar or R^{b} radicals, where the ring Ar^{b} may form a ring system with an R, Ar or Z^{c} group or the rings Ar^{a} and Ar^{b} together may form a ring system, and the dotted lines represent the bonds to the CO group or Z^{b} group;
Ar is the same or different at each instance and is an aromatic or heteroaromatic ring system which has 5 to 60 aromatic ring atoms and may be substituted by one or more R radicals; the Ar group here may form a ring system with at least one Ar, R, R^{a}, R^{b} group or a further group;
R, R^{a}, R^{b} is the same or different at each instance and is H, D, OH, F, CI, Br, I, CN, NO₂, N(Ar′)₂, N(R¹)₂, C(═O)N(Ar′)₂, C(═O)N(R¹)₂, C(Ar′)₃, C(R¹)₃, Si(Ar′)₃, Si(R¹)₃, B(Ar′)₂, B(R¹)₂, C(═O)Ar′, C(═O)R¹, P(═O)(Ar′)₂, P(═O)(R¹)₂, P(Ar′)₂, P(R¹)₂, S(═O)Ar′, S(═O)R¹, S(═O)₂Ar′, S(═O)₂R¹, OSO₂Ar′, OSO₂R¹, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 20 carbon atoms, where the alkyl, alkoxy, thioalkoxy, alkenyl or alkynyl group may in each case be substituted by one or more R¹ radicals, where one or more nonadjacent CH₂ groups may be replaced by R¹C═CR¹, C═C, Si(R¹)₂, C═O, C═S, C═Se, C═NR¹, —C(═O)O—, —C(═O)NR¹—, NR¹, P(═O)(R¹), —O—, —S—, SO or SO₂, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals; or heteroarylthio group which has 5 to 60 aromatic ring atoms and may be substituted by one or more R¹ radicals, or a diarylamino, arylheteroarylamino, diheteroarylamino group which has 5 to 60 aromatic ring atoms and may be substituted by one or more R¹ radicals, or an aralkyl or heteroarylalkyl group which has 5 to 60 aromatic ring atoms and 1 to 10 carbon atoms and the alkyl radical and may be substituted by one or more R¹ radicals; at the same time, two R, R^{a}, R^{b} radicals together or with a further group may also form a ring system;
Ar′ is the same or different at each instance and is an aromatic or heteroaromatic ring system which has 5 to 60 aromatic ring atoms and may be substituted by one or more R¹ radicals; at the same time, it is possible for two Ar′ radicals bonded to the same carbon atom, silicon atom, nitrogen atom, phosphorus atom or boron atom also to be joined together via a bridge by a single bond or a bridge selected from B(R¹), C(R¹)₂, Si(R¹)₂, C═O, C═NR¹, C═C(R¹)₂, O, S, S═O, SO₂, N(R¹), P(R¹) and P(═O)R¹;
R¹ is the same or different at each instance and is H, D, F, Cl, Br, I, CN, NO₂, N(Ar″)₂, N(R²)₂, C(═O)Ar″, C(═O)R², P(═O)(Ar″)₂, P(Ar″)₂, B(Ar″)₂, B(R²)₂, C(Ar″)₃, C(R²)₃, Si(Ar″)₃, Si(R²)₃, a straight-chain alkyl, alkoxy or thioalkoxy group having 1 to 40 carbon atoms or a branched or cyclic alkyl, alkoxy or thioalkoxy group having 3 to 40 carbon atoms or an alkenyl group having 2 to 40 carbon atoms, each of which may be substituted by one or more R² radicals, where one or more nonadjacent CH₂ groups may be replaced by —R²C═CR²—, —C═C—, Si(R²)₂, C═O, C═S, C═Se, C═NR², —C(═O)O—, —C(═O)NR²—, NR², P(═O)(R²), —O—, —S—, SO or SO₂ and where one or more hydrogen atoms may be replaced by D, F, Cl, Br, I, CN or NO₂, or an aromatic or heteroaromatic ring system which has 5 to 60 aromatic ring atoms, each of which may be substituted by one or more R² radicals, or an aryloxy or heteroaryloxy group which has 5 to 60 aromatic ring atoms and may be substituted by one or more R² radicals, or an aralkyl or heteroaralkyl group which has 5 to 60 aromatic ring atoms and may be substituted by one or more R² radicals, or a combination of these systems; at the same time, two or more, preferably adjacent R¹ radicals together may form a ring system; at the same time, one or more R¹ radicals may form a ring system with a further part of the compound;
Ar″ is the same or different at each instance and is an aromatic or heteroaromatic ring system which has 5 to 30 aromatic ring atoms and may be substituted by one or more R² radicals; at the same time, it is possible for two Ar″ radicals bonded to the same carbon atom, silicon atom, nitrogen atom, phosphorus atom or boron atom also to be joined together via a bridge by a single bond or a bridge selected from B(R²), C(R²)₂, Si(R²)₂, C═O, C═NR², C═C(R²)₂, O, S, S═O, SO₂, N(R²), P(R²) and P(═O)R²;
R² is the same or different at each instance and is selected from the group consisting of H, D, F, CN, an aliphatic hydrocarbyl radical having 1 to 20 carbon atoms or an aromatic or heteroaromatic ring system which has 5 to 30 aromatic ring atoms and in which one or more hydrogen atoms may be replaced by D, F, Cl, Br, I or CN and which may be substituted by one or more alkyl groups each having 1 to 4 carbon atoms; at the same time, two or more, preferably adjacent substituents R² together may form a ring system.

Preference is given here to structures/compounds of formula (I) that have an Ar^{b} group, where the W^{a}, W^{b} groups more preferably form a ring of the formula

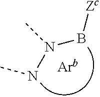

where the symbols Ar^{b} and Z^{c} have the definition given above, where Z^{c} is preferably Ar.

The ring Ar^{b} is the same or different at each instance and is an aromatic or heteroaromatic ring system which has 5 to 60, preferably 5 to 50, aromatic ring atoms and may be substituted by one or more Ar or R^{b} radicals, where the ring Ar^{b} may form a ring system with an R, Ar or Z^{c} group or the rings Ar^{a} and Ar^{b} together may form a ring system, and the dotted lines represent the bonds to the CO group or Z^{b} group. It should be remembered here that the Ar^{b} ring in the above formula has two nitrogen atoms and one boron atom. Therefore, the expression “aromatic ring system having 5 to 60 aromatic ring atoms” makes it clear that significant parts of the ring Ar^{b} need not have any heteroatoms, and that the constituents not mentioned explicitly may constitute an aromatic ring system having 5 to 60 aromatic ring atoms. It may accordingly be the case that the ring Ar^{b} has one Ar^{b} group, and also two nitrogen atoms and one boron atom. The Ar^{b} group is the same or different at each instance and is an aromatic or heteroaromatic ring system which has 5 to 50 aromatic ring atoms and may be substituted by one or more Ar or R^{b} radicals, where the Ar^{b} group may form a ring system with an R, Ar or Z^{c} group or the ring Ar^{a} and the Ar^{b} group together may form a ring system. Preferably, the ring Ar^{b} is formed by an Ar^{b} group and the two nitrogen atoms and the boron atom, where this ring formed by the Ar^{b} group and the two nitrogen atoms and the boron atom preferably comprises five to eight, more preferably five or six, ring atoms. The Ar^{b} group preferably binds to the further atoms of the ring formed by the Ar^{b} group and the two nitrogen atoms and the boron atom via two adjacent carbon atoms that are part of an aromatic or heteroaromatic group. If the ring formed by the Ar^{b} group and the two nitrogen atoms and the boron atom comprises more than 5 ring atoms, the further radicals may be regarded as part of the Ar^{b} group that does not necessarily contain solely aryl or heteroaryl groups.

An aryl group in the context of this invention contains 6 to 40 carbon atoms; a heteroaryl group in the context of this invention contains 2 to 40 carbon atoms and at least one heteroatom, with the proviso that the sum total of carbon atoms and heteroatoms is at least 5. The heteroatoms are preferably selected from N, O and/or S. An aryl group or heteroaryl group is understood here to mean either a simple aromatic cycle, i.e. benzene, or a simple heteroaromatic cycle, for example pyridine, pyrimidine, thiophene, etc., or a fused (annelated) aryl or heteroaryl group, for example naphthalene, anthracene, phenanthrene, quinoline, isoquinoline, etc. Aromatics joined to one another by a single bond, for example biphenyl, by contrast, are not referred to as an aryl or heteroaryl group but as an aromatic ring system.

An electron-deficient heteroaryl group in the context of the present invention is a heteroaryl group having at least one heteroaromatic six-membered ring having at least one nitrogen atom. Further aromatic or heteroaromatic five-membered or six-membered rings may be fused onto this six-membered ring. Examples of electron-deficient heteroaryl groups are pyridine, pyrimidine, pyrazine, pyridazine, triazine, quinoline, quinazoline or quinoxaline.

An aromatic ring system in the context of this invention contains 6 to 60 carbon atoms in the ring system. A heteroaromatic ring system in the context of this invention contains 2 to 60 carbon atoms and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for two or more aryl or heteroaryl groups to be joined by a non-aromatic unit, for example a carbon, nitrogen or oxygen atom. For example, systems such as fluorene, 9,9′-spirobifluorene, 9,9-diarylfluorene, triarylamine, diaryl ethers, stilbene, etc. shall also be regarded as aromatic ring systems in the context of this invention, and likewise systems in which two or more aryl groups are joined, for example, by a short alkyl group. Preferably, the aromatic ring system is selected from fluorene, 9,9′-spirobifluorene, 9,9-diarylamine or groups in which two or more aryl and/or heteroaryl groups are joined to one another by single bonds.

In the context of the present invention, an aliphatic hydrocarbyl radical or an alkyl group or an alkenyl or alkynyl group which may contain 1 to 20 carbon atoms and in which individual hydrogen atoms or CH₂ groups may also be substituted by the abovementioned groups is preferably understood to mean the methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl radicals. An alkoxy group having 1 to 40 carbon atoms is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy and 2,2,2-trifluoroethoxy. A thioalkyl group having 1 to 40 carbon atoms is understood to mean especially methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio. In general, alkyl, alkoxy or thioalkyl groups according to the present invention may be straight-chain, branched or cyclic, where one or more nonadjacent CH₂ groups may be replaced by the abovementioned groups; in addition, it is also possible for one or more hydrogen atoms to be replaced by D, F, Cl, Br, I, CN or NO₂, preferably F, Cl or CN, further preferably F or CN, especially preferably CN.

An aromatic or heteroaromatic ring system which has 5-60 or 5-40 aromatic ring atoms and may also be substituted in each case by the abovementioned radicals and which may be joined to the aromatic or heteroaromatic system via any desired positions is understood to mean especially groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or groups derived from combinations of these systems.

The wording that two or more radicals together may form a ring, in the context of the present description, should be understood to mean, inter alia, that the two radicals are joined to one another by a chemical bond with formal elimination of two hydrogen atoms. This is illustrated by the following scheme:

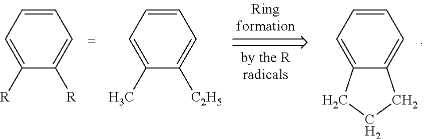

In addition, however, the abovementioned wording shall also be understood to mean that, if one of the two radicals is hydrogen, the second radical binds to the position to which the hydrogen atom was bonded, forming a ring. This will be illustrated by the following scheme:

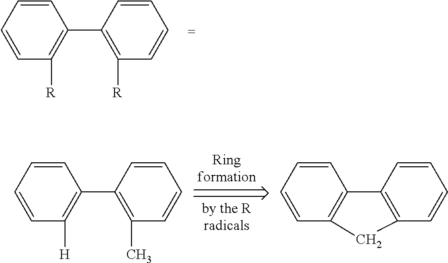

In a preferred configuration, the compounds of the invention may comprise a structure of the formulae (II-1) to (II-18); more preferably, the compounds of the invention may be selected from the compounds of the formulae (II-1) to (II-18):

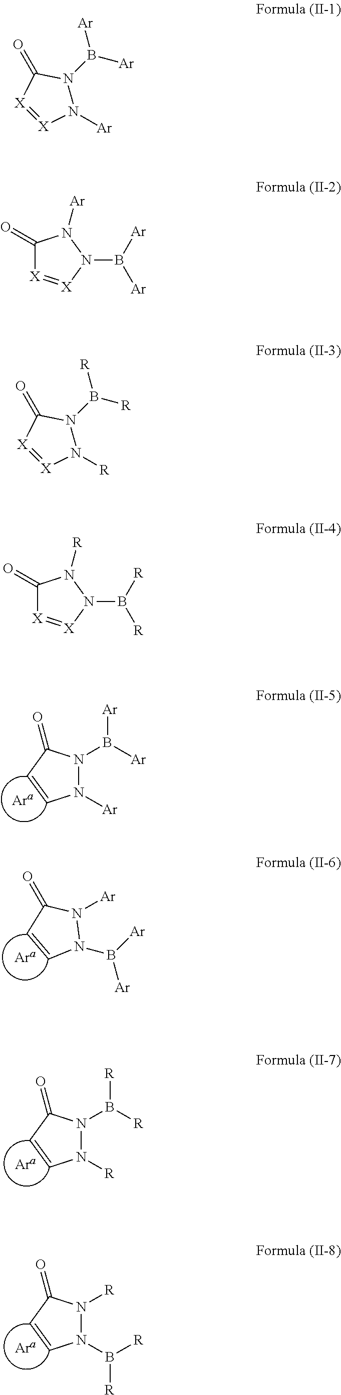

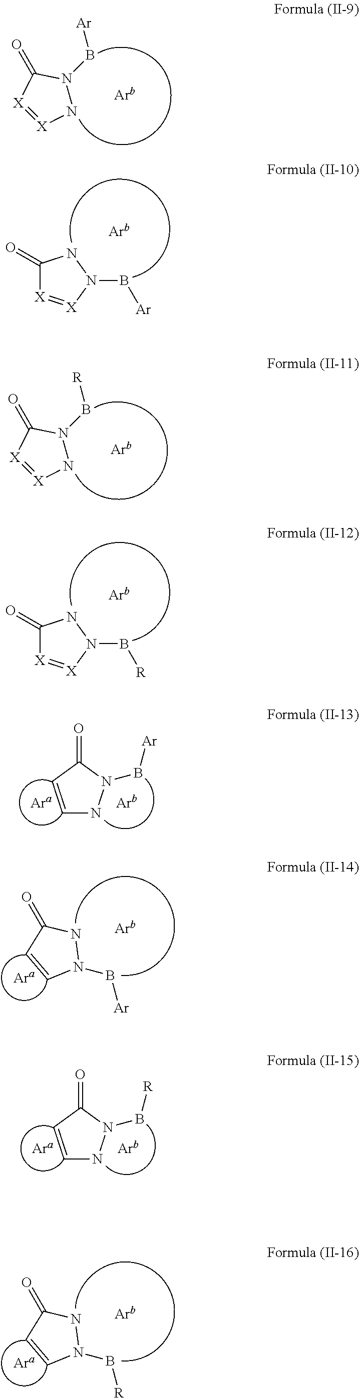

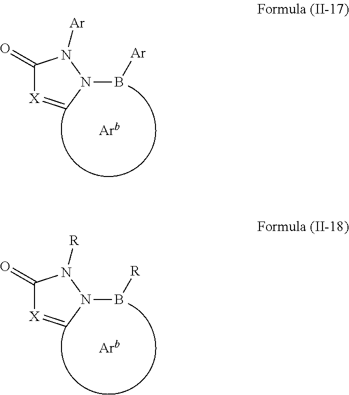

where the symbols R, Ar, Ar^{a} and Ar^{b} have the definitions given above, especially for formula (I), and X is the same or different at each instance and is N or CR, preferably CR. In formulae (II-17) and (II-18), the ring Ar^{b} is preferably formed by an Ar^{b} group, the nitrogen atom, the boron atom and the carbon atom, where the further preferences for this ring correspond to those detailed above.

Preference is given here to structures/compounds of the formulae (II-5) to (II-16), particular preference to structures/compounds of the formulae (II-9) to (II-16), especial preference to structures/compounds of the formulae (II-13) to (II-16), and very especial preference to structures/compounds of the formulae (II-13) and (II-14).

In addition, structures/compounds of the formulae (II-1), (II-3), (II-5), (II-7), (II-9), (II-11), (II-13) and (II-15) are preferred over comparable structures/compounds of the formulae (II-2), (II-4), (II-6), (II-8), (II-10), (II-12), (II-14) and (II-16). Structures or compounds are comparable especially when substituents and/or substitution patterns are essentially the same, “essentially the same” meaning “apart from the position of the carbonyl group relative to the boron atom”. This preference is also applicable to the structures and/or compounds shown below, unless stated otherwise.

If two or more nitrogen atoms are present in a compound, these nitrogen atoms are preferably not adjacent, such that there are no N—N bonds apart from the N—N bond in formula (I) or the preferred embodiments of that structure/compound shown above and hereinafter.

In a further preferred embodiment, it may be the case that the compounds of the invention include a structure of the formulae (III-1) to (III-48), where the compounds of the invention may more preferably be selected from the compounds of the formulae (III-1) to (III-48)

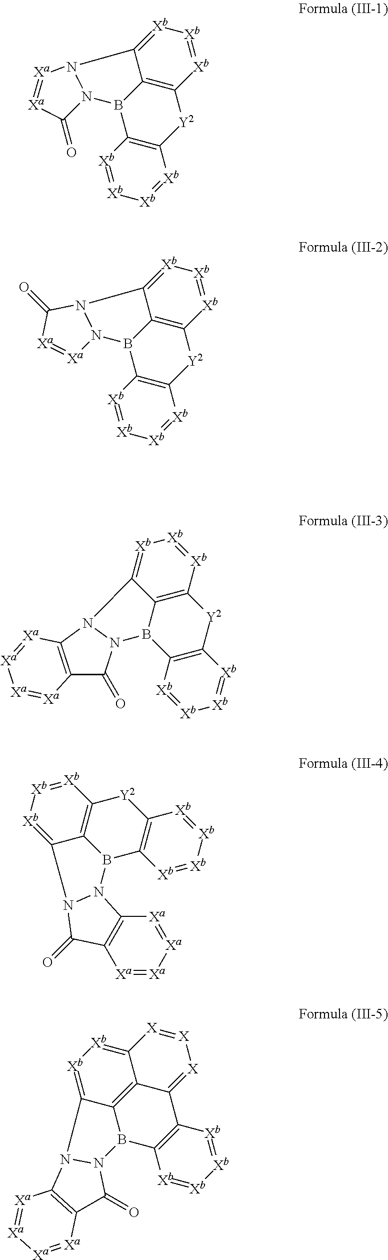

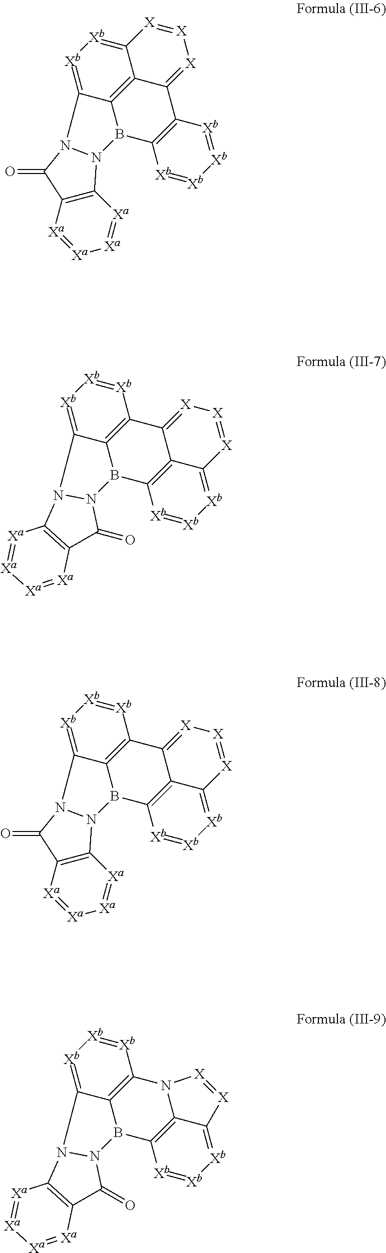

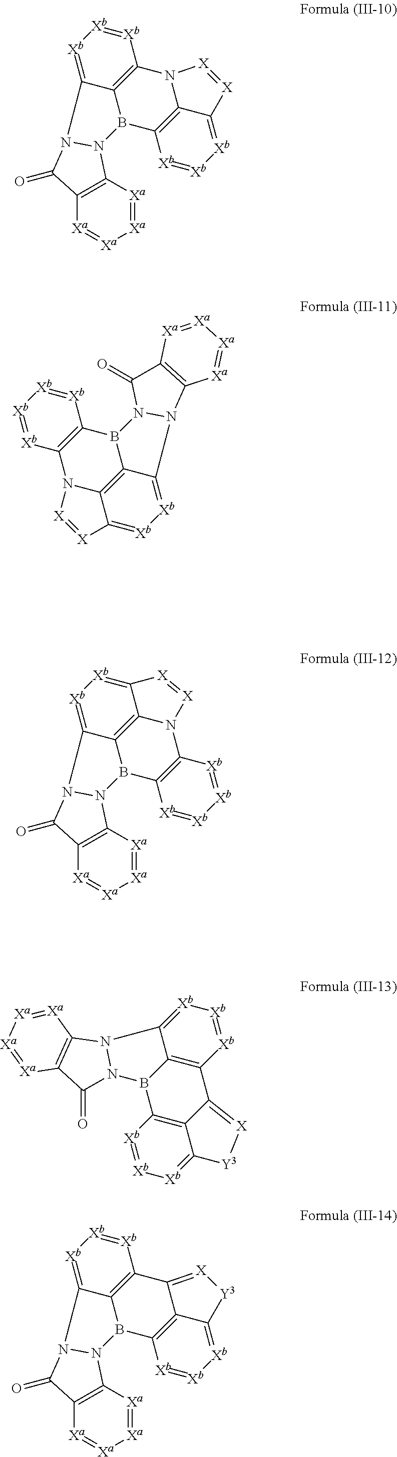

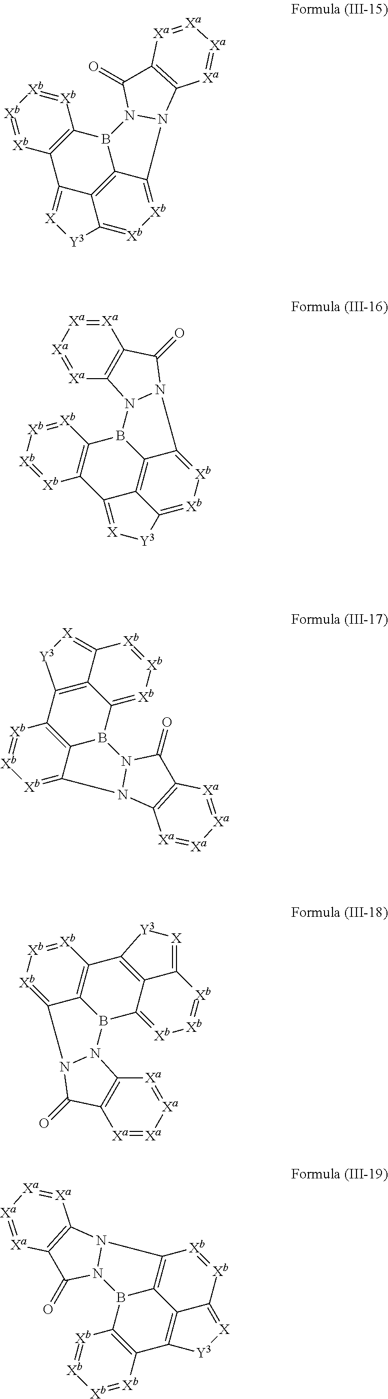

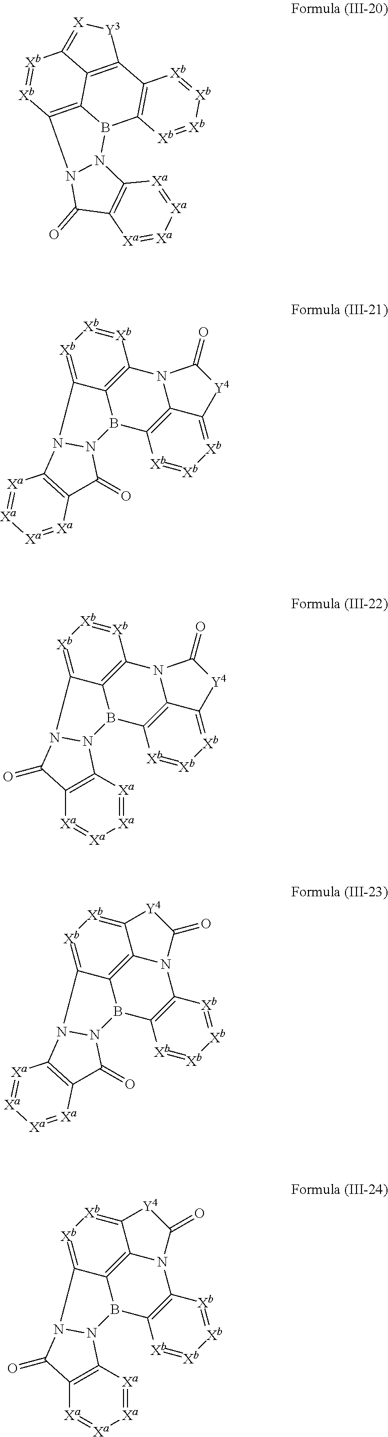

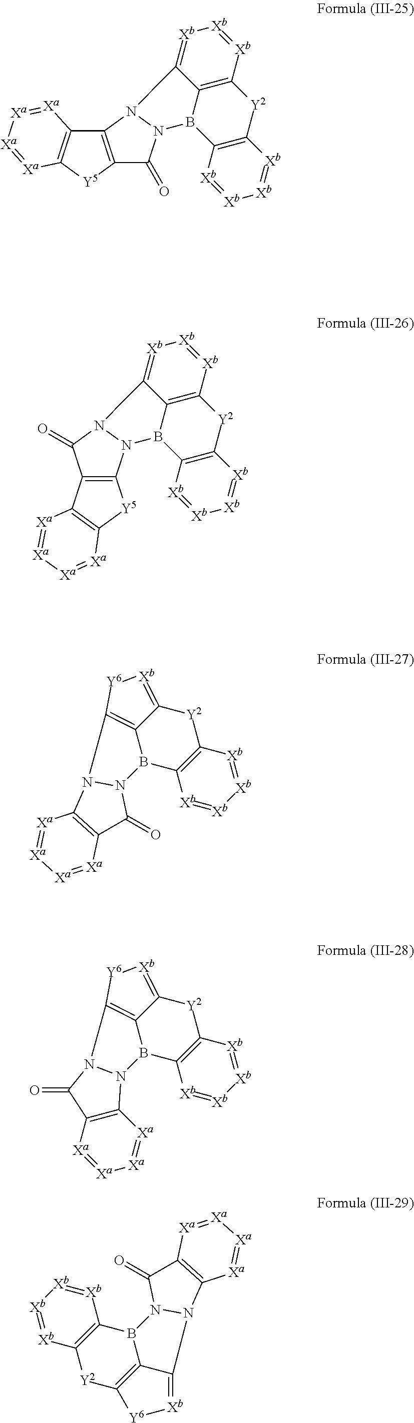

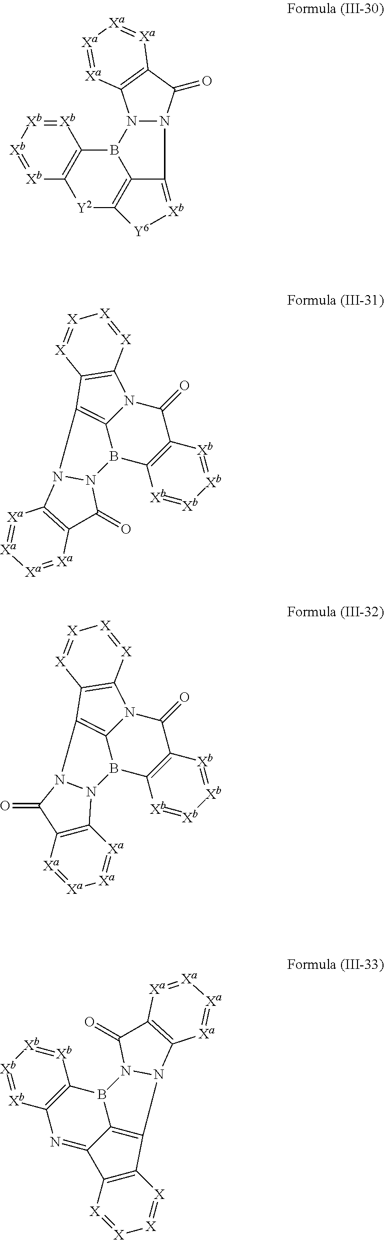

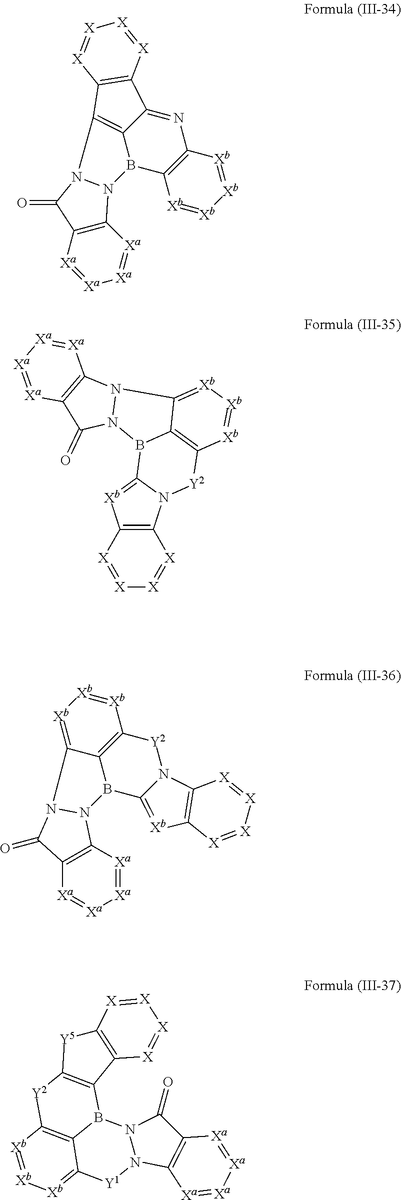

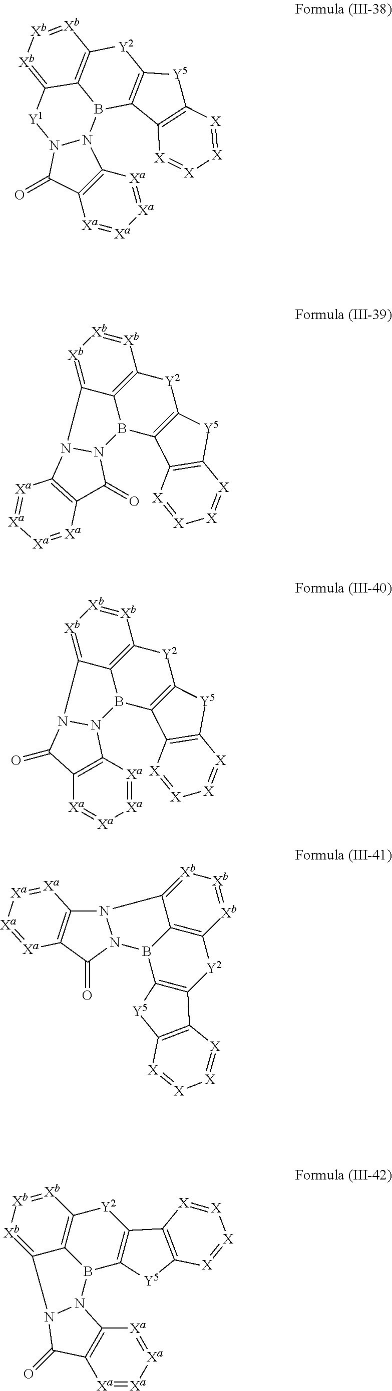

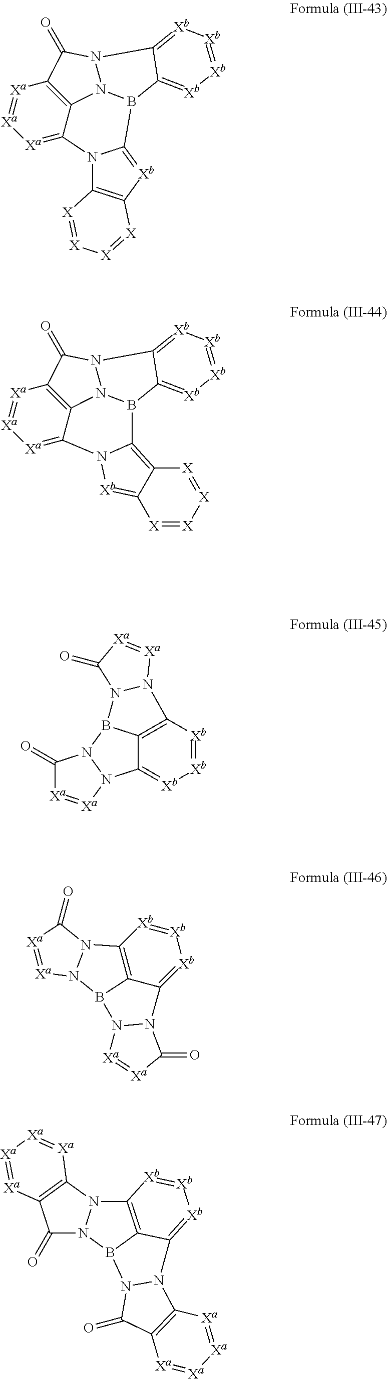

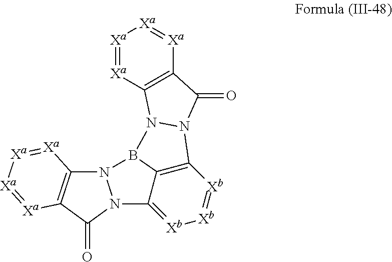

where the symbols Ar and R have the definitions detailed above, especially for formula (I), and the further symbols are as follows:
X is the same or different at each instance and is N or CR, preferably CR, with the proviso that not more than two of the X groups in one cycle are N, where R has the definition detailed above, especially for formula (I);
X^{a} is the same or different at each instance and is N or CR^{a}, preferably CR^{a}, with the proviso that not more than two of the X^{a} groups in one cycle are N, where R^{a} has the definition detailed above, especially for formula (I);
X^{b} is the same or different at each instance and is N or CR^{b}, preferably CR^{b}, with the proviso that not more than two of the X^{b} groups in one cycle are N, where R^{b} has the definition detailed above, especially for formula (I);
Y¹ is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O or SO₂, preferably a bond, N(Ar), N(R), B(Ar), B(R), P(═O)R, P(═O)Ar, C═O, C(R)₂, C═C(R)₂, C═C(R)(Ar), Si(R)₂, O, S, Se, S═O or SO₂, more preferably N(Ar), B(Ar), B(R), C(R)₂, C═O, O or S, where R has the definition detailed above, especially for formula (I);
Y² is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O or SO₂, preferably a bond, N(Ar), N(R), B(Ar), B(R), P(═O)R, P(═O)Ar, C═O, C(R)₂, C═C(R)₂, C═C(R)(Ar), Si(R)₂, O, S, Se, S═O or SO₂, more preferably N(Ar), C(R)₂, O or S, where R has the definition detailed above, especially for formula (I);
Y³ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O or SO₂, preferably N(Ar), N(R), B(Ar), B(R), P(═O)R, P(═O)Ar, C═O, C(R)₂, C═C(R)₂, C═C(R)(Ar), Si(R)₂, O, S, Se, S═O or SO₂, more preferably N(Ar), C(R)₂, O or S, where R has the definition detailed above, especially for formula (I);
Y⁴ is the same or different at each instance and is N(Ar), N(R), P(Ar), P(R), P(═O)Ar, P(═O)R, P(═S)Ar, P(═S)R, C(R)₂, Si(R)₂, O or S, preferably N(Ar), N(R) or O, S, more preferably N(Ar) or O, where R has the definition detailed above, especially for formula (I);
Y⁵ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O or SO₂, preferably N(Ar), N(R), B(Ar), B(R), P(═O)R, P(═O)Ar, C═O, C(R)₂, C═C(R)₂, C═C(R)(Ar), Si(R)₂, O, S, Se, S═O or SO₂, more preferably N(Ar), C(R)₂, O or S, where R has the definition detailed above, especially for formula (I);
Y⁶ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O or SO₂, preferably N(Ar), N(R), B(Ar), B(R), P(═O)R, P(═O)Ar, C═O, C(R)₂, C═C(R)₂, C═C(R)(Ar), Si(R)₂, O, S, Se, S═O or SO₂, more preferably N(Ar), C(R)₂, O or S, where R has the definition detailed above, especially for formula (I).

Preference is given here to structures/compounds of the formulae (III-3) to (III-14), (III-17) to (III-26), (III-47) and (III-48), particular preference to structures of the formulae (III-3), (III-5), (III-7), (III-9), (III-11), (III-13), (III-17), (III-19), (III-21), (III-23), (III-25) and (III-47).

It may preferably be the case, especially in formulae (III-1) to (III-48), that not more than four and preferably not more than two X, X^{a} and X^{b} groups are N; more preferably, all X, X^{a} and X^{b} groups are CR, CR^{a} or CR^{b}.

In a further preferred embodiment, it may be the case that the compounds of the invention include a structure of the formulae (IV-1) to (IV-48), where the compounds of the invention may more preferably be selected from the compounds of the formulae (IV-1) to (IV-48)

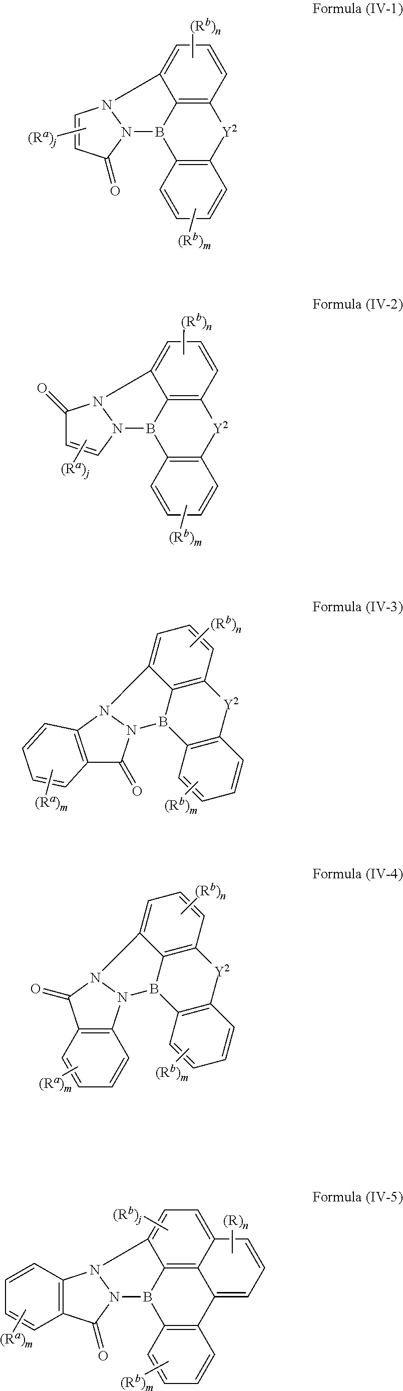

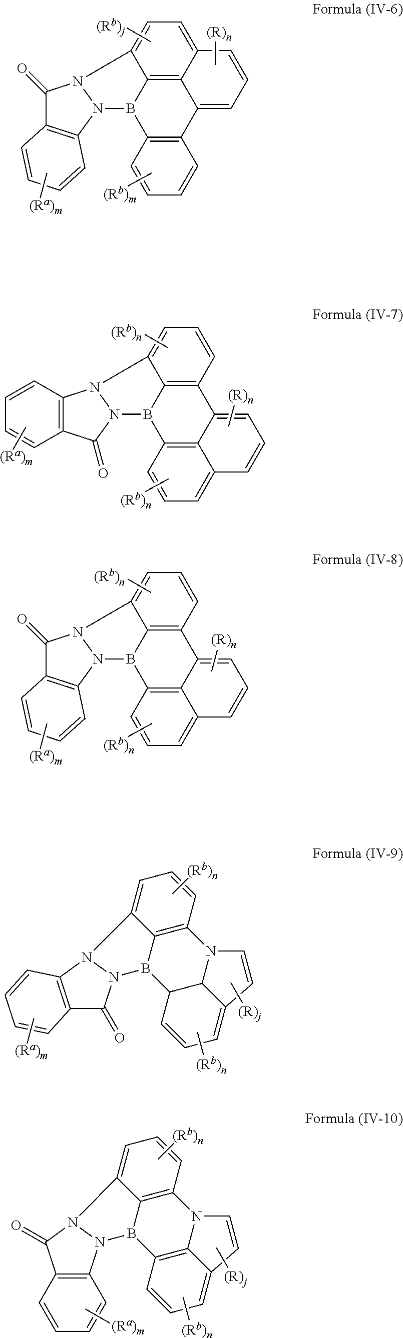

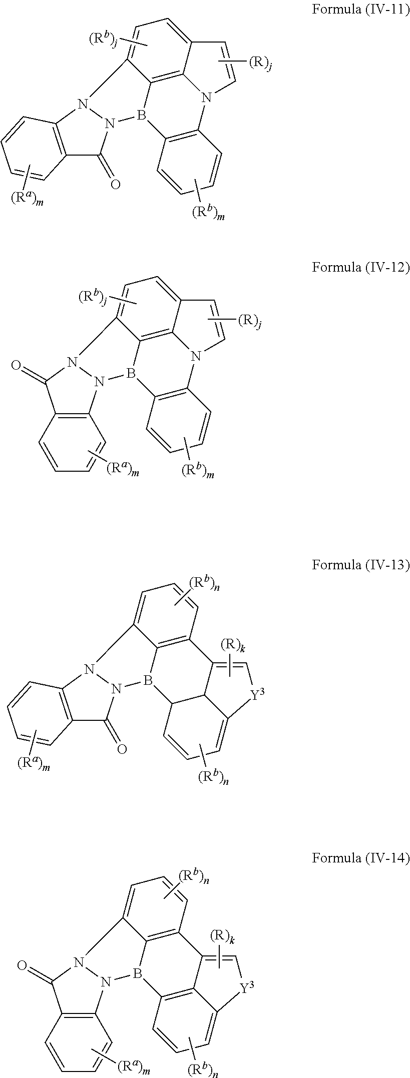

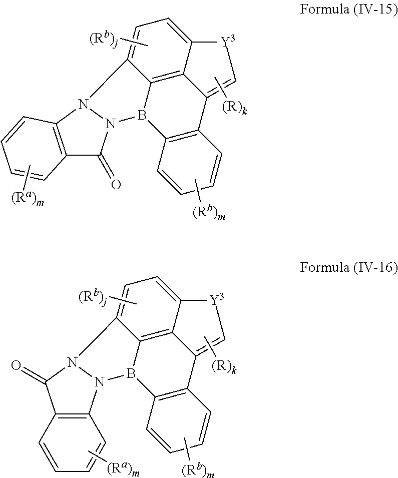

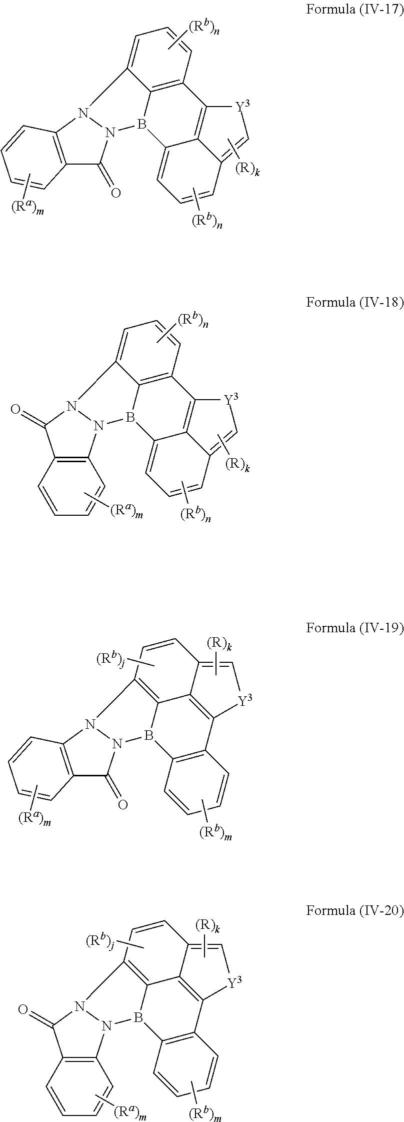

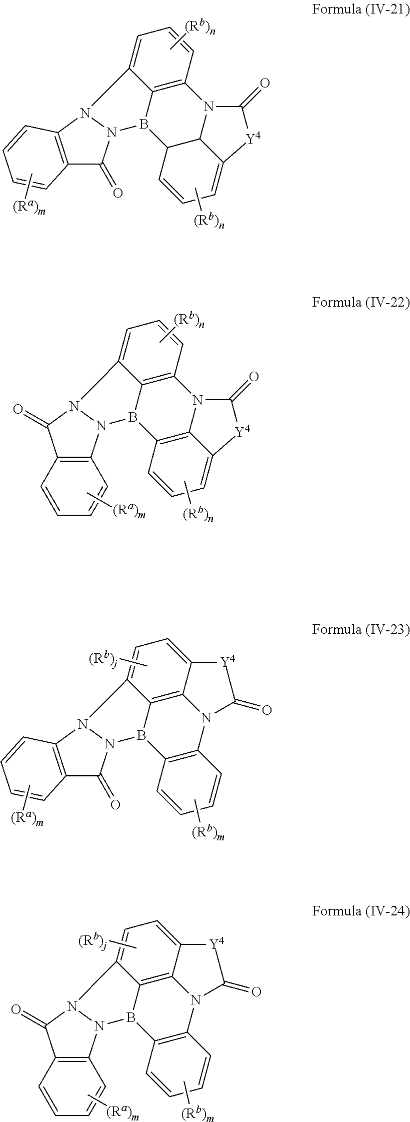

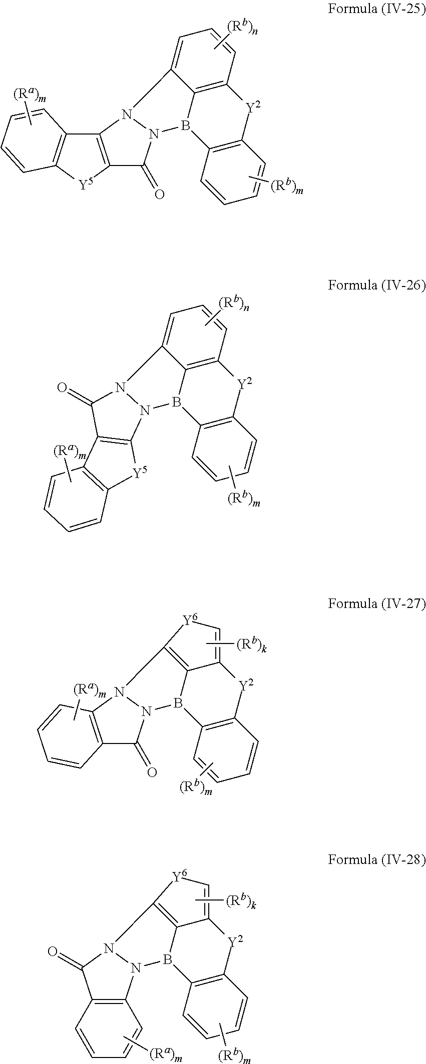

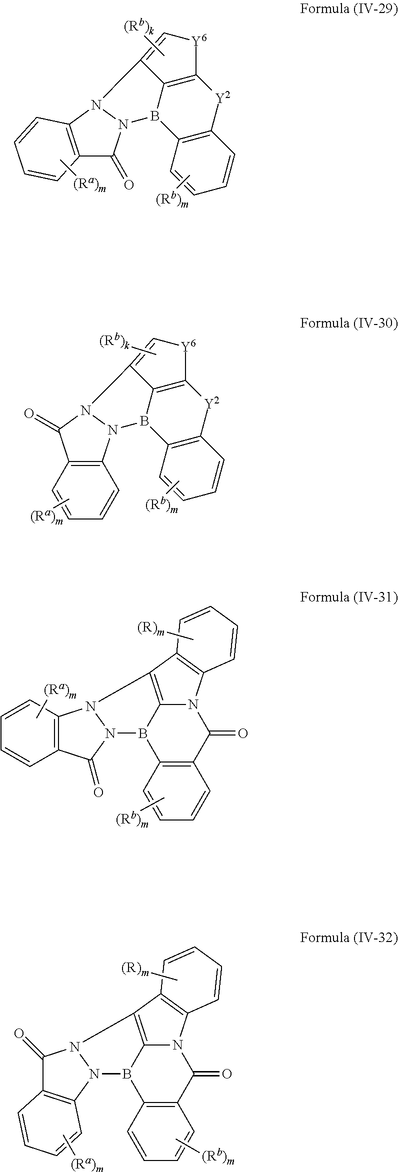

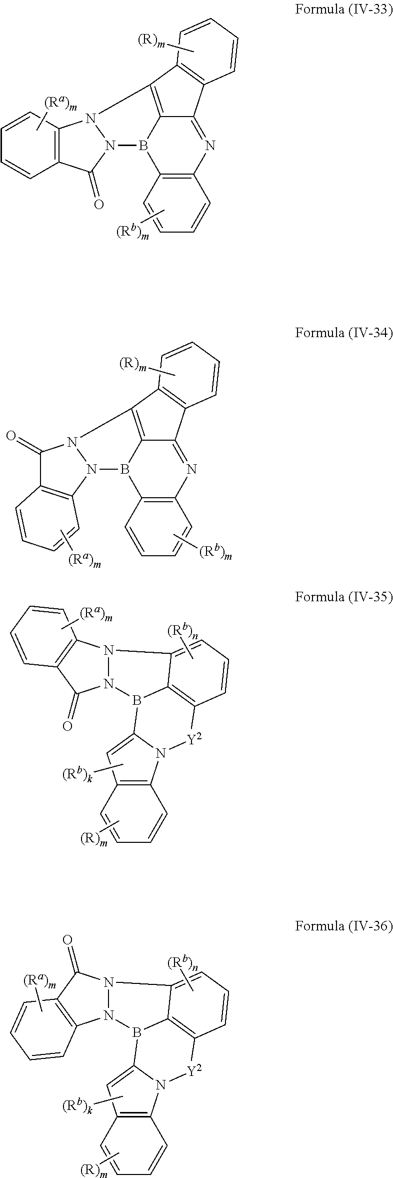

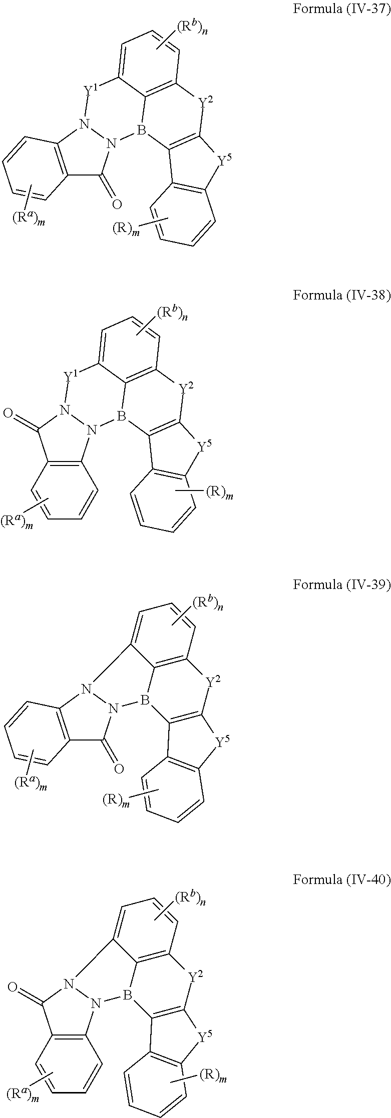

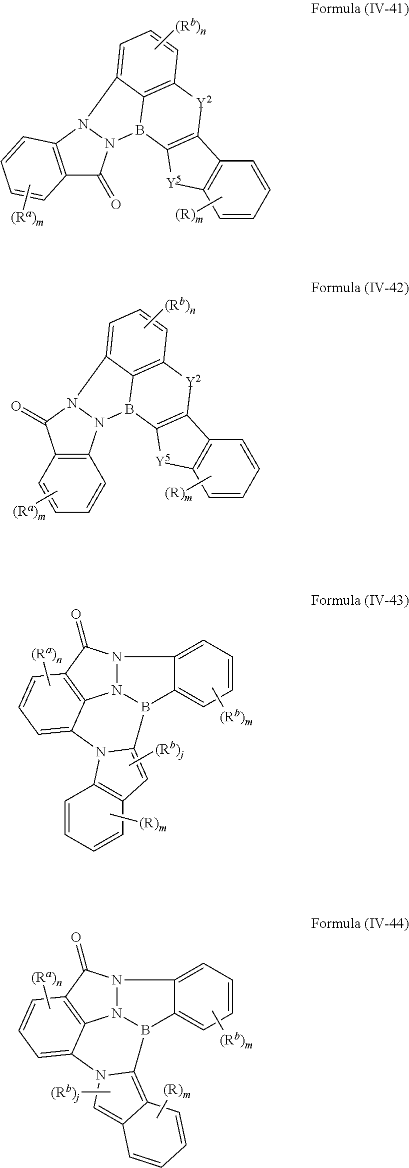

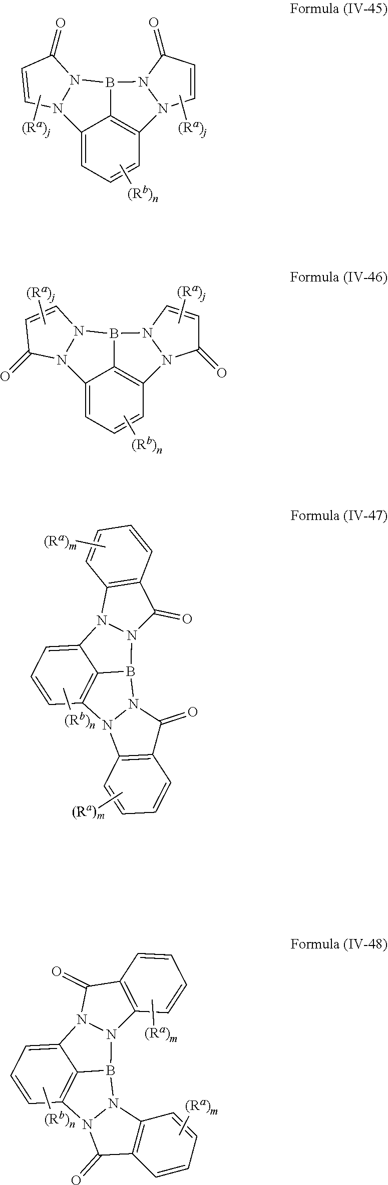

where the symbols R, R^{a} and R^{b} have the definitions given above, especially for formula (I), the symbols Y¹, Y², Y³, Y⁴, Y⁵ and Y⁶ have the definitions given above, especially for formulae (III-1) to (III-48), and the further symbols are as follows:
l is 0, 1, 2, 3, 4 or 5, preferably 0, 1 or 2;
m is 0, 1, 2, 3 or 4, preferably 0, 1 or 2;
n is 0, 1, 2 or 3, preferably 0, 1 or 2;
j is 0, 1 or 2, preferably 0 or 1;
k is 0 or 1.

Preference is given here to structures/compounds of the formulae (IV-3) to (IV-14), (IV-17) to (IV-26), (IV-47) and (IV-48), particular preference to structures of the formulae (IV-3), (IV-5), (IV-7), (IV-9), (IV-11), (IV-13), (IV-17), (IV-19), (IV-21), (IV-23), (IV-25) and (IV-47).

The sum total of the indices k, j, m, n and l at most, especially in structures/compounds of the formulae (IV-1) to (IV-48), is preferably not more than 10, preferably not more than 8, especially preferably not more than 6 and more preferably not more than 4.

In addition, in formulae including (I), (II-1) to (II-18), (III-1) to (III-48), (IV-1) to (IV-48) and/or the preferred embodiments of these formulae detailed hereinafter, it may be the case that at least one R, R^{a}, R^{b} radical is a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 20 carbon atoms, where the alkyl, alkoxy, thioalkoxy, alkenyl or alkynyl group may in each case be substituted by one or more R¹ radicals, where one or more nonadjacent CH₂ groups may be replaced by R¹C═CR¹, C═C, Si(R¹)₂, C═O, C═S, C═Se, C═NR¹, —C(═O)O—, —C(═O)NR¹—, NR¹, P(═O)(R¹), —O—, —S—, SO or SO₂, or is an aromatic or heteroaromatic ring system which has 5 to 60 aromatic ring atoms and may be substituted in each case by one or more R¹ radicals, or is an aryloxy or heteroaryloxy group which has 5 to 60 aromatic ring atoms and may be substituted by one or more R¹ radicals, or is a heteroarylthio group which has 5 to 60 aromatic ring atoms and may be substituted by one or more R¹ radicals, or is a diarylamino, arylheteroarylamino, diheteroarylamino group which has 5 to 60 aromatic ring atoms and may be substituted by one or more R¹ radicals, or is an arylalkyl or heteroarylalkyl group which has 5 to 60 aromatic ring atoms and 1 to 10 carbon atoms in the alkyl radical and may be substituted by one or more R¹ radicals.

Preferably, in formulae including (I), (II-1) to (II-18), (III-1) to (III-48), (IV-1) to (IV-48) and/or the preferred embodiments of these formulae detailed hereinafter, it may be the case that at least one R, R^{a}, R^{b} radical is an aromatic or heteroaromatic ring system which has 5 to 60 aromatic ring atoms and may be substituted in each case by one or more R¹ radicals, or is an aryloxy or heteroaryloxy group which has 5 to 60 aromatic ring atoms and may be substituted by one or more R¹ radicals, or is a heteroarylthio group which has 5 to 60 aromatic ring atoms and may be substituted by one or more R¹ radicals, or is a diarylamino, arylheteroarylamino, diheteroarylamino group which has 5 to 60 aromatic ring atoms and may be substituted by one or more R¹ radicals, or is an arylalkyl or heteroarylalkyl group which has 5 to 60 aromatic ring atoms and 1 to 10 carbon atoms in the alkyl radical and may be substituted by one or more R¹ radicals, more preferably an aromatic or heteroaromatic ring system which has 5 to 60 aromatic ring atoms and may be substituted in each case by one or more R¹ radicals.

In addition, it may preferably be the case that the structures/compounds of the formulae (I), (II-1) to (II-18), (III-1) to (III-48), (IV-1) to (IV-48) and/or the preferred embodiments of these formulae detailed hereinafter have at most one and preferably no free olefinic double bond, where aromatic 6-membered rings are preferably fused to aromatic 5-membered rings. Free olefinic double bonds are firstly —C═C— groups that are not part of an aromatic or heteroaromatic system and preferably have hydrogen atoms.

In addition, free olefinic double bonds are —C═C— groups that are part of a heteroaromatic 5-membered ring, as realized in furan or imidazole radicals, for example, where these groups must be in free form. This is the case especially if the carbon atoms of the C═C double bond are bonded to a hydrogen atom. In the case of fusion of a further aromatic or heteroaromatic ring, as is the case, for example, in dibenzofuranyl or benzimidazole radicals, there are no olefinic double bonds since the —C═C— groups are not in free form here. Moreover, there are no olefinic double bonds if the two carbon atoms of the C═C double bond are joined by a ring which is preferably formed by the groups of the formulae (RA-1) to (RA-12), formulae (RA-1a) to (RA-4f) and/or of the formula (RB) described below.

Furthermore, it may preferably be the case that the structures/compounds of the formulae (I), (II-1) to (II-18), (III-1) to (III-48), (IV-1) to (IV-48) and/or the preferred embodiments of these formulae detailed hereinafter do not have any structures having 7 ring atoms, excluding bridged structures here, especially bicyclic and tricyclic systems.

In a preferred development of the present invention, it may be the case that at least two R, R^{a}, R^{b} radicals together with the further groups to which the two R, R^{a}, R^{b} radicals bind form a fused ring, where the two R, R^{a}, R^{b} radicals form at least one structure of the formulae (RA-1) to (RA-12):

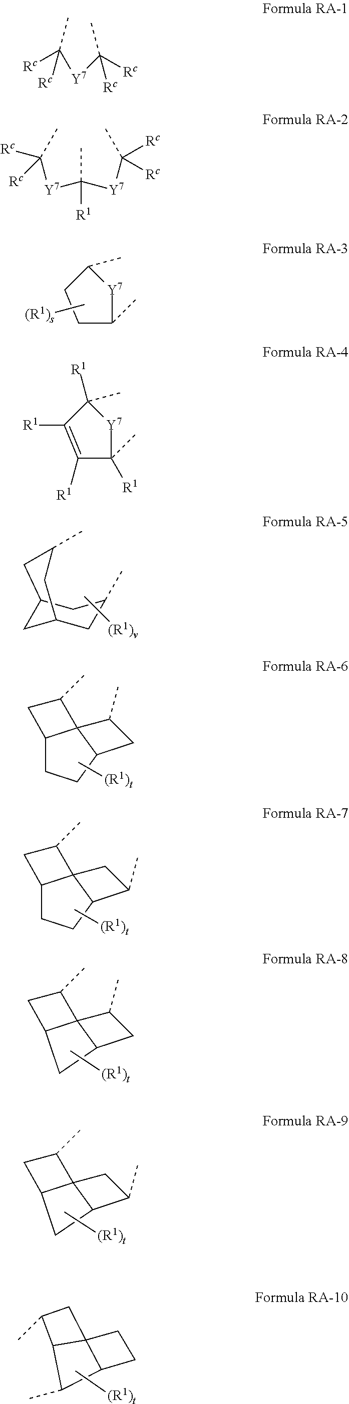

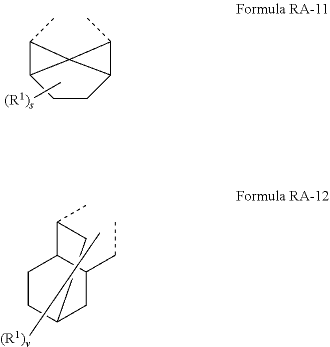

where R¹ has the definition detailed above, the dotted bonds represent the sites of attachment via which the two R, R^{a}, R^{b} radicals bind to the further groups, and the further symbols have the following definition:
Y⁷ is the same or different at each instance and is C(R¹)₂, (R¹)₂C—C(R¹)₂, (R¹)C═C(R¹), NR¹, NAr′, 0 or S, preferably C(R¹)₂, (R¹)₂C—C(R¹)₂, (R¹)C═C(R¹), 0 or S;
R^{c} is the same or different at each instance and is F, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 20 carbon atoms, where the alkyl, alkoxy, thioalkoxy, alkenyl or alkynyl group may be substituted in each case by one or more R² radicals, where one or more nonadjacent CH₂ groups may be replaced by R²C═CR², C═C, Si(R²)₂, C═O, C═S, C═Se, C═NR², —C(═O)O—, —C(═O)NR²—, NR², P(═O)(R¹), —O—, —S—, SO or SO₂, or an aromatic or heteroaromatic ring system which has 5 to 60 aromatic ring atoms and may be substituted in each case by one or more R² radicals, or an aryloxy or heteroaryloxy group which has 5 to 60 aromatic ring atoms and may be substituted by one or more R² radicals; at the same time, it is also possible for two R^{c} radicals together or one R^{c} radical together with an R¹ radical or together with a further group to form a ring system;
s is 0, 1, 2, 3, 4, 5 or 6, preferably 0, 1, 2, 3 or 4, more preferably 0, 1 or 2;
t is 0, 1, 2, 3, 4, 5, 6, 7 or 8, preferably 0, 1, 2, 3 or 4, more preferably 0, 1 or 2;
v is 0, 1, 2, 3, 4, 5, 6, 7, 8 or 9, preferably 0, 1, 2, 3 or 4, more preferably 0, 1 or 2.

In a preferred embodiment of the invention, the at least two R, R^{a}, R^{b} radicals together with the further groups to which the two R, R^{a}, R^{b} radicals bind form a fused ring, where the two R, R^{a}, R^{b} radicals preferably form at least one of the structures of the formulae (RA-1a) to (RA-4f):

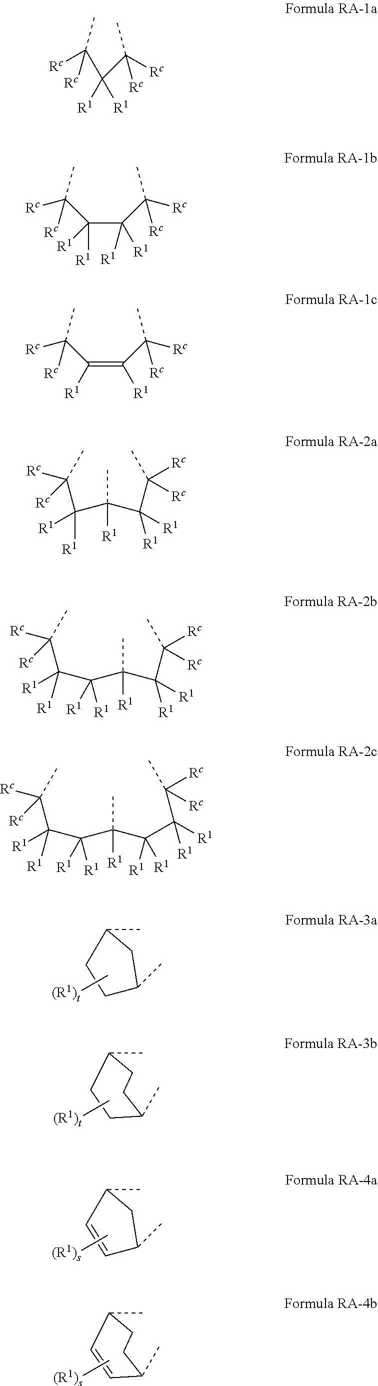

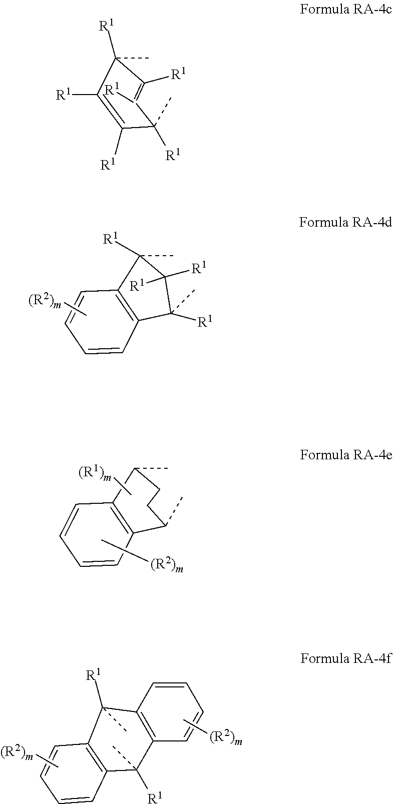

where the dotted bonds represent the sites of attachment via which the two R, R^{a}, R^{b} radicals bind to the further groups, the index m is 0, 1, 2, 3 or 4, preferably 0, 1 or 2, and the symbols R¹, R², R^{c} and indices s and t have the definition detailed above, especially for formula (I) and/or formulae (RA-1) to (RA-12).

It may further be the case that the at least two R, R^{a}, R^{b} radicals form the structures of the formulae (RA-1) to (RA-12) and/or (RA-1a) to (RA-4f) and form a fused ring, represent R, R^{a}, R^{b} radicals from adjacent X, X^{a}, X^{b} groups, or represent R, R^{a}, R^{b} radicals that each bind to adjacent carbon atoms, where these carbon atoms are preferably connected via a bond.

In a further-preferred configuration, at least two R, R^{a}, R^{b} radicals together with the further groups to which the two R, R^{a}, R^{b} radicals bind form a fused ring, where the two R, R^{a}, R^{b} radicals form structures of the formula (RB):

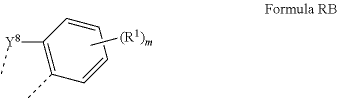

where R¹ has the definition set out above, especially for formula (I), the dotted bonds represent the bonding sites via which the two R, R^{a}, R^{b} radicals bind to the further groups, the index m is 0, 1, 2, 3 or 4, preferably 0, 1 or 2, and Y⁸ is C(R¹)₂, NR¹, NAr′, BR¹, BAr′, O or S, preferably C(R¹)₂, NAr′ or O.

It may be the case here that the at least two R, R^{a}, R^{b} radicals form the structures of the formula (RB) and form a fused ring, represent R, R^{a}, R^{b} radicals from adjacent X, X^{a}, X^{b} groups, or represent R, R^{a}, R^{b} radicals that each bind to adjacent carbon atoms, where these carbon atoms are preferably joined to one another via a bond.

More preferably, the compounds include at least one structure of the formulae (V-1) to (V-12); more preferably, the compounds are selected from compounds of the formulae (V-1) to (V-12), where the compounds have at least one fused ring:

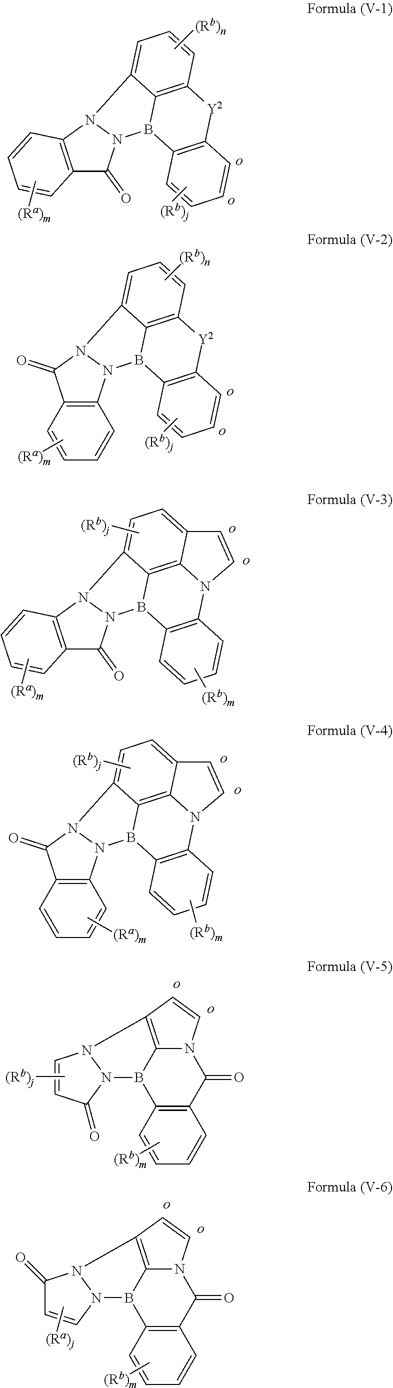

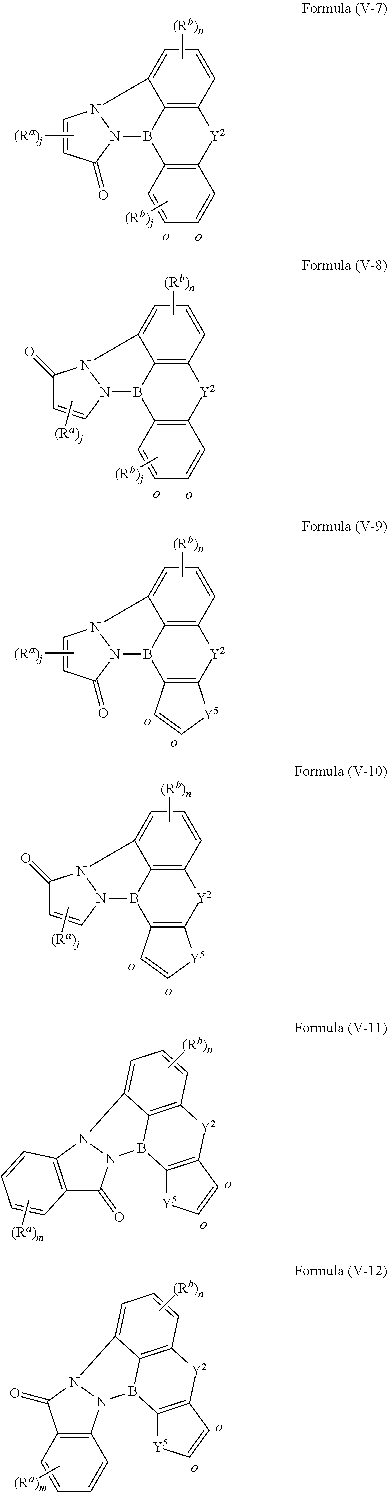

where the symbols R^{a}, R^{b}, Y² and Y⁵ have the definitions given above, especially for formula (I) and/or formulae (III-1) to (III-48), the symbol o represents the sites of attachment, and the further symbols have the following definition:
m is 0, 1, 2, 3 or 4, preferably 0, 1 or 2;
n is 0, 1, 2 or 3, preferably 0, 1 or 2;
j is 0, 1 or 2, preferably 0 or 1.

More preferably, the compounds include at least one structure of the formulae (VI-1) to (VI-12); more preferably, the compounds are selected from compounds of the formulae (VI-1) to (VI-12), where the compounds have at least one fused ring:

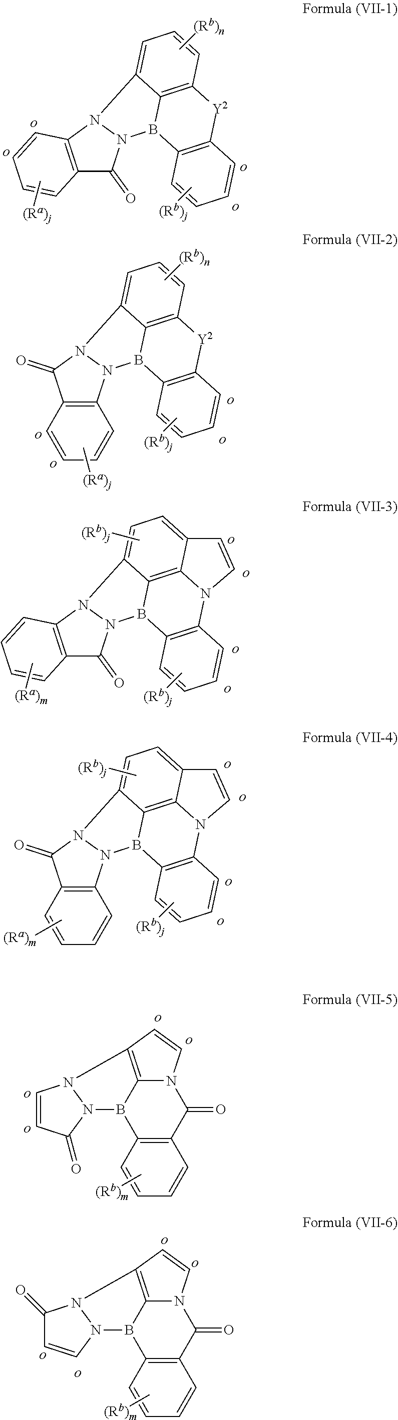

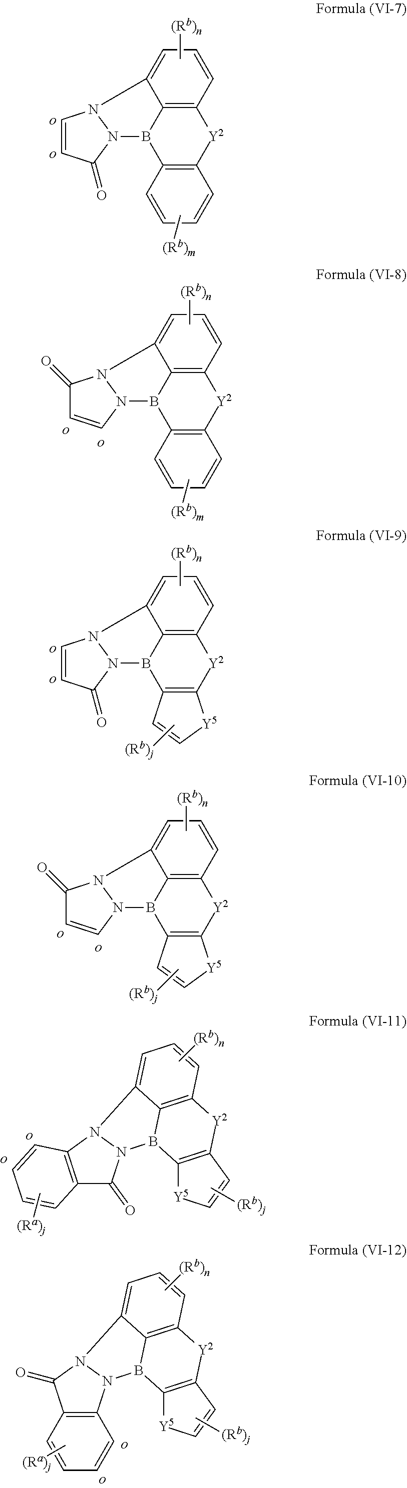

where the symbols R, R^{a}, R^{b}, Y² and Y⁵ have the definitions given above, especially for formula (I) and/or formulae (III-1) to (III-48), the symbol o represents the sites of attachment of the fused ring, and the further symbols have the following definition:
m is 0, 1, 2, 3 or 4, preferably 0, 1 or 2;
n is 0, 1, 2 or 3, preferably 0, 1 or 2;
j is 0, 1 or 2, preferably 0 or 1.

Preferably, the fused ring, especially in formulae (V-1) to (V-12) and/or (VI-1) to (VI-12), is formed by at least two R, R^{a}, R^{b} radicals and the further groups to which the two R, R^{a}, R^{b} radicals bind, where the at least two R, R^{a}, R^{b} radicals form structures of the formulae (RA-1) to (RA-12) and/or of the formula (RB), preferably structures of the formulae (RA-1) to (RA-12).

It may preferably be the case that the compounds have at least two fused rings, where at least one fused ring is formed by structures of the formulae (RA-1) to (RA-12) and/or (RA-1a) to (RA-4f) and a further ring by structures of the formulae (RA-1) to (RA-12), (RA-1a) to (RA-4f) or (RB).

More preferably, the compounds include at least one structure of the formulae (VII-1) to (VII-12); more preferably, the compounds are selected from compounds of the formulae (VII-1) to (VII-12), where the compounds have at least two fused rings:

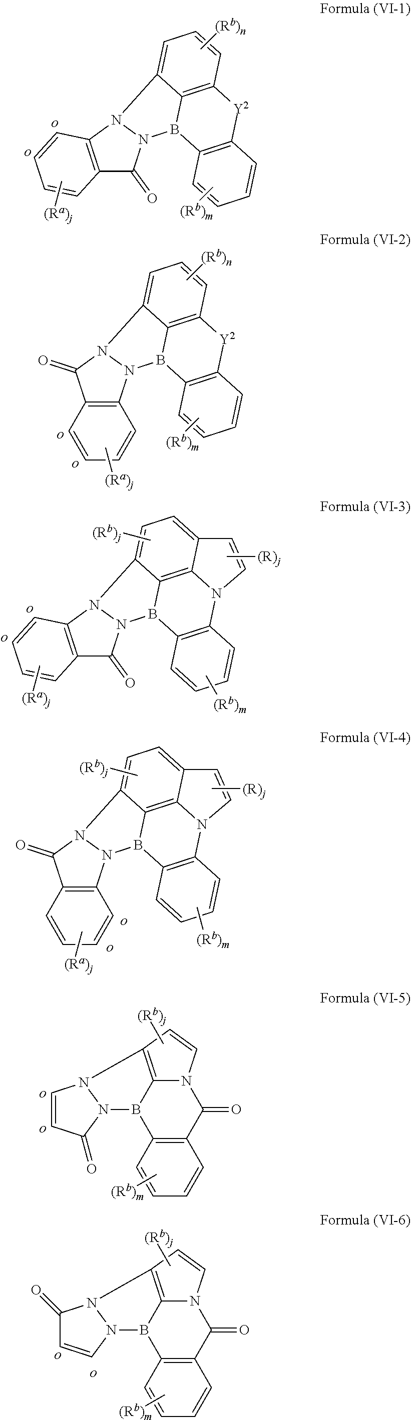

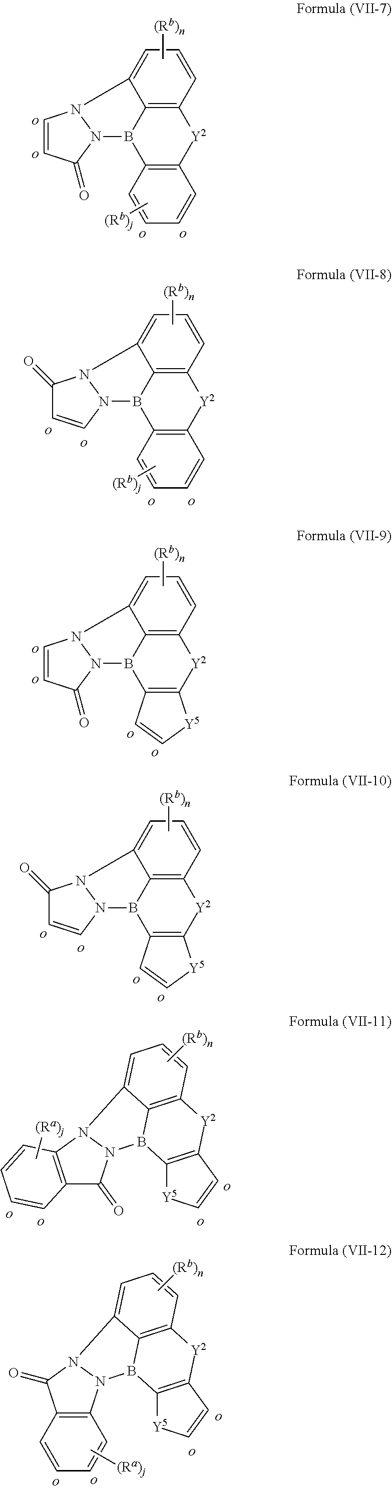

where the symbols R^{a}, R^{b}, Y² and Y⁵ have the definitions given above, especially for formula (I) and/or formulae (III-1) to (III-48), the symbol o represents the sites of attachment, and the further symbols have the following definition:
m is 0, 1, 2, 3 or 4, preferably 0, 1 or 2;
n is 0, 1, 2 or 3, preferably 0, 1 or 2;
j is 0, 1 or 2, preferably 0 or 1.

Preferably, at least one of the fused rings, more preferably both of the fused rings, especially in formulae (VII-1) to (VII-12), is formed by at least two R, R^{a}, R^{b} radicals and the further groups to which the two R, R^{a}, R^{b} radicals bind, where the at least two R, R^{a}, R^{b} radicals form structures of the formulae (RA-1) to (RA-12) and/or of the formula (RB), preferably structures of the formulae (RA-1) to (RA-12).

Especially in the formulae (V-1) to (V-12), (VI-1) to (VI-12) and/or (VII-1) to (VII-12), it may be the case that the sum total of the indices j, n and m is preferably 0, 1, 2 or 3, more preferably 1 or 2.

It may additionally be the case that the substituents R, R^{a}, R^{b}, R^{c}, R¹ and R² according to the above formulae do not form a fused aromatic or heteroaromatic ring system with the ring atoms of the ring system to which the substituents R, R^{a}, R^{b}, R^{c}, R¹ and R² bind. This includes the formation of a fused aromatic or heteroaromatic ring system with possible substituents R¹ and R² that may be bonded to the R, R^{a}, R^{b}, R^{c} and R¹ radicals.

When two radicals that may especially be selected from R, R^{a}, R^{b}, R^{c}, R¹ and/or R² form a ring system with one another, this ring system may be mono- or polycyclic, aliphatic, heteroaliphatic, aromatic or heteroaromatic.

In this case, the radicals which together form a ring system may be adjacent, meaning that these radicals are bonded to the same carbon atom or to carbon atoms directly bonded to one another, or they may be further removed from one another. In addition, the ring systems provided with the substituents R, R^{a}, R^{b}, R^{c}, R¹ and/or R² may also be joined to one another via a bond, such that this can bring about a ring closure. In this case, each of the corresponding bonding sites has preferably been provided with a substituent R, R^{a}, R^{b}, R^{c}, R¹ and/or R².

In a preferred configuration, a compound of the invention can be represented by at least one of the structures of formulae (I), (II-1) to (II-18), (III-1) to (III-48), (IV-1) to (IV-48), (V-1) to (V-12), (VI-1) to (VI-12) and/or (VII-1) to (VII-12). Preferably, compounds of the invention, preferably comprising structures of formulae (I), (II-1) to (II-18), (III-1) to (III-48), (IV-1) to (IV-48), (V-1) to (V-12), (VI-1) to (VI-12) and/or (VII-1) to (VII-12) have a molecular weight of not more than 5000 g/mol, preferably not more than 4000 g/mol, particularly preferably not more than 3000 g/mol, especially preferably not more than 2000 g/mol and most preferably not more than 1200 g/mol.

In addition, it is a feature of preferred compounds of the invention that they are sublimable. These compounds generally have a molar mass of less than about 1200 g/mol.

It may preferably be the case that Ar^{a} is the same or different at each instance and is selected from phenyl, biphenyl, terphenyl, quaterphenyl, fluorene, spirobifluorene, naphthalene, indole, benzofuran, benzothiophene, carbazole, dibenzofuran, dibenzothiophene, indenocarbazole, indolocarbazole, pyridine, pyrimidine, pyrazine, pyridazine, triazine, quinoline, isoquinoline, quinazoline, quinoxaline, phenanthrene and triphenylene, each of which may be substituted by one or more Ar or R^{a} radicals.

A structure of formula (I) may comprise a ring Ar^{b} which is the same or different at each instance and is an aromatic or heteroaromatic ring system which has 5 to 60 aromatic ring atoms and may be substituted by one or more Ar or R^{b} radicals, where the ring Ar^{b} may form a ring system with an R, Ar or Z^{c} group or the rings Ar^{a} and Ar^{b} together may form a ring system. Accordingly, the ring Ar^{b} may comprise an Ar^{b} group which is the same or different at each instance and is an aromatic or heteroaromatic ring system which has 5 to 50 aromatic ring atoms and may be substituted by one or more Ar or R^{b} radicals. In this case, this Ar^{b} group, with the two nitrogen atoms and the boron atom, forms a ring having preferably five to eight, more preferably five or six, ring atoms. In addition, it may preferably be the case that the Ar^{b} group is the same or different at each instance and is selected from phenyl, biphenyl, terphenyl, quaterphenyl, fluorene, spirobifluorene, naphthalene, indole, benzofuran, benzothiophene, carbazole, dibenzofuran, dibenzothiophene, indenocarbazole, indolocarbazole, pyridine, pyrimidine, pyrazine, pyridazine, triazine, quinoline, isoquinoline, quinazoline, quinoxaline, phenanthrene or triphenylene, each of which may be substituted by one or more Ar or R^{b} radicals.

Preferred aromatic or heteroaromatic ring systems R, R^{a}, R^{b}, R^{c}, Ar′ and/or Ar are selected from phenyl, biphenyl, especially ortho-, meta- or para-biphenyl, terphenyl, especially ortho-, meta- or para-terphenyl or branched terphenyl, quaterphenyl, especially ortho-, meta- or para-quaterphenyl or branched quaterphenyl, fluorene which may be joined via the 1, 2, 3 or 4 position, spirobifluorene which may be joined via the 1, 2, 3 or 4 position, naphthalene, especially 1- or 2-bonded naphthalene, indole, benzofuran, benzothiophene, carbazole which may be joined via the 1, 2, 3, 4 or 9 position, dibenzofuran which may be joined via the 1, 2, 3 or 4 position, dibenzothiophene which may be joined via the 1, 2, 3 or 4 position, indenocarbazole, indolocarbazole, pyridine, pyrimidine, pyrazine, pyridazine, triazine, quinoline, isoquinoline, quinazoline, quinoxaline, phenanthrene or triphenylene, each of which may be substituted by one or more R¹ or R radicals.

It may preferably the case that at least one substituent R, R^{a}, R^{b} is the same or different at each instance and is selected from the group consisting of H, D, a branched or cyclic alkyl, alkoxy or thioalkoxy group having 3 to 20 carbon atoms or an aromatic or heteroaromatic ring system selected from the groups of the following formulae Ar-1 to Ar-78; preferably, the substituents R, R^{a}, R^{b} either form a fused ring, preferably according to the structures of the formulae (RA-1) to (RA-12) or (RB), or the substituent R, R^{a}, R^{b} is the same or different at each instance and is selected from the group consisting of H, D or an aromatic heteroaromatic ring system selected from the groups of the following formulae Ar-1 to Ar-78, and/or the Ar′ group is the same or different at each instance and is selected from the groups of the following formulae Ar-1 to Ar-78:

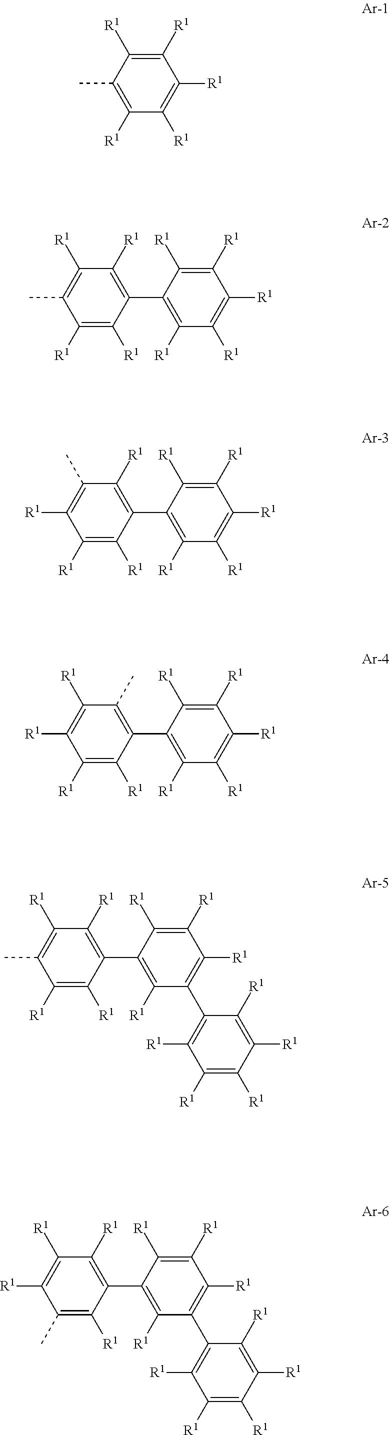

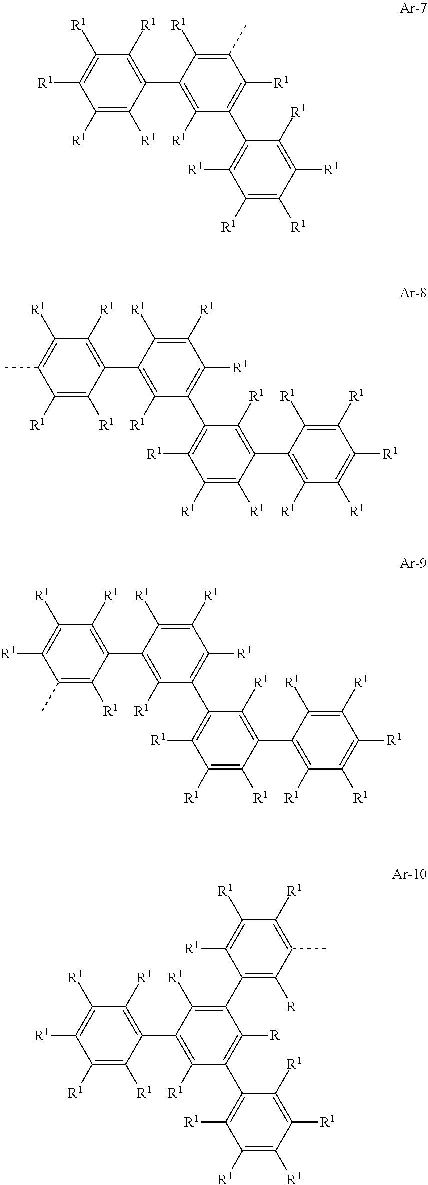

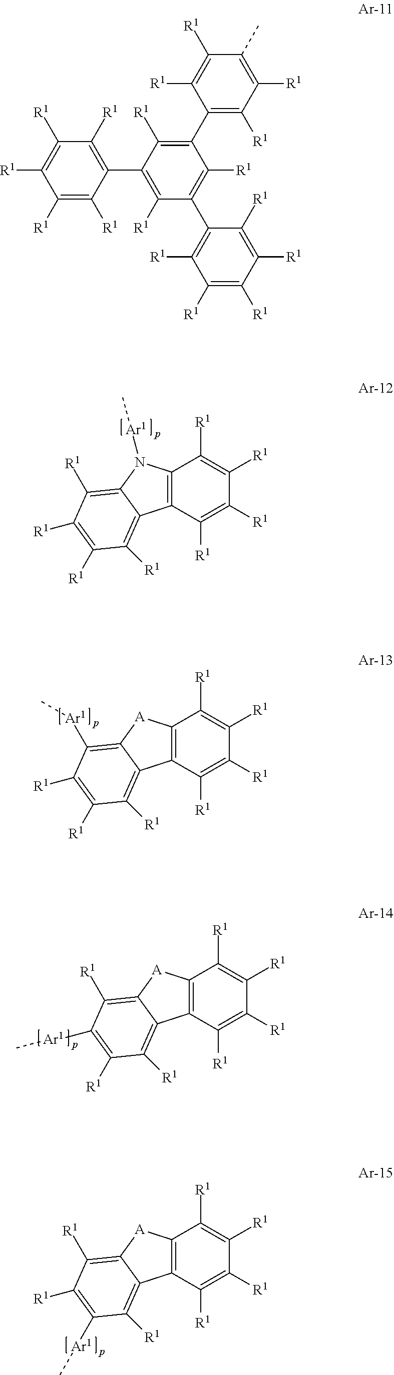

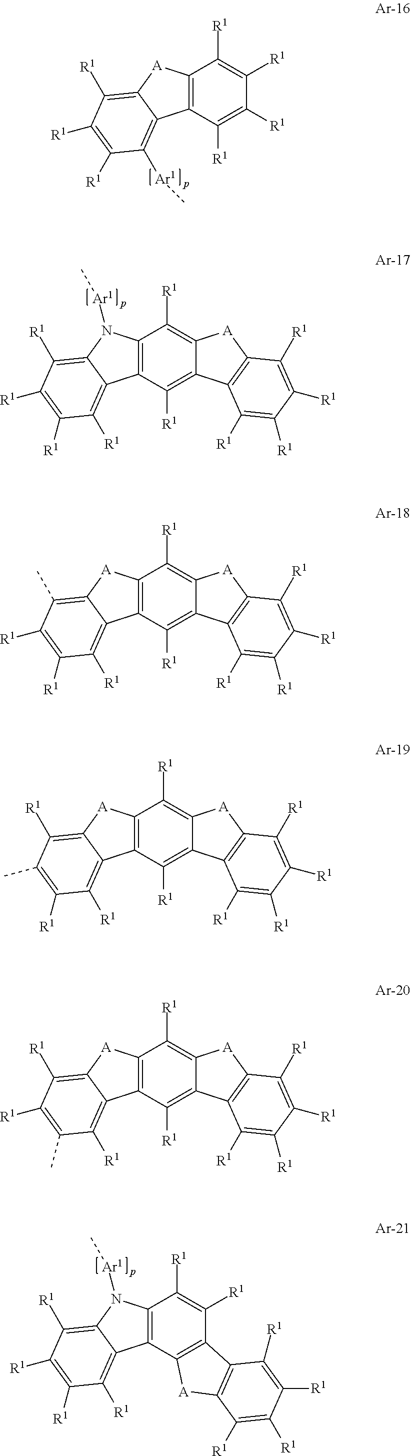

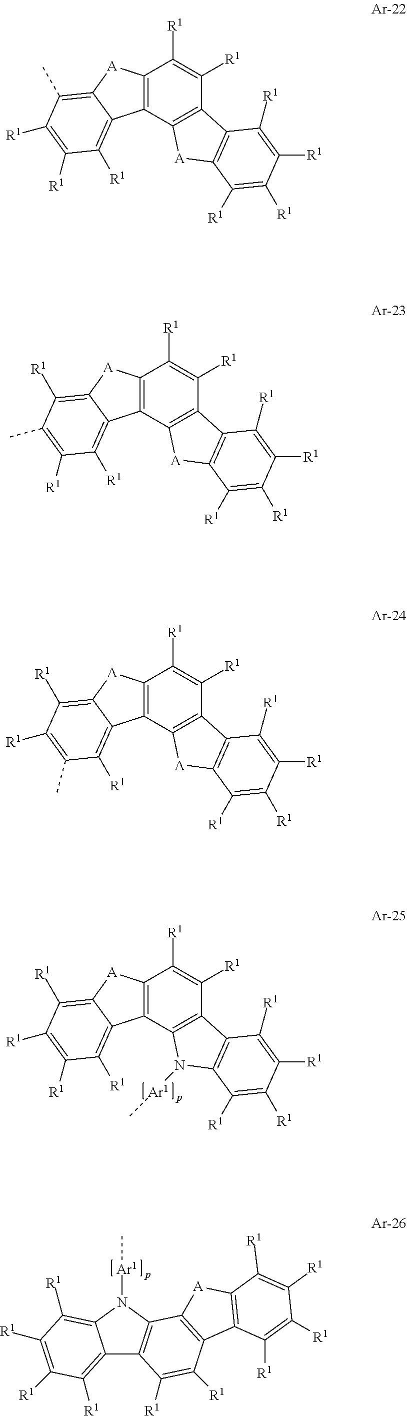

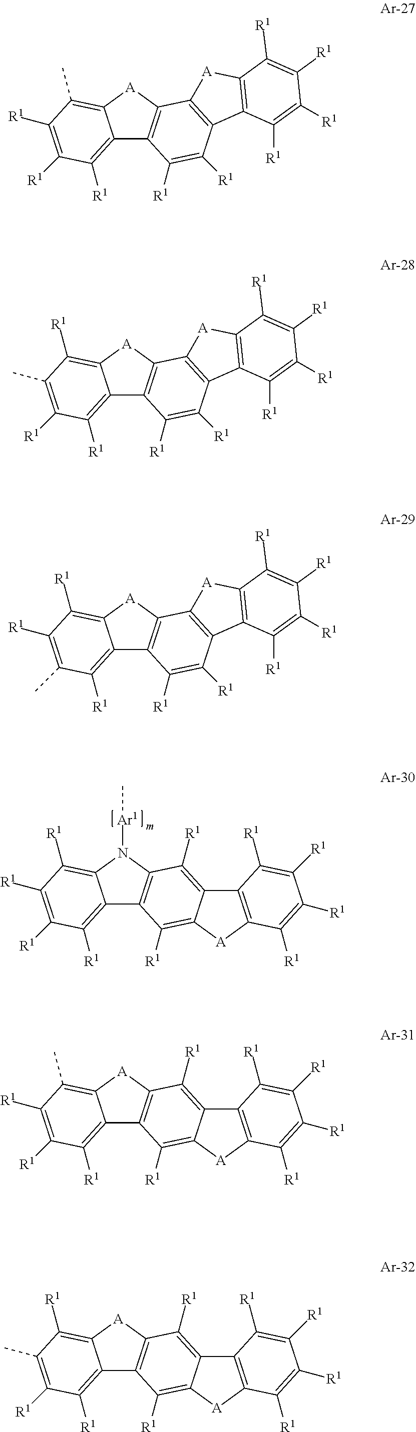

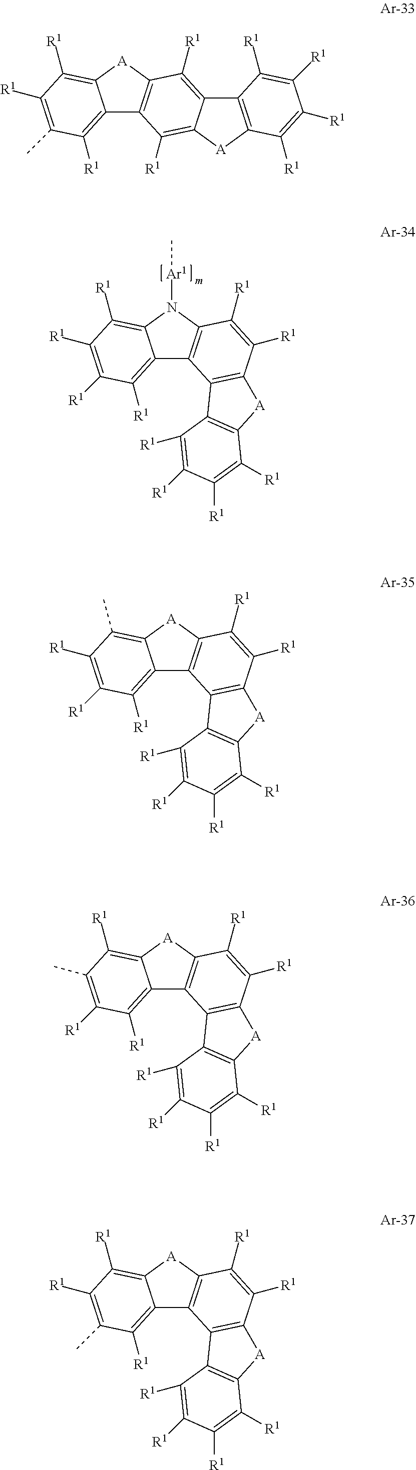

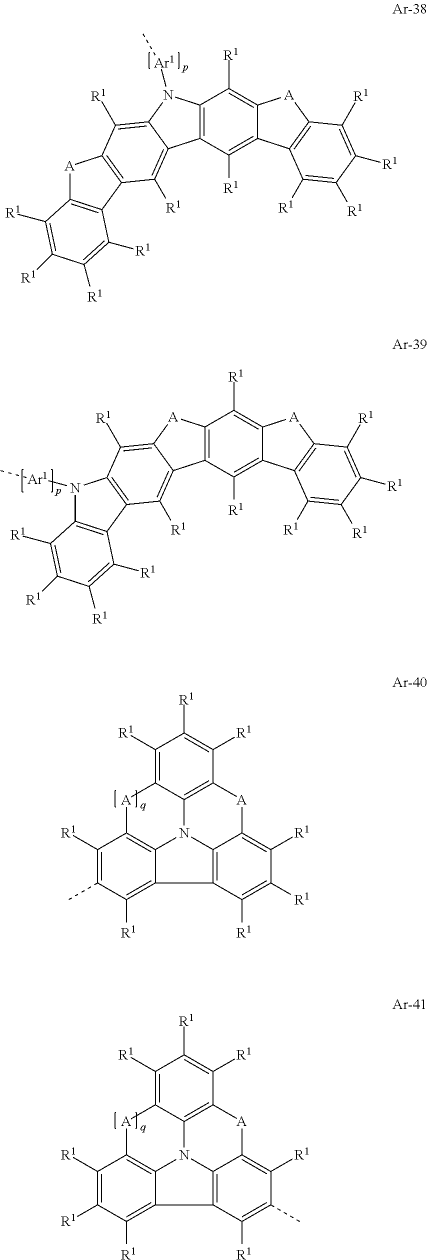

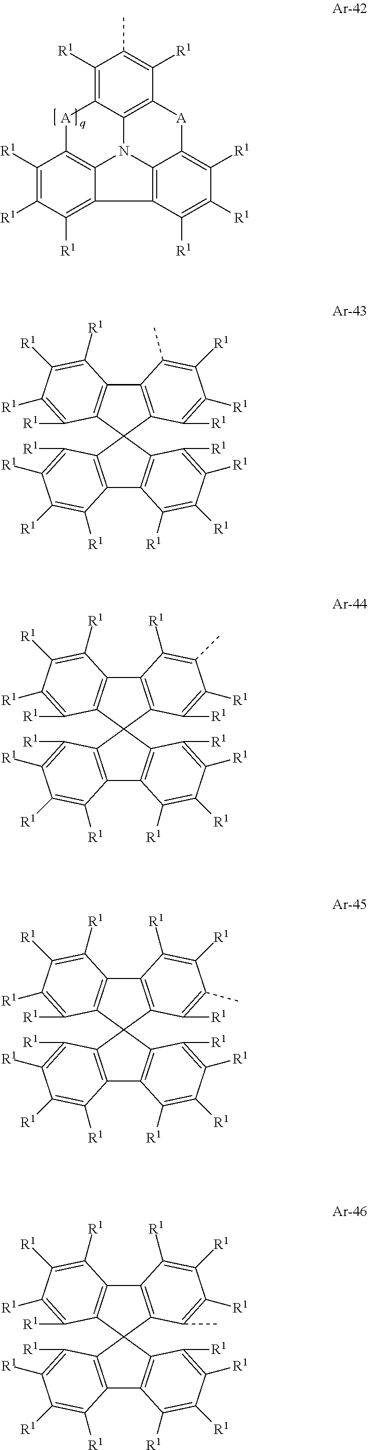

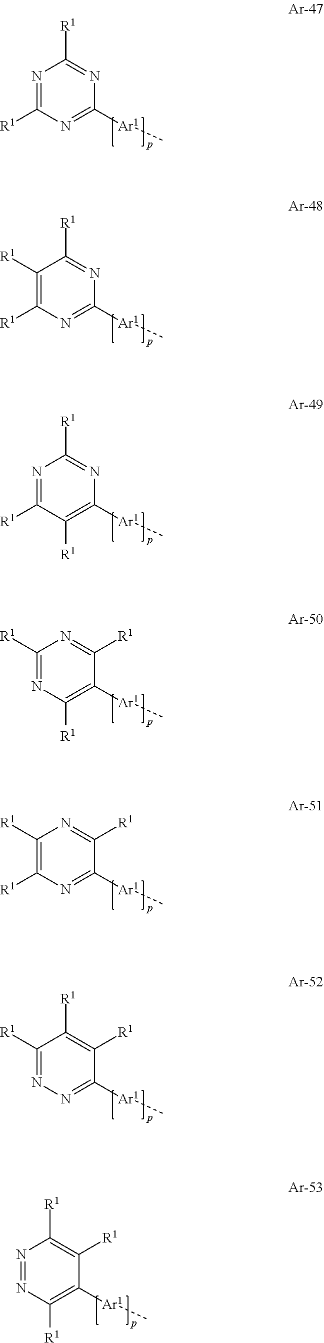

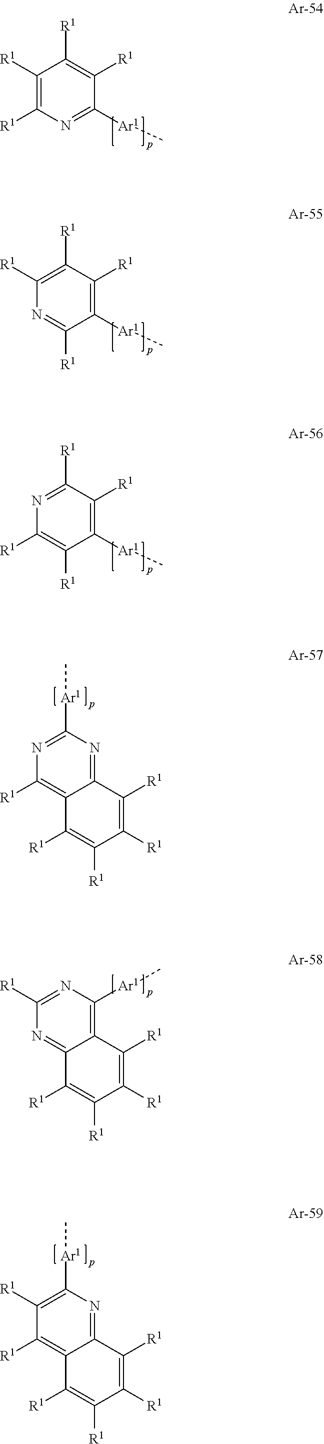

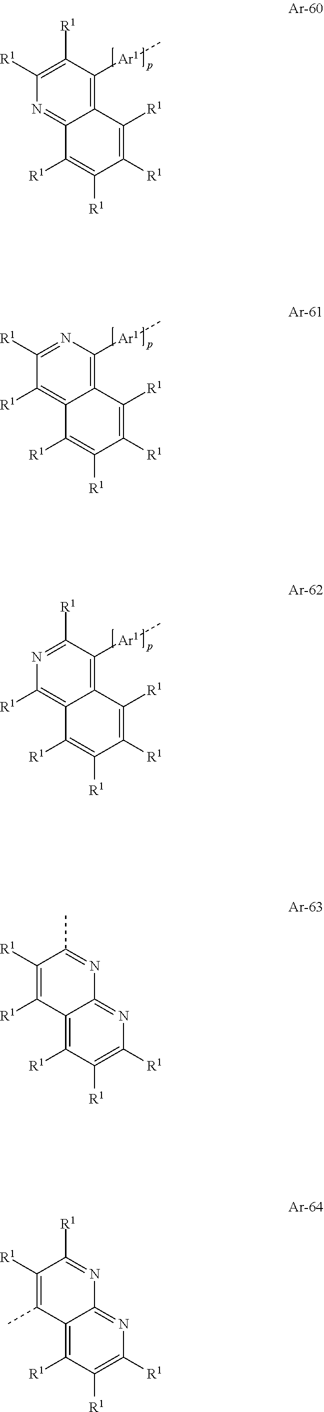

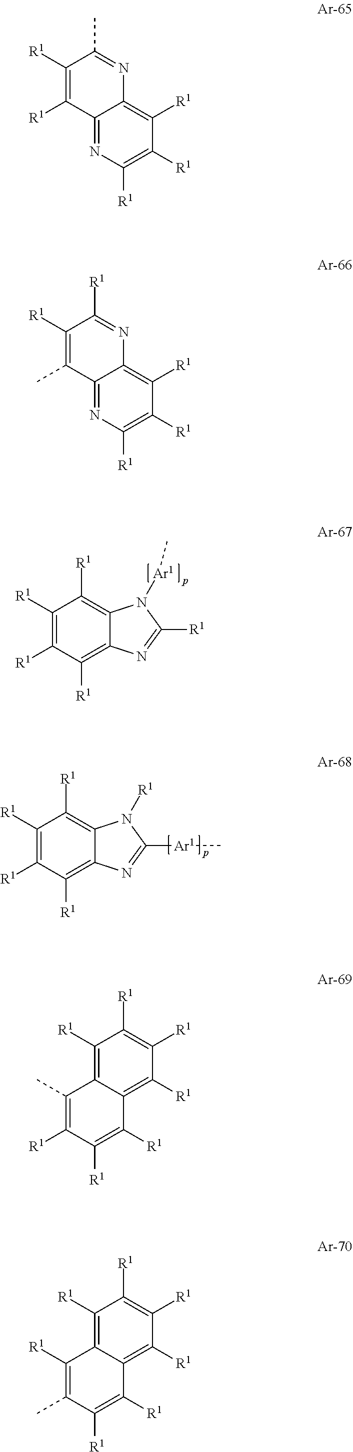

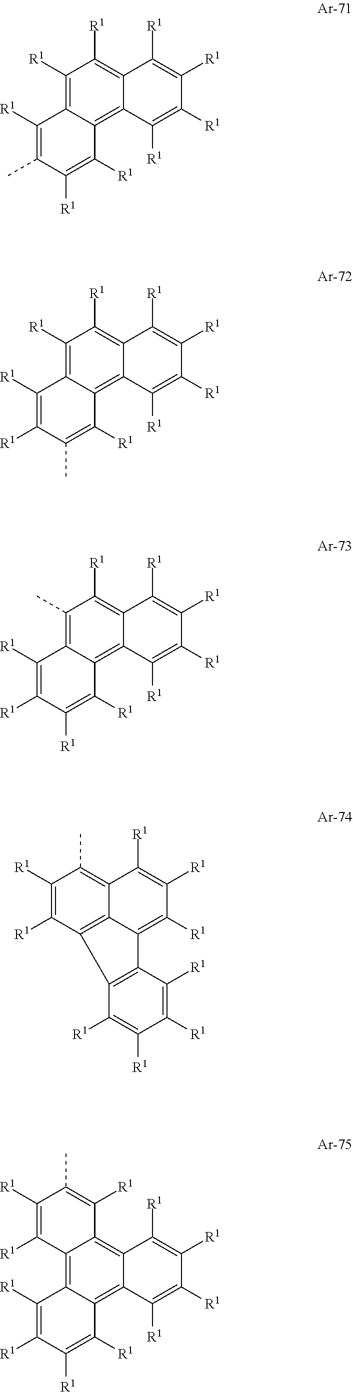

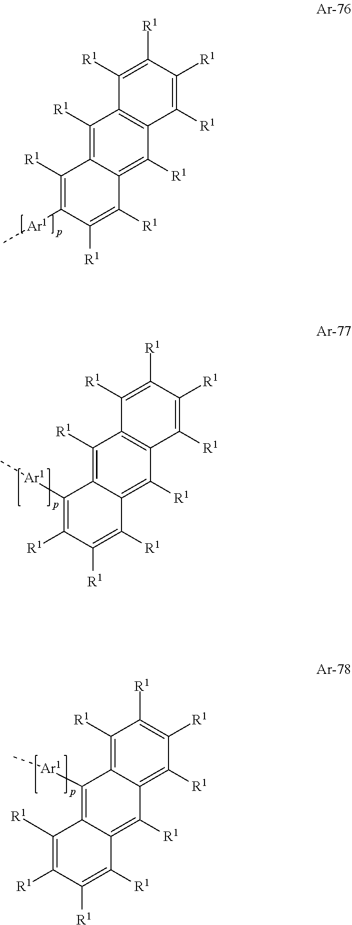

where R¹ is as defined above, the dotted bond represents the site of attachment and, in addition:
Ar¹ is the same or different at each instance and is a bivalent aromatic or heteroaromatic ring system which has 6 to 18 aromatic ring atoms and may be substituted in each case by one or more R¹ radicals;
A is the same or different at each instance and is C(R¹)₂, NR¹, O or S;
p is 0 or 1, where p=0 means that the Ar¹ group is absent and that the corresponding aromatic or heteroaromatic group is bonded directly to the corresponding radical;
q is 0 or 1, where q=0 means that no A group is bonded at this position and R¹ radicals are bonded to the corresponding carbon atoms instead.

Preference is given to structures of the formulae (Ar-1), (Ar-2), (Ar-3), (Ar-12), (Ar-13), (Ar-14), (Ar-15), (Ar-16), (Ar-69), (Ar-70), (Ar-75), and particular preference to structures of the formulae (Ar-1), (Ar-2), (Ar-3), (Ar-12), (Ar-13), (Ar-14), (Ar-15), (Ar-16).

When the abovementioned groups for structures of the formulae (Ar-1) to (Ar-78) have two or more A groups, possible options for these include all combinations from the definition of A. Preferred embodiments in that case are those in which one A group is NR¹ and the other A group is C(R¹)₂ or in which both A groups are NR¹ or in which both A groups are O.

When A is NR¹, the substituent R¹ bonded to the nitrogen atom is preferably an aromatic or heteroaromatic ring system which has 5 to 24 aromatic ring atoms and may also be substituted by one or more R² radicals. In a particularly preferred embodiment, this R¹ substituent is the same or different at each instance and is an aromatic or heteroaromatic ring system which has 6 to 24 aromatic ring atoms, especially 6 to 18 aromatic ring atoms, which does not have any fused aryl groups and which does not have any fused heteroaryl groups in which two or more aromatic or heteroaromatic 6-membered ring groups are fused directly to one another, and which may also be substituted in each case by one or more R² radicals. Preference is given to phenyl, biphenyl, terphenyl and quaterphenyl having bonding patterns as listed above for Ar-1 to Ar-11, where these structures, rather than by R¹, may be substituted by one or more R² radicals, but are preferably unsubstituted. Preference is further given to triazine, pyrimidine and quinazoline as listed above for Ar-47 to Ar-50, Ar-57 and Ar-58, where these structures, rather than by R¹, may be substituted by one or more R² radicals.

There follows a description of preferred substituents R, R^{a}, R^{b} and R^{c}.

In a preferred embodiment of the invention, R, R^{a}, R^{b} are the same or different at each instance and are selected from the group consisting of H, D, F, CN, NO₂, Si(R¹)₃, B(OR¹)₂, a straight-chain alkyl group having 1 to 20 carbon atoms or a branched or cyclic alkyl group having 3 to 20 carbon atoms, where the alkyl group may be substituted in each case by one or more R¹ radicals, or an aromatic or heteroaromatic ring system which has 5 to 60 aromatic ring atoms, preferably 5 to 40 aromatic ring atoms, and may be substituted in each case by one or more R¹ radicals.

In a further-preferred embodiment of the invention, substituent R, R^{a}, R^{b} is the same or different at each instance and is selected from the group consisting of H, D, F, a straight-chain alkyl group having 1 to 20 carbon atoms or a branched or cyclic alkyl group having 3 to 20 carbon atoms, where the alkyl group may be substituted in each case by one or more R¹ radicals, or an aromatic or heteroaromatic ring system which has 5 to 60 aromatic ring atoms, preferably 5 to 40 aromatic ring atoms, and may be substituted in each case by one or more R¹ radicals.

It may further be the case that at least one substituent R, R^{a}, R^{b} is the same or different at each instance and is selected from the group consisting of H, D, an aromatic or heteroaromatic ring system which has 6 to 30 aromatic ring atoms and may be substituted by one or more R¹ radicals, and an N(Ar′)₂ group. In a further-preferred embodiment of the invention, the substituents R, R^{a}, R^{b} either form a ring according to the structures of the formulae (RA-1) to (RA-12), (RA-1a) to (RA-4f) or (RB), or the substituent R, R^{a}, R^{b} is the same or different at each instance and is selected from the group consisting of H, D, an aromatic heteroaromatic ring system which has 6 to 30 aromatic ring atoms and may be substituted by one or more R¹ radicals, or an N(Ar′)₂ group. More preferably, substituent R, R^{a}, R^{b} is the same or different at each instance and is selected from the group consisting of H or an aromatic or heteroaromatic ring system having 6 to 24 aromatic ring atoms, preferably having 6 to 18 aromatic ring atoms, more preferably having 6 to 13 aromatic ring atoms, each of which may be substituted by one or more R¹ radicals.

It may preferably the case that at least one substituent R, R^{a}, R^{b} is selected from phenyl, biphenyl, terphenyl, quaterphenyl, fluorene, spirobifluorene, naphthalene, indole, benzofuran, benzothiophene, carbazole, dibenzofuran, dibenzothiophene, indenocarbazole, indolocarbazole, pyridine, pyrimidine, pyrazine, pyridazine, triazine, quinoline, isoquinoline, quinazoline, quinoxaline, phenanthrene or triphenylene, each of which may be substituted by one or more R¹ radicals. What is meant more particularly here by the expression “substituent” is that R, R^{a}, R^{b} are not H. In addition, the substituents R, R^{a}, R^{b} may be the same or different if two or more substituents selected from the aromatic or heteroaromatic groups mentioned are present.

In a further embodiment, it may be the case that at least one substituent R, R^{a}, R^{b} is selected from o-biphenyl, o,o′-terphenyl, o,o′,p-quaterphenyl, 4,6-diphenylpyrimidin-2-yl, 4,6-diphenyltriazin-2-yl, naphthalene, phenanthrene, chrysene, spirobifluorene, triphenylene, anthracene, benzanthracene, fluorene and/or pyrene, each of which may be substituted by one or more R¹ radicals. Preference is given here to spirobifluorene, o-biphenyl, o,o′-terphenyl, o,o′,p-quaterphenyl, 4,6-diphenylpyrimidin-2-yl, 4,6-diphenyltriazin-2-yl radicals. The substituents R, R^{a}, R^{b} may be the same or different if two or more substituents selected from the aromatic groups mentioned are present.

Structures/compounds having a group selected from o-biphenyl, o,o′-terphenyl, o,o′,p-quaterphenyl, 4,6-diphenylpyrimidin-2-yl, 4,6-diphenyltriazin-2-yl, naphthalene, phenanthrene, chrysene, spirobifluorene, triphenylene, anthracene, benzanthracene, fluorene and/or pyrene are especially suitable for use as electron transport material and/or as matrix material.

In a preferred embodiment of the invention, R^{c} is the same or different at each instance and is selected from the group consisting of a straight-chain alkyl group having 1 to 20 carbon atoms or a branched or cyclic alkyl group having 3 to 20 carbon atoms, where the alkyl group may be substituted in each case by one or more R¹ radicals, or an aromatic or heteroaromatic ring system which has 5 to 60 aromatic ring atoms, preferably 5 to 40 aromatic ring atoms, and may be substituted in each case by one or more R² radicals.

In a further-preferred embodiment of the invention, R^{c} is the same or different at each instance and is selected from the group consisting of a straight-chain alkyl group having 1 to 10 carbon atoms or a branched or cyclic alkyl group having 3 to 10 carbon atoms, where the alkyl group may be substituted in each case by one or more R² radicals, an aromatic or heteroaromatic ring system which has 6 to 30 aromatic ring atoms and may be substituted by one or more R² radicals. More preferably, R^{c} is the same or different at each instance and are selected from the group consisting of a straight-chain alkyl group having 1 to 5 carbon atoms or a branched or cyclic alkyl group having 3 to 5 carbon atoms, where the alkyl group may be substituted in each case by one or more R² radicals, or an aromatic or heteroaromatic ring system which has 6 to 24 aromatic ring atoms, preferably 6 to 18 aromatic ring atoms, more preferably 6 to 13 aromatic ring atoms, and may be substituted in each case by one or more R² radicals.

In a preferred embodiment of the invention, R^{c} is the same or different at each instance and is selected from the group consisting of a straight-chain alkyl group having 1 to 6 carbon atoms or a cyclic alkyl group having 3 to 6 carbon atoms, where the alkyl group may be substituted in each case by one or more R² radicals, or an aromatic or heteroaromatic ring system which has 6 to 24 aromatic ring atoms and may be substituted in each case by one or more R² radicals; at the same time, two R^{c} radicals together may also form a ring system. More preferably, R^{c} is the same or different at each instance and is selected from the group consisting of a straight-chain alkyl group having 1, 2, 3 or 4 carbon atoms or a branched or cyclic alkyl group having 3 to 6 carbon atoms, where the alkyl group may be substituted in each case by one or more R² radicals, but is preferably unsubstituted, or an aromatic ring system which has 6 to 12 aromatic ring atoms, especially 6 aromatic ring atoms, and may be substituted in each case by one or more preferably nonaromatic R² radicals, but is preferably unsubstituted; at the same time, two R^{c} radicals together may form a ring system. Most preferably, R^{c} is the same or different at each instance and is selected from the group consisting of a straight-chain alkyl group having 1, 2, 3 or 4 carbon atoms, or a branched alkyl group having 3 to 6 carbon atoms. Most preferably, R^{c} is a methyl group or is a phenyl group, where two phenyl groups together may form a ring system, preference being given to a methyl group over a phenyl group.

Preferred aromatic or heteroaromatic ring systems represented by the substituent R, R^{a}, R^{b}, R^{c}, or Ar or Ar′ are selected from phenyl, biphenyl, especially ortho-, meta- or para-biphenyl, terphenyl, especially ortho-, meta- or para-terphenyl or branched terphenyl, quaterphenyl, especially ortho-, meta- or para-quaterphenyl or branched quaterphenyl, fluorene which may be joined via the 1, 2, 3 or 4 position, spirobifluorene which may be joined via the 1, 2, 3 or 4 position, naphthalene, especially 1- or 2-bonded naphthalene, indole, benzofuran, benzothiophene, carbazole which may be joined via the 1, 2, 3 or 4 position, dibenzofuran which may be joined via the 1, 2, 3 or 4 position, dibenzothiophene which may be joined via the 1, 2, 3 or 4 position, indenocarbazole, indolocarbazole, pyridine, pyrimidine, pyrazine, pyridazine, triazine, quinoline, isoquinoline, quinazoline, quinoxaline, phenanthrene or triphenylene, each of which may be substituted by one or more R, R¹ or R² radicals. The structures Ar-1 to Ar-78 listed above are particularly preferred, preference being given to structures of the formulae (Ar-1), (Ar-2), (Ar-3), (Ar-12), (Ar-13), (Ar-14), (Ar-15), (Ar-16), (Ar-69), (Ar-70), (Ar-75), and particular preference to structures of the formulae (Ar-1), (Ar-2), (Ar-3), (Ar-12), (Ar-13), (Ar-14), (Ar-15), (Ar-16). With regard to the structures Ar-1 to Ar-78, it should be stated that these are shown with a substituent R¹. In the case of the ring systems Ar, these substituents R¹ should be replaced by R, and in the case of R^{c}, these substituents R¹ should be replaced by R².

Further suitable R, R^{a}, R^{b} groups are groups of the formula —Ar⁴—N(Ar²)(Ar³) where Ar², Ar³ and Ar⁴ are the same or different at each instance and are an aromatic or heteroaromatic ring system which has 5 to 24 aromatic ring atoms and may be substituted in each case by one or more R¹ radicals.

The total number of aromatic ring atoms in Ar², Ar³ and Ar⁴ here is not more than 60 and preferably not more than 40.

Ar⁴ and Ar² here may also be bonded to one another and/or Ar² and Ar³ to one another by a group selected from C(R¹)₂, NR¹, O and S. Preferably, Ar⁴ and Ar² are joined to one another and Ar² and Ar³ to one another in the respective ortho position to the bond to the nitrogen atom. In a further embodiment of the invention, none of the Ar², Ar³ and Ar⁴ groups are bonded to one another.

Preferably, Ar⁴ is an aromatic or heteroaromatic ring system which has 6 to 24 aromatic ring atoms, preferably 6 to 12 aromatic ring atoms, and may be substituted in each case by one or more R¹ radicals. More preferably, Ar⁴ is selected from the group consisting of ortho-, meta- or para-phenylene or ortho-, meta- or para-biphenyl, each of which may be substituted by one or more R¹ radicals, but are preferably unsubstituted. Most preferably, Ar⁴ is an unsubstituted phenylene group.

Preferably, Ar² and Ar³ are the same or different at each instance and are an aromatic or heteroaromatic ring system which has 6 to 24 aromatic ring atoms and may be substituted in each case by one or more R¹ radicals. Particularly preferred Ar² and Ar³ groups are the same or different at each instance and are selected from the group consisting of benzene, ortho-, meta- or para-biphenyl, ortho-, meta- or para-terphenyl or branched terphenyl, ortho-, meta- or para-quaterphenyl or branched quaterphenyl, 1-, 2-, 3- or 4-fluorenyl, 1-, 2-, 3- or 4-spirobifluorenyl, 1- or 2-naphthyl, indole, benzofuran, benzothiophene, 1-, 2-, 3- or 4-carbazole, 1-, 2-, 3- or 4-dibenzofuran, 1-, 2-, 3- or 4-dibenzothiophene, indenocarbazole, indolocarbazole, 2-, 3- or 4-pyridine, 2-, 4- or 5-pyrimidine, pyrazine, pyridazine, triazine, phenanthrene or triphenylene, each of which may be substituted by one or more R¹ radicals. Most preferably, Ar² and Ar³ are the same or different at each instance and are selected from the group consisting of benzene, biphenyl, especially ortho-, meta- or para-biphenyl, terphenyl, especially ortho-, meta- or para-terphenyl or branched terphenyl, quaterphenyl, especially ortho-, meta- or para-quaterphenyl or branched quaterphenyl, fluorene, especially 1-, 2-, 3- or 4-fluorene, or spirobifluorene, especially 1-, 2-, 3- or 4-spirobifluorene.

In a further preferred embodiment of the invention, R¹ is the same or different at each instance and is selected from the group consisting of H, D, F, CN, a straight-chain alkyl group having 1 to 10 carbon atoms or a branched or cyclic alkyl group having 3 to 10 carbon atoms, where the alkyl group may be substituted in each case by one or more R² radicals, or an aromatic or heteroaromatic ring system which has 6 to 24 aromatic ring atoms and may be substituted in each case by one or more R² radicals. In a particularly preferred embodiment of the invention, R¹ is the same or different at each instance and is selected from the group consisting of H, a straight-chain alkyl group having 1 to 6 carbon atoms, especially having 1, 2, 3 or 4 carbon atoms, or a branched or cyclic alkyl group having 3 to 6 carbon atoms, where the alkyl group may be substituted by one or more R⁵ radicals, but is preferably unsubstituted, or an aromatic or heteroaromatic ring system which has 6 to 13 aromatic ring atoms and may be substituted in each case by one or more R⁵ radicals, but is preferably unsubstituted.

In a further preferred embodiment of the invention, R² is the same or different at each instance and is H, an alkyl group having 1 to 4 carbon atoms or an aryl group having 6 to 10 carbon atoms, which may be substituted by an alkyl group having 1 to 4 carbon atoms, but is preferably unsubstituted.

At the same time, in compounds of the invention that are processed by vacuum evaporation, the alkyl groups preferably have not more than five carbon atoms, more preferably not more than 4 carbon atoms, most preferably not more than 1 carbon atom. For compounds that are processed from solution, suitable compounds are also those substituted by alkyl groups, especially branched alkyl groups, having up to 10 carbon atoms or those substituted by oligoarylene groups, for example ortho-, meta- or para-terphenyl or branched terphenyl or quaterphenyl groups.

It may further be the case that the compound includes exactly two or exactly three structures of formula (I), (II-1) to (II-18), (III-1) to (III-48), (IV-1) to (IV-48), (V-1) to (V-12), (VI-1) to (VI-12) and/or (VII-1) to (VII-12).

In a preferred configuration, the compounds are selected from compounds of the formulae (D-1) and (D-17):

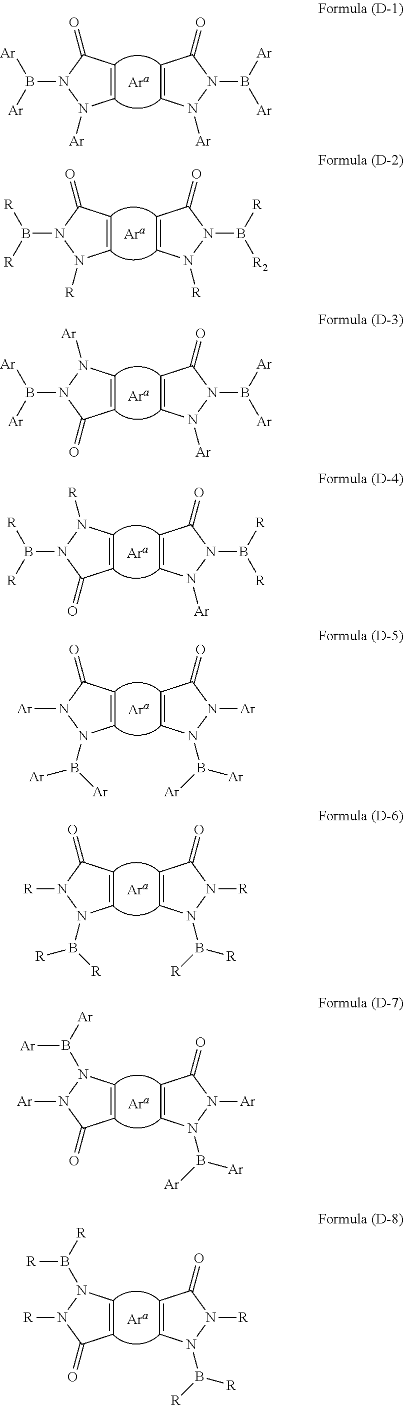

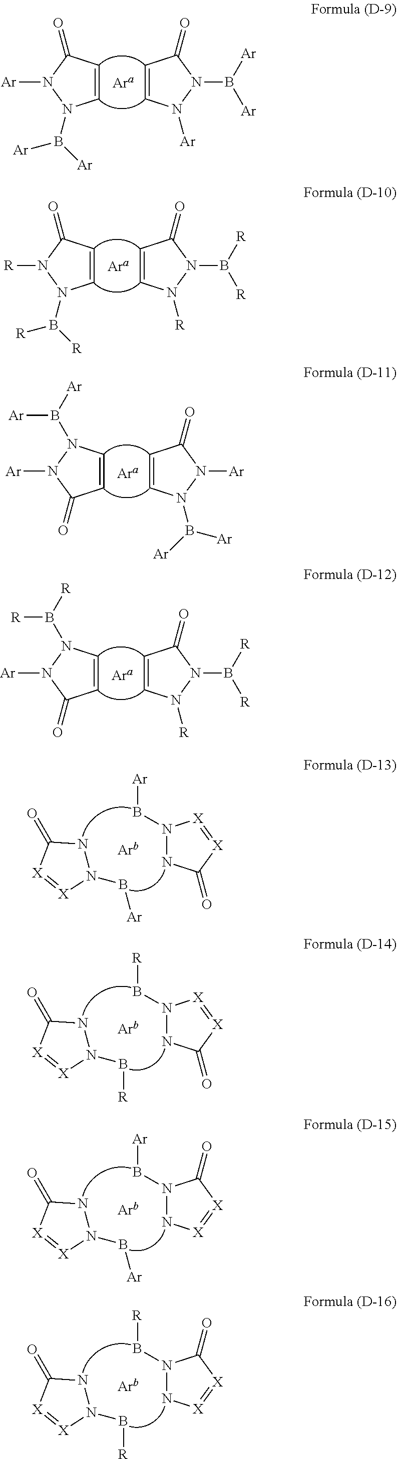

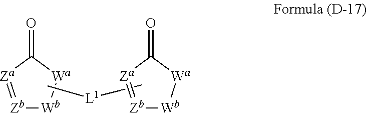

where the L¹ group is a connecting group, preferably a bond or an aromatic or heteroaromatic ring system which has 5 to 40, preferably 5 to 30, aromatic ring atoms and may be substituted by one or more R¹ radicals, and the further symbols used have the definitions given above, especially for formula (I) and/or formulae (II-1) to (II-18).

In a further preferred embodiment of the invention, L¹ is a bond or an aromatic or heteroaromatic ring system which has 5 to 14 aromatic or heteroaromatic ring atoms, preferably an aromatic ring system which has 6 to 12 carbon atoms, and which may be substituted by one or more R¹ radicals, but is preferably unsubstituted, where R¹ may have the definition given above, especially for formula (I). More preferably, L¹ is an aromatic ring system having 6 to 10 aromatic ring atoms or a heteroaromatic ring system having 6 to 13 heteroaromatic ring atoms, each of which may be substituted by one or more R² radicals, but is preferably unsubstituted, where R² may have the definition given above, especially for formula (I). Further preferably, the symbol L¹ shown in formula (D17) inter alia is the same or different at each instance and is a bond or an aryl or heteroaryl radical having 5 to 24 ring atoms, preferably 6 to 13 ring atoms, more preferably 6 to 10 ring atoms, such that an aromatic or heteroaromatic group of an aromatic or heteroaromatic ring system is bonded to the respective atom of the further group directly, i.e. via an atom of the aromatic or heteroaromatic group.

It may additionally be the case that the L¹ group shown in formula (D17) comprises an aromatic ring system having not more than four, preferably not more than three, more preferably not more than two, fused aromatic and/or heteroaromatic 6-membered rings, and preferably does not comprise any fused aromatic or heteroaromatic ring system. Accordingly, naphthyl structures are preferred over anthracene structures. In addition, fluorenyl, spirobifluorenyl, dibenzofuranyl and/or dibenzothienyl structures are preferred over naphthyl structures.

Particular preference is given to structures having no fusion, for example phenyl, biphenyl, terphenyl and/or quaterphenyl structures.

Examples of suitable aromatic or heteroaromatic ring systems L¹ are selected from the group consisting of ortho-, meta- or para-phenylene, ortho-, meta- or para-biphenylene, terphenylene, especially branched terphenylene, quaterphenylene, especially branched quaterphenylene, fluorenylene, spirobifluorenylene, dibenzofuranylene, dibenzothienylene and carbazolylene, each of which may be substituted by one or more R¹ radicals, but are preferably unsubstituted.

The abovementioned preferred embodiments may be combined with one another as desired within the restrictions defined in claim 1. In a particularly preferred embodiment of the invention, the abovementioned preferences occur simultaneously.

Examples of preferred compounds according to the embodiments detailed above are the compounds shown in the following table:

| | |
|---|---|
| 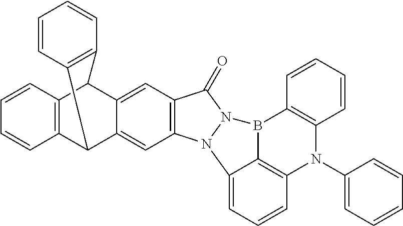 [SMILES: O=c1c2cc3c(cc2n2n1B1c4ccccc4N(c4ccccc4)c4cccc-2c41)C1c2ccccc2C3c2ccccc21] | 1 |
| 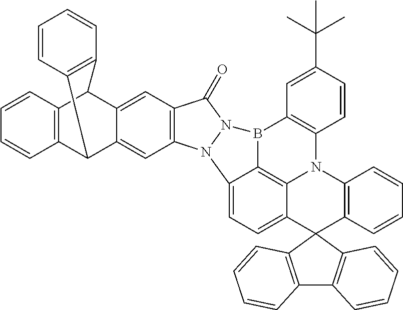 [SMILES: CC(C)(C)c1ccc2c(c1)B1c3c(ccc4c3N2c2ccccc2C42c3ccccc3-c3ccccc32)-n2c3cc4c(cc3c(=O)n21)C1c2ccccc2C4c2ccccc21] | 2 |
| 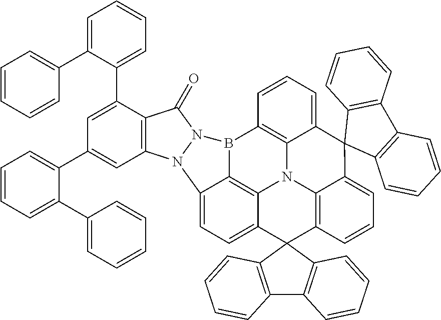 [SMILES: O=c1c2c(-c3ccccc3-c3ccccc3)cc(-c3ccccc3-c3ccccc3)cc2n2n1B1c3cccc4c3N3c5c(cccc5C5(c6ccccc6-c6ccccc65)c5ccc-2c1c53)C41c2ccccc2-c2ccccc21] | 3 |
| 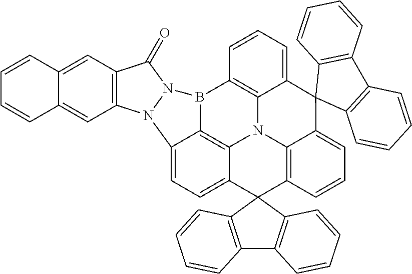 [SMILES: O=c1c2cc3ccccc3cc2n2n1B1c3cccc4c3N3c5c(cccc5C5(c6ccccc6-c6ccccc65)c5ccc-2c1c53)C41c2ccccc2-c2ccccc21] | 4 |
| 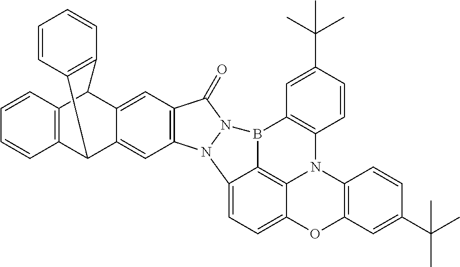 [SMILES: CC(C)(C)c1ccc2c(c1)Oc1ccc3c4c1N2c1ccc(C(C)(C)C)cc1B4n1c(=O)c2cc4c(cc2n1-3)C1c2ccccc2C4c2ccccc21] | 5 |
| 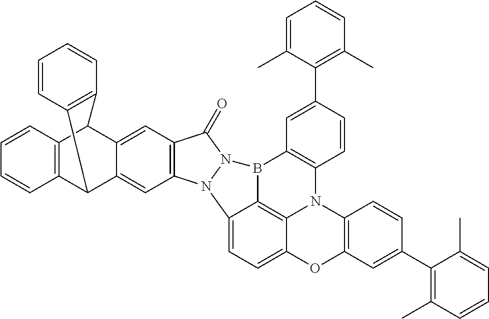 [SMILES: Cc1cccc(C)c1-c1ccc2c(c1)Oc1ccc3c4c1N2c1ccc(-c2c(C)cccc2C)cc1B4n1c(=O)c2cc4c(cc2n1-3)C1c2ccccc2C4c2ccccc21] | 6 |
| 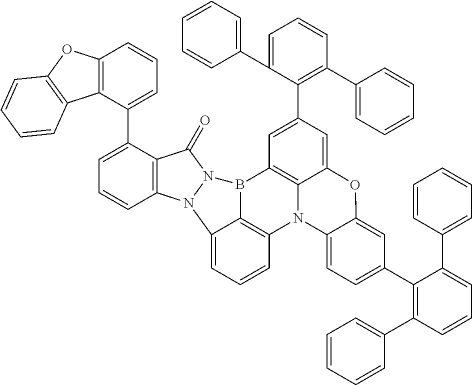 [SMILES: O=c1c2c(-c3cccc4oc5ccccc5c34)cccc2n2n1B1c3cc(-c4c(-c5ccccc5)cccc4-c4ccccc4)cc4c3N(c3ccc(-c5c(-c6ccccc6)cccc5-c5ccccc5)cc3O4)c3cccc-2c31] | 7 |
| 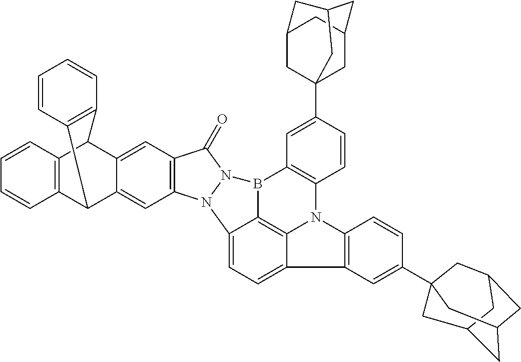 [SMILES: O=c1c2cc3c(cc2n2n1B1c4cc(C56CC7CC(CC(C7)C5)C6)ccc4-n4c5ccc(C67CC8CC(CC(C8)C6)C7)cc5c5ccc-2c1c54)C1c2ccccc2C3c2ccccc21] | 8 |
| 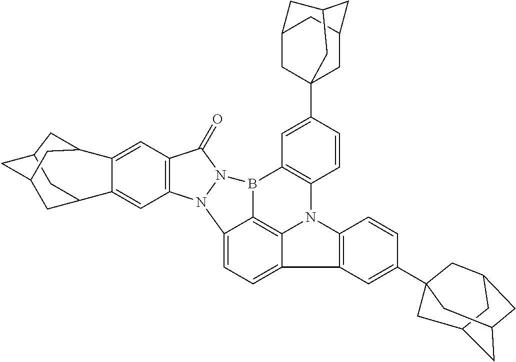 [SMILES: O=c1c2cc3c(cc2n2n1B1c4cc(C56CC7CC(CC(C7)C5)C6)ccc4-n4c5ccc(C67CC8CC(CC(C8)C6)C7)cc5c5ccc-2c1c54)C1CC2CC(CC3C2)C1] | 9 |
| 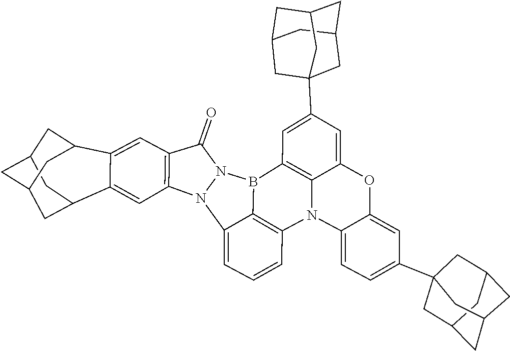 [SMILES: O=c1c2cc3c(cc2n2n1B1c4cc(C56CC7CC(CC(C7)C5)C6)cc5c4N(c4ccc(C67CC8CC(CC(C8)C6)C7)cc4O5)c4cccc-2c41)C1CC2CC(CC3C2)C1] | 10 |
| 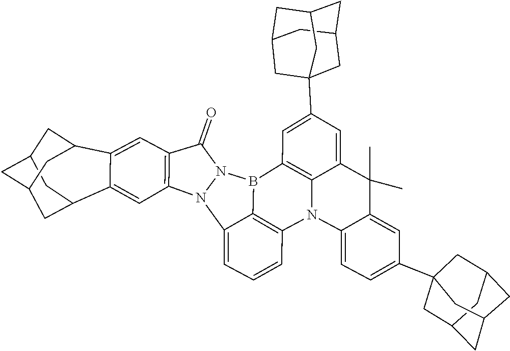 [SMILES: CC1(C)c2cc(C34CC5CC(CC(C5)C3)C4)ccc2N2c3cccc4c3B(c3cc(C56CC7CC(CC(C7)C5)C6)cc1c32)n1c(=O)c2cc3c(cc2n1-4)C1CC2CC(CC3C2)C1] | 11 |
| 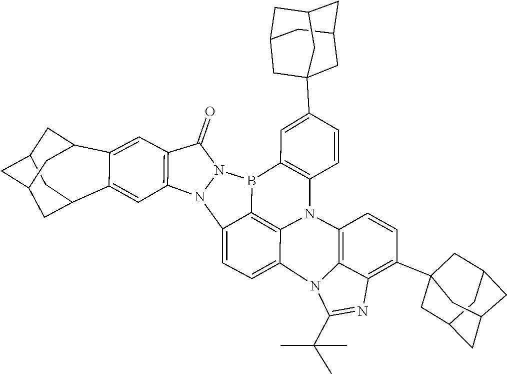 [SMILES: CC(C)(C)c1nc2c(C34CC5CC(CC(C5)C3)C4)ccc3c2n1-c1ccc2c4c1N3c1ccc(C35CC6CC(CC(C6)C3)C5)cc1B4n1c(=O)c3cc4c(cc3n1-2)C1CC2CC(CC4C2)C1] | 12 |
| 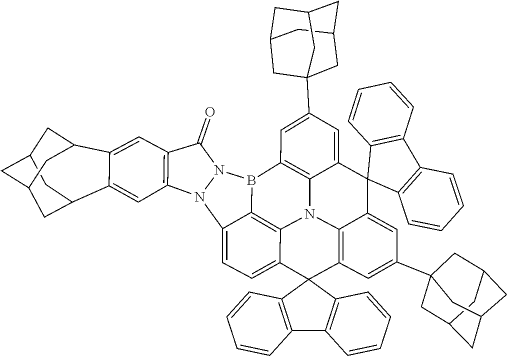 [SMILES: O=c1c2cc3c(cc2n2n1B1c4cc(C56CC7CC(CC(C7)C5)C6)cc5c4N4c6c(cc(C78CC9CC(CC(C9)C7)C8)cc6C6(c7ccccc7-c7ccccc76)c6ccc-2c1c64)C51c2ccccc2-c2ccccc21)C1CC2CC(CC3C2)C1] | 13 |
| 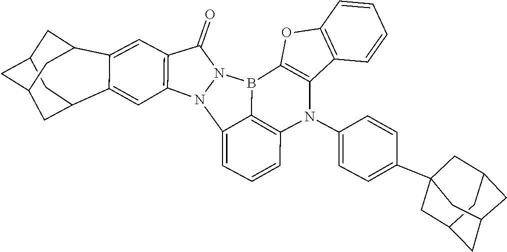 [SMILES: O=c1c2cc3c(cc2n2n1B1c4oc5ccccc5c4N(c4ccc(C56CC7CC(CC(C7)C5)C6)cc4)c4cccc-2c41)C1CC2CC(CC3C2)C1] | 14 |
| 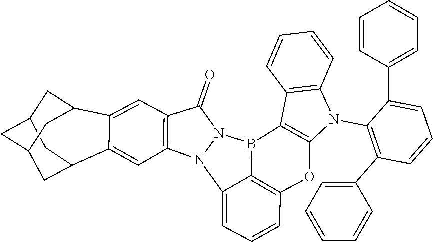 [SMILES: O=c1c2cc3c(cc2n2n1B1c4c(cccc4-2)Oc2c1c1ccccc1n2-c1c(-c2ccccc2)cccc1-c1ccccc1)C1CC2CC(CC3C2)C1] | 15 |
| 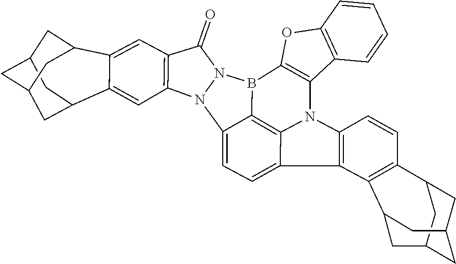 [SMILES: O=c1c2cc3c(cc2n2n1B1c4oc5ccccc5c4-n4c5ccc6c(c5c5ccc-2c1c54)C1CC2CC(CC6C2)C1)C1CC2CC(CC3C2)C1] | 16 |
| 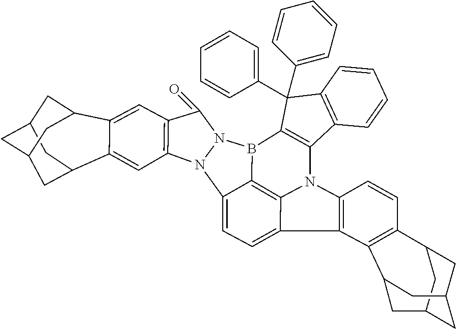 [SMILES: O=c1c2cc3c(cc2n2n1B1C4=C(c5ccccc5C4(c4ccccc4)c4ccccc4)n4c5ccc6c(c5c5ccc-2c1c54)C1CC2CC(CC6C2)C1)C1CC2CC(CC3C2)C1] | 20 |
| 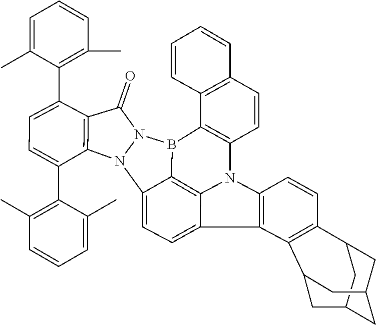 [SMILES: Cc1cccc(C)c1-c1ccc(-c2c(C)cccc2C)c2c1c(=O)n1n2-c2ccc3c4c5c(ccc4n4c3c2B1c1c-4ccc2ccccc12)C1CC2CC(C1)CC5C2] | 21 |
| 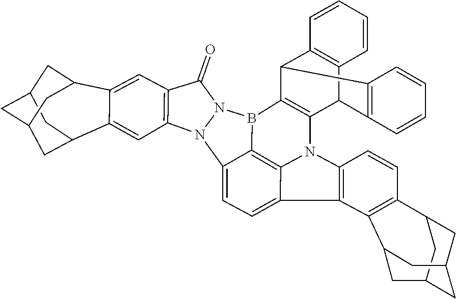 [SMILES: O=c1c2cc3c(cc2n2n1B1C4=C(C5c6ccccc6C4c4ccccc45)n4c5ccc6c(c5c5ccc-2c1c54)C1CC2CC(CC6C2)C1)C1CC2CC(CC3C2)C1] | 22 |
| 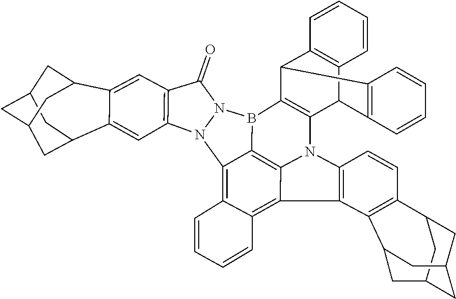 [SMILES: O=c1c2cc3c(cc2n2n1B1C4=C(C5c6ccccc6C4c4ccccc45)n4c5ccc6c(c5c5c7ccccc7c-2c1c54)C1CC2CC(CC6C2)C1)C1CC2CC(CC3C2)C1] | 23 |
| 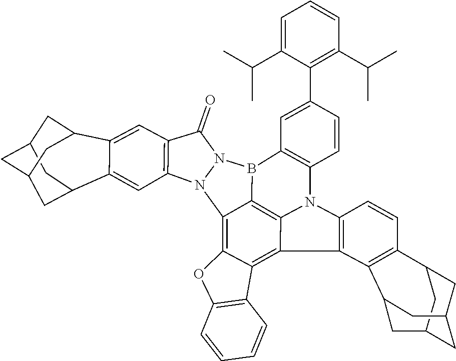 [SMILES: CC(C)c1cccc(C(C)C)c1-c1ccc2c(c1)B1c3c(c4oc5ccccc5c4c4c5c6c(ccc5n-2c34)C2CC3CC(C2)CC6C3)-n2c3cc4c(cc3c(=O)n21)C1CC2CC(C1)CC4C2] | 24 |
| 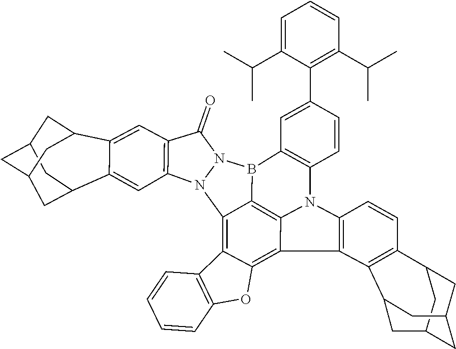 [SMILES: CC(C)c1cccc(C(C)C)c1-c1ccc2c(c1)B1c3c(c4c5ccccc5oc4c4c5c6c(ccc5n-2c34)C2CC3CC(C2)CC6C3)-n2c3cc4c(cc3c(=O)n21)C1CC2CC(C1)CC4C2] | 25 |
| 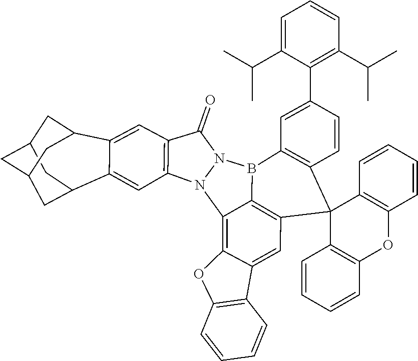 [SMILES: CC(C)c1cccc(C(C)C)c1-c1ccc2c(c1)B1c3c(cc4c(oc5ccccc54)c3-n3c4cc5c(cc4c(=O)n31)C1CC3CC(C1)CC5C3)C21c2ccccc2Oc2ccccc21] | 26 |
| 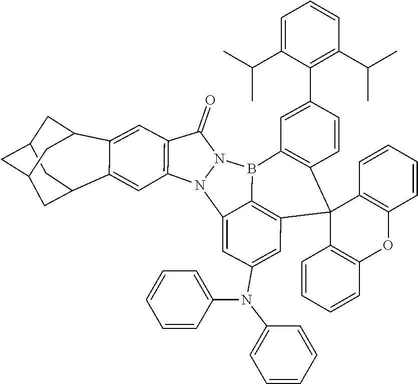 [SMILES: CC(C)c1cccc(C(C)C)c1-c1ccc2c(c1)B1c3c(cc(N(c4ccccc4)c4ccccc4)cc3C23c2ccccc2Oc2ccccc23)-n2c3cc4c(cc3c(=O)n21)C1CC2CC(C1)CC4C2] | 27 |
| 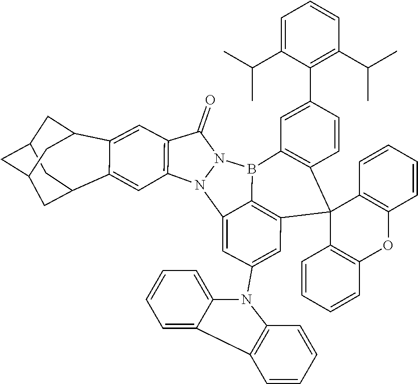 [SMILES: CC(C)c1cccc(C(C)C)c1-c1ccc2c(c1)B1c3c(cc(-n4c5ccccc5c5ccccc54)cc3C23c2ccccc2Oc2ccccc23)-n2c3cc4c(cc3c(=O)n21)C1CC2CC(C1)CC4C2] | 28 |
| 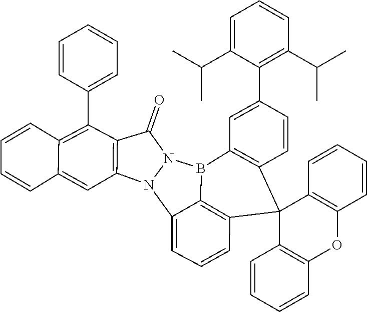 [SMILES: CC(C)c1cccc(C(C)C)c1-c1ccc2c(c1)B1c3c(cccc3C23c2ccccc2Oc2ccccc23)-n2c3cc4ccccc4c(-c4ccccc4)c3c(=O)n21] | 29 |
| 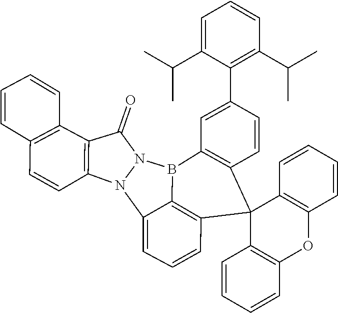 [SMILES: CC(C)c1cccc(C(C)C)c1-c1ccc2c(c1)B1c3c(cccc3C23c2ccccc2Oc2ccccc23)-n2c3ccc4ccccc4c3c(=O)n21] | 30 |
| 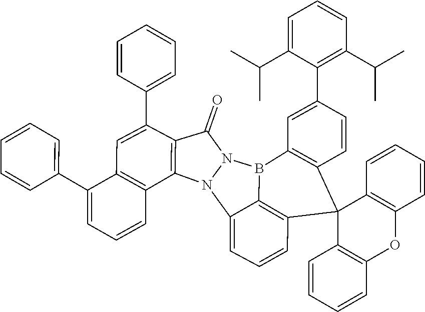 [SMILES: CC(C)c1cccc(C(C)C)c1-c1ccc2c(c1)B1c3c(cccc3C23c2ccccc2Oc2ccccc23)-n2c3c(c(-c4ccccc4)cc4c(-c5ccccc5)cccc43)c(=O)n21] | 31 |
| 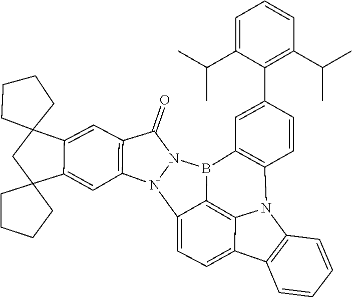 [SMILES: CC(C)c1cccc(C(C)C)c1-c1ccc2c(c1)B1c3c(ccc4c5ccccc5n-2c34)-n2c3cc4c(cc3c(=O)n21)C1(CCCC1)CC41CCCC1] | 32 |
| 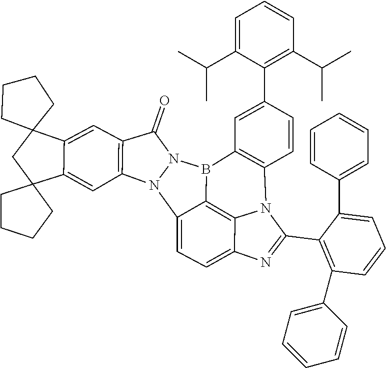 [SMILES: CC(C)c1cccc(C(C)C)c1-c1ccc2c(c1)B1c3c(ccc4nc(-c5c(-c6ccccc6)cccc5-c5ccccc5)n-2c34)-n2c3cc4c(cc3c(=O)n21)C1(CCCC1)CC41CCCC1] | 33 |
| 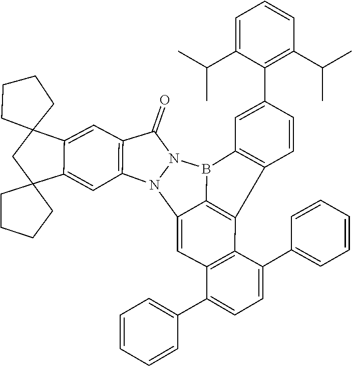 [SMILES: CC(C)c1cccc(C(C)C)c1-c1ccc2c(c1)B1c3c(cc4c(-c5ccccc5)ccc(-c5ccccc5)c4c3-2)-n2c3cc4c(cc3c(=O)n21)C1(CCCC1)CC41CCCC1] | 34 |
| 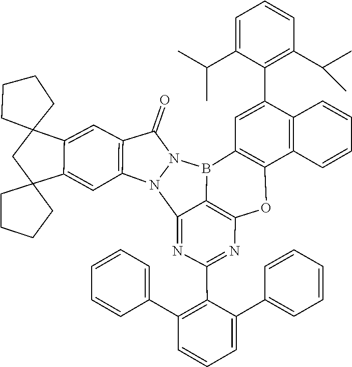 [SMILES: CC(C)c1cccc(C(C)C)c1-c1cc2c(c3ccccc13)Oc1nc(-c3c(-c4ccccc4)cccc3-c3ccccc3)nc3c1B2n1c(=O)c2cc4c(cc2n1-3)C1(CCCC1)CC41CCCC1] | 35 |
| 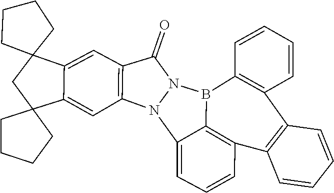 [SMILES: O=c1c2cc3c(cc2n2n1B1c4ccccc4-c4ccccc4-c4cccc-2c41)C1(CCCC1)CC31CCCC1] | 36 |
| 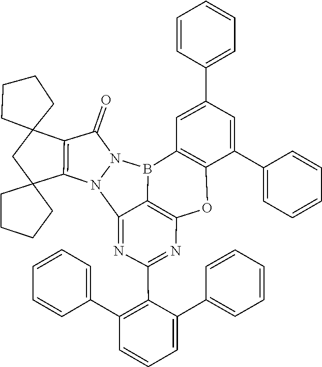 [SMILES: O=c1c2c(n3n1B1c4cc(-c5ccccc5)cc(-c5ccccc5)c4Oc4nc(-c5c(-c6ccccc6)cccc5-c5ccccc5)nc-3c41)C1(CCCC1)CC21CCCC1] | 37 |
| 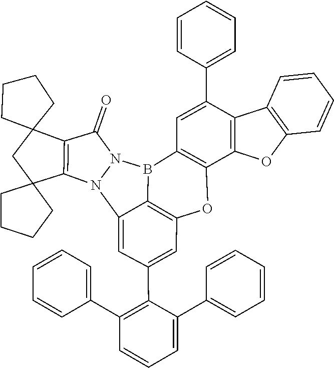 [SMILES: O=c1c2c(n3n1B1c4cc(-c5ccccc5)c5c(oc6ccccc65)c4Oc4cc(-c5c(-c6ccccc6)cccc5-c5ccccc5)cc-3c41)C1(CCCC1)CC21CCCC1] | 38 |
| 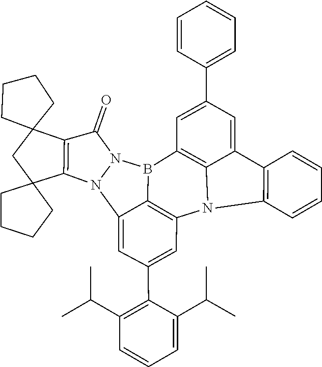 [SMILES: CC(C)c1cccc(C(C)C)c1-c1cc2c3c(c1)-n1c4c(c(=O)n1B3c1cc(-c3ccccc3)cc3c5ccccc5n-2c13)C1(CCCC1)CC41CCCC1] | 39 |
| 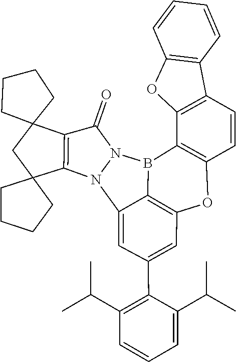 [SMILES: CC(C)c1cccc(C(C)C)c1-c1cc2c3c(c1)-n1c4c(c(=O)n1B3c1c(ccc3c1oc1ccccc13)O2)C1(CCCC1)CC41CCCC1] | 40 |
| 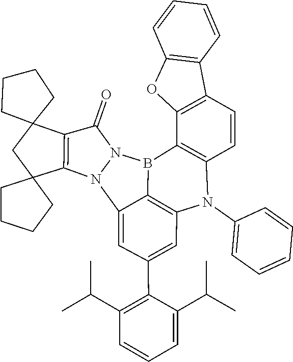 [SMILES: CC(C)c1cccc(C(C)C)c1-c1cc2c3c(c1)-n1c4c(c(=O)n1B3c1c(ccc3c1oc1ccccc13)N2c1ccccc1)C1(CCCC1)CC41CCCC1] | 41 |
| 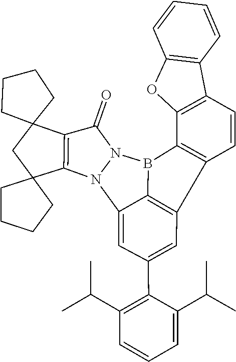 [SMILES: CC(C)c1cccc(C(C)C)c1-c1cc2c3c(c1)-n1c4c(c(=O)n1B3c1c-2ccc2c1oc1ccccc12)C1(CCCC1)CC41CCCC1] | 42 |
| 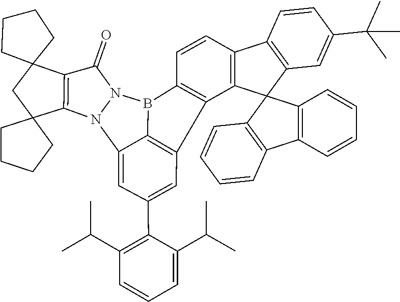 [SMILES: CC(C)c1cccc(C(C)C)c1-c1cc2c3c(c1)-n1c4c(c(=O)n1B3c1ccc3c(c1-2)C1(c2ccccc2-c2ccccc21)c1cc(C(C)(C)C)ccc1-3)C1(CCCC1)CC41CCCC1] | 43 |
| 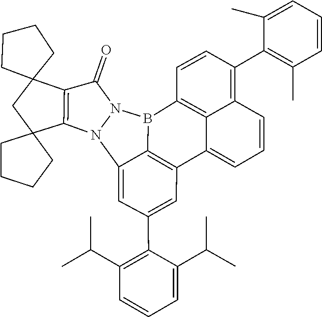 [SMILES: Cc1cccc(C)c1-c1ccc2c3c(cccc13)-c1cc(-c3c(C(C)C)cccc3C(C)C)cc3c1B2n1c(=O)c2c(n1-3)C1(CCCC1)CC21CCCC1] | 44 |
| 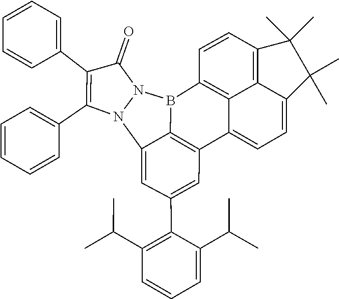 [SMILES: CC(C)c1cccc(C(C)C)c1-c1cc2c3c(c1)-n1c(-c4ccccc4)c(-c4ccccc4)c(=O)n1B3c1ccc3c4c(ccc-2c14)C(C)(C)C3(C)C] | 45 |
| 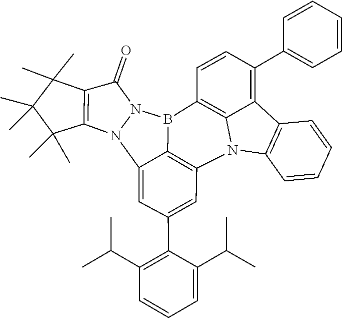 [SMILES: CC(C)c1cccc(C(C)C)c1-c1cc2c3c(c1)-n1c4c(c(=O)n1B3c1ccc(-c3ccccc3)c3c5ccccc5n-2c13)C(C)(C)C(C)(C)C4(C)C] | 46 |
| 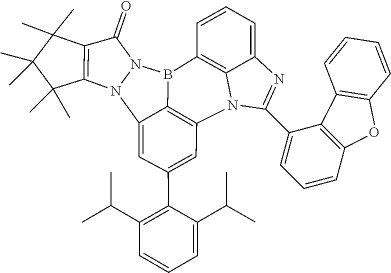 [SMILES: CC(C)c1cccc(C(C)C)c1-c1cc2c3c(c1)-n1c4c(c(=O)n1B3c1cccc3nc(-c5cccc6oc7ccccc7c56)n-2c13)C(C)(C)C(C)(C)C4(C)C] | 47 |
| 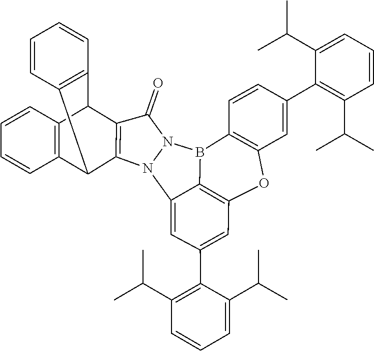 [SMILES: CC(C)c1cccc(C(C)C)c1-c1ccc2c(c1)Oc1cc(-c3c(C(C)C)cccc3C(C)C)cc3c1B2n1c(=O)c2c(n1-3)C1c3ccccc3C2c2ccccc21] | 48 |
| 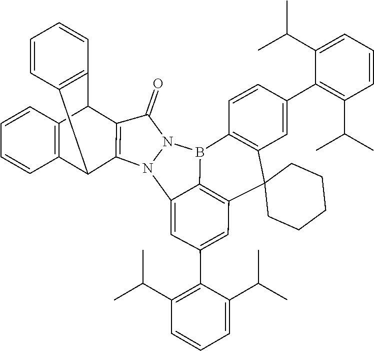 [SMILES: CC(C)c1cccc(C(C)C)c1-c1ccc2c(c1)C1(CCCCC1)c1cc(-c3c(C(C)C)cccc3C(C)C)cc3c1B2n1c(=O)c2c(n1-3)C1c3ccccc3C2c2ccccc21] | 49 |
| 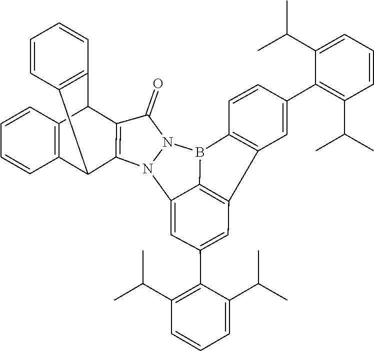 [SMILES: CC(C)c1cccc(C(C)C)c1-c1ccc2c(c1)-c1cc(-c3c(C(C)C)cccc3C(C)C)cc3c1B2n1c(=O)c2c(n1-3)C1c3ccccc3C2c2ccccc21] | 50 |
| 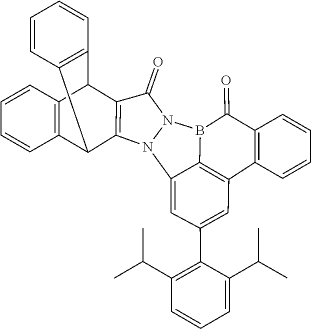 [SMILES: CC(C)c1cccc(C(C)C)c1-c1cc2c3c(c1)-n1c4c(c(=O)n1B3C(=O)c1ccccc1-2)C1c2ccccc2C4c2ccccc21] | 51 |
| 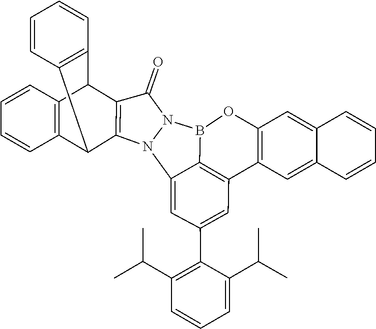 [SMILES: CC(C)c1cccc(C(C)C)c1-c1cc2c3c(c1)-n1c4c(c(=O)n1B3Oc1cc3ccccc3cc1-2)C1c2ccccc2C4c2ccccc21] | 52 |
| 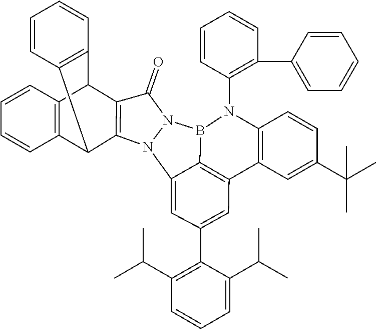 [SMILES: CC(C)c1cccc(C(C)C)c1-c1cc2c3c(c1)-n1c4c(c(=O)n1B3N(c1ccccc1-c1ccccc1)c1ccc(C(C)(C)C)cc1-2)C1c2ccccc2C4c2ccccc21] | 53 |
| 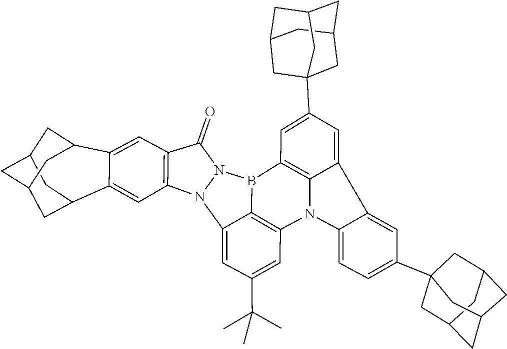 [SMILES: CC(C)(C)c1cc2c3c(c1)-n1c4cc5c(cc4c(=O)n1B3c1cc(C34CC6CC(CC(C6)C3)C4)cc3c4cc(C67CC8CC(CC(C8)C6)C7)ccc4n-2c13)C1CC2CC(C1)CC5C2] | 54 |
| 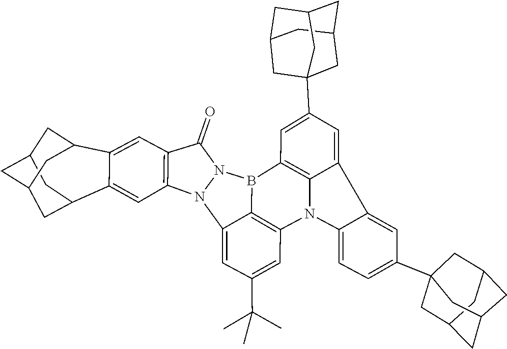 [SMILES: CC(C)(C)c1cc2c3c(c1)-n1c4cc5c(cc4c(=O)n1B3c1cc(C34CC6CC(CC(C6)C3)C4)cc3c4cc(C67CC8CC(CC(C8)C6)C7)ccc4n-2c13)C1CC2CC(C1)CC5C2] | 55 |
| 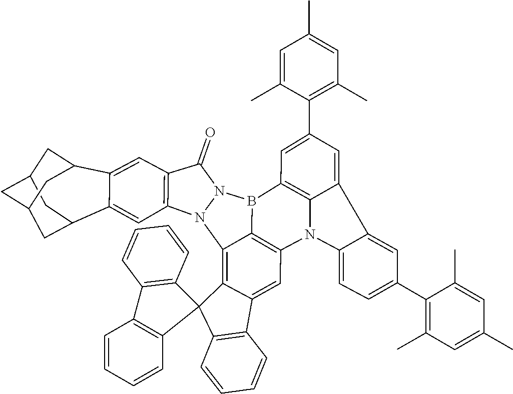 [SMILES: Cc1cc(C)c(-c2ccc3c(c2)c2cc(-c4c(C)cc(C)cc4C)cc4c2n3-c2cc3c(c5c2B4n2c(=O)c4cc6c(cc4n2-5)C2CC4CC(CC6C4)C2)C2(c4ccccc4-c4ccccc42)c2ccccc2-3)c(C)c1] | 56 |
| 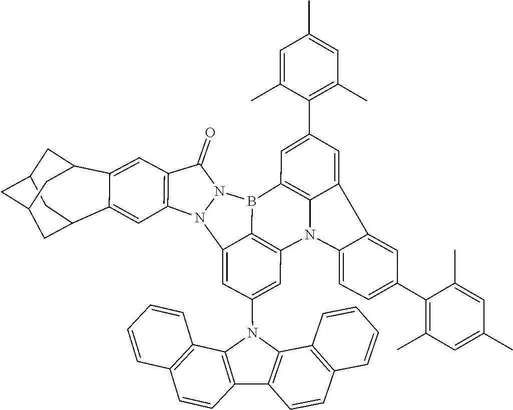 [SMILES: Cc1cc(C)c(-c2ccc3c(c2)c2cc(-c4c(C)cc(C)cc4C)cc4c2n3-c2cc(-n3c5c6ccccc6ccc5c5ccc6ccccc6c53)cc3c2B4n2c(=O)c4cc5c(cc4n2-3)C2CC3CC(CC5C3)C2)c(C)c1] | 57 |
| 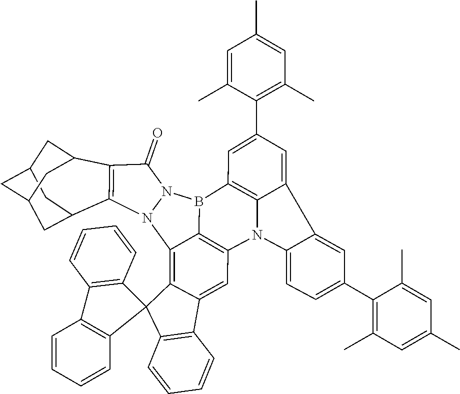 [SMILES: Cc1cc(C)c(-c2ccc3c(c2)c2cc(-c4c(C)cc(C)cc4C)cc4c2n3-c2cc3c(c5c2B4n2c(=O)c4c(n2-5)C2CC5CC(CC4C5)C2)C2(c4ccccc4-c4ccccc42)c2ccccc2-3)c(C)c1] | 58 |
| 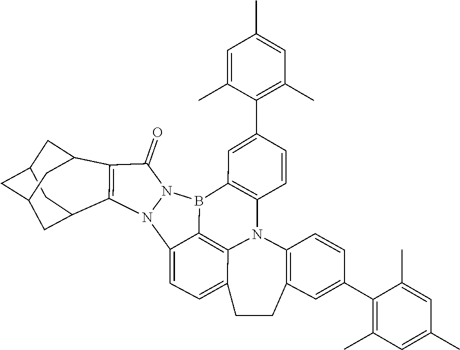 [SMILES: Cc1cc(C)c(-c2ccc3c(c2)CCc2ccc4c5c2N3c2ccc(-c3c(C)cc(C)cc3C)cc2B5n2c(=O)c3c(n2-4)C2CC4CC(CC3C4)C2)c(C)c1] | 59 |
| 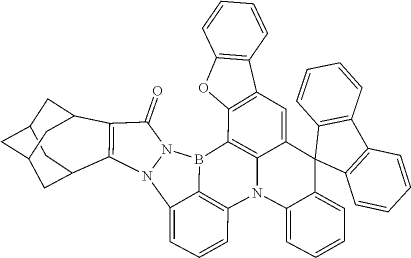 [SMILES: O=c1c2c(n3n1B1c4c(cccc4-3)N3c4ccccc4C4(c5ccccc5-c5ccccc54)c4cc5c(oc6ccccc65)c1c43)C1CC3CC(CC2C3)C1] | 60 |
| 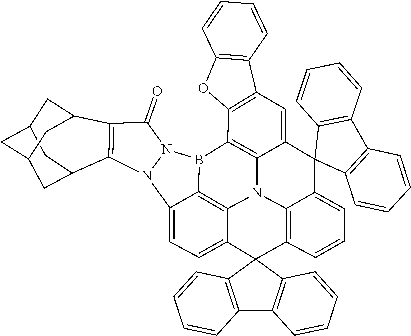 [SMILES: O=c1c2c(n3n1B1c4c-3ccc3c4N4c5c(cccc5C5(c6ccccc6-c6ccccc65)c5cc6c(oc7ccccc76)c1c54)C31c3ccccc3-c3ccccc31)C1CC3CC(CC2C3)C1] | 61 |
| 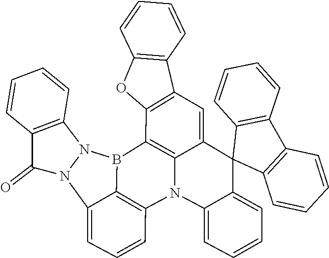 [SMILES: O=c1c2ccccc2n2n1-c1cccc3c1B2c1c2c(cc4c1oc1ccccc14)C1(c4ccccc4-c4ccccc41)c1ccccc1N32] | 62 |
| 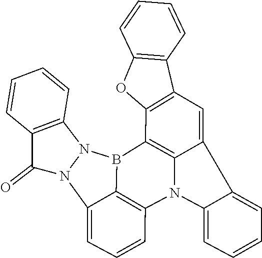 [SMILES: O=c1c2ccccc2n2n1-c1cccc3c1B2c1c2oc4ccccc4c2cc2c4ccccc4n-3c12] | 63 |
| 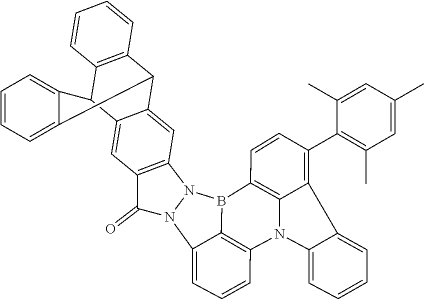 [SMILES: Cc1cc(C)c(-c2ccc3c4c2c2ccccc2n4-c2cccc4c2B3n2c3cc5c(cc3c(=O)n2-4)C2c3ccccc3C5c3ccccc32)c(C)c1] | 64 |
| 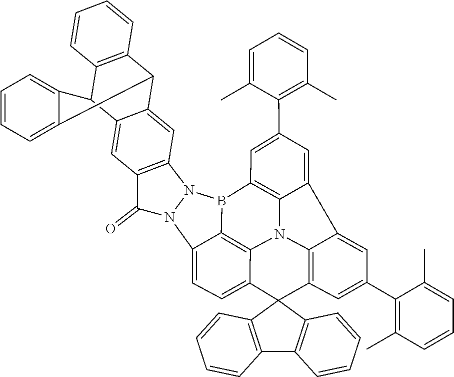 [SMILES: Cc1cccc(C)c1-c1cc2c3c(c1)c1cc(-c4c(C)cccc4C)cc4c1n3-c1c(ccc3c1B2n1c2cc5c(cc2c(=O)n1-3)C1c2ccccc2C5c2ccccc21)C41c2ccccc2-c2ccccc21] | 65 |
| 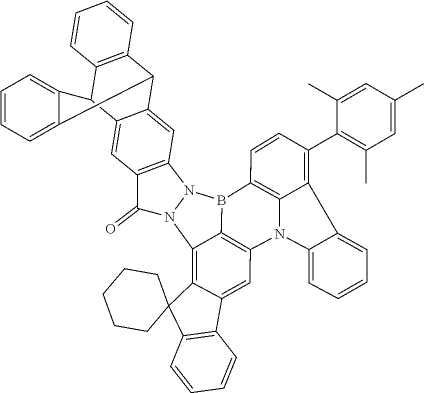 [SMILES: Cc1cc(C)c(-c2ccc3c4c2c2ccccc2n4-c2cc4c(c5c2B3n2c3cc6c(cc3c(=O)n2-5)C2c3ccccc3C6c3ccccc32)C2(CCCCC2)c2ccccc2-4)c(C)c1] | 66 |
| 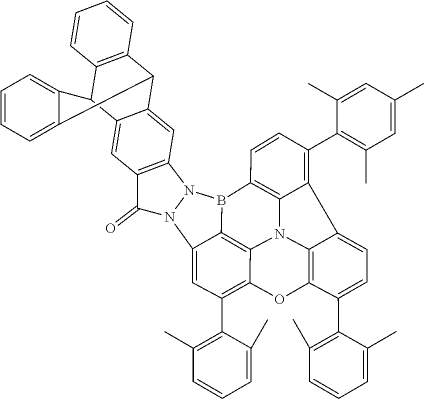 [SMILES: Cc1cc(C)c(-c2ccc3c4c2c2ccc(-c5c(C)cccc5C)c5c2n4-c2c(c(-c4c(C)cccc4C)cc4c2B3n2c3cc6c(cc3c(=O)n2-4)C2c3ccccc3C6c3ccccc32)O5)c(C)c1] | 67 |
| 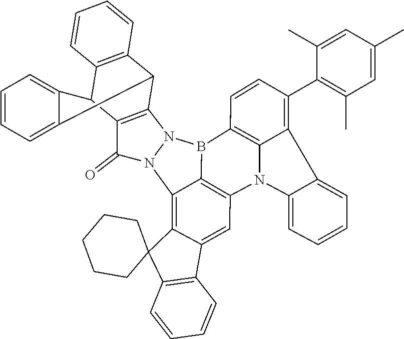 [SMILES: Cc1cc(C)c(-c2ccc3c4c2c2ccccc2n4-c2cc4c(c5c2B3n2c3c(c(=O)n2-5)C2c5ccccc5C3c3ccccc32)C2(CCCCC2)c2ccccc2-4)c(C)c1] | 68 |
| 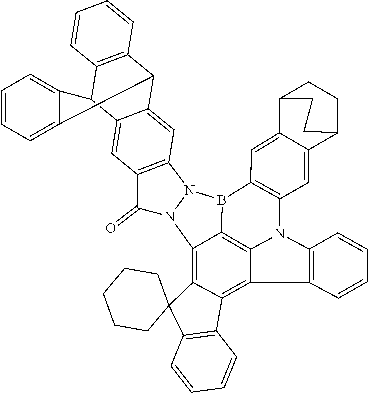 [SMILES: O=c1c2cc3c(cc2n2n1-c1c4c(c5c6ccccc6n6c5c1B2c1cc2c(cc1-6)C1CCC2CC1)-c1ccccc1C41CCCCC1)C1c2ccccc2C3c2ccccc21] | 69 |
| 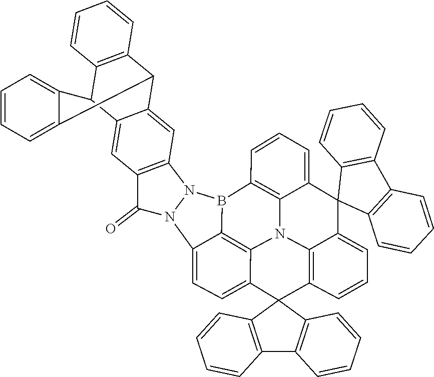 [SMILES: O=c1c2cc3c(cc2n2n1-c1ccc4c5c1B2c1cccc2c1N5c1c(cccc1C41c4ccccc4-c4ccccc41)C21c2ccccc2-c2ccccc21)C1c2ccccc2C3c2ccccc21] | 70 |
| 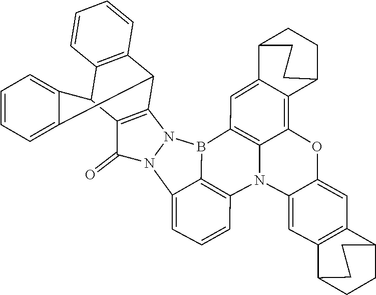 [SMILES: O=c1c2c(n3n1-c1cccc4c1B3c1cc3c(c5c1N4c1cc4c(cc1O5)C1CCC4CC1)C1CCC3CC1)C1c3ccccc3C2c2ccccc21] | 71 |
| 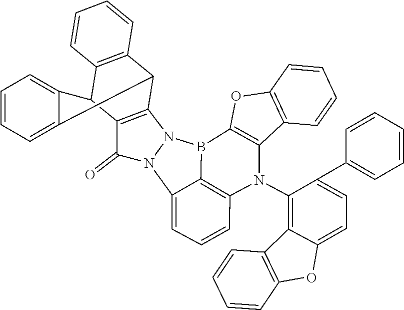 [SMILES: O=c1c2c(n3n1-c1cccc4c1B3c1oc3ccccc3c1N4c1c(-c3ccccc3)ccc3oc4ccccc4c13)C1c3ccccc3C2c2ccccc21] | 72 |
| 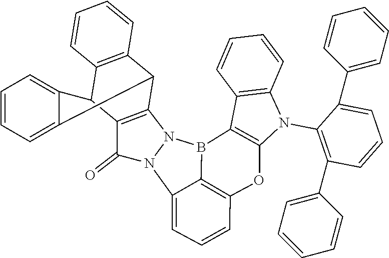 [SMILES: O=c1c2c(n3n1-c1cccc4c1B3c1c(n(-c3c(-c5ccccc5)cccc3-c3ccccc3)c3ccccc13)O4)C1c3ccccc3C2c2ccccc21] | 73 |
| 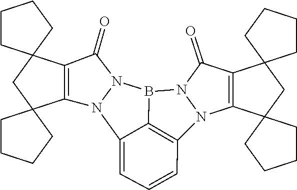 [SMILES: O=c1c2c(n3n1B1c4c-3cccc4-n3c4c(c(=O)n31)C1(CCCC1)CC41CCCC1)C1(CCCC1)CC21CCCC1] | 74 |
| 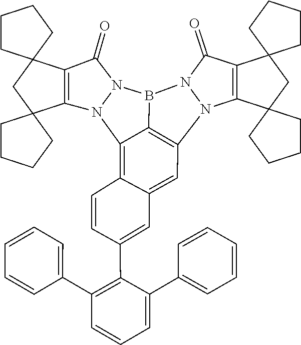 [SMILES: O=c1c2c(n3n1B1c4c-3cc3cc(-c5c(-c6ccccc6)cccc5-c5ccccc5)ccc3c4-n3c4c(c(=O)n31)C1(CCCC1)CC41CCCC1)C1(CCCC1)CC21CCCC1] | 75 |
| 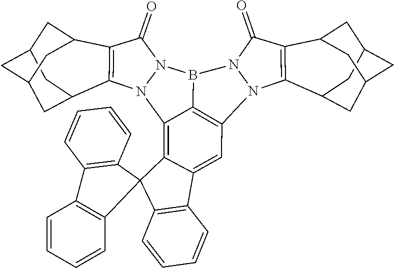 [SMILES: O=c1c2c(n3n1B1c4c-3cc3c(c4-n4c5c(c(=O)n41)C1CC4CC(C1)CC5C4)C1(c4ccccc4-c4ccccc41)c1ccccc1-3)C1CC3CC(CC2C3)C1] | 76 |
| 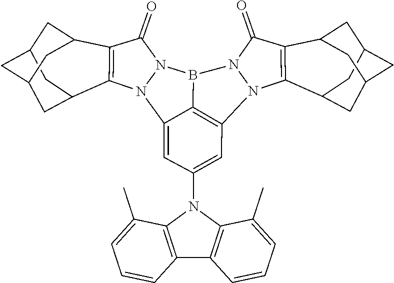 [SMILES: Cc1cccc2c3cccc(C)c3n(-c3cc4c5c(c3)-n3c6c(c(=O)n3B5n3c(=O)c5c(n3-4)C3CC4CC(CC5C4)C3)C3CC4CC(C3)CC6C4)c12] | 77 |
| 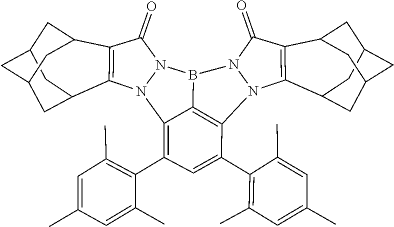 [SMILES: Cc1cc(C)c(-c2cc(-c3c(C)cc(C)cc3C)c3c4c2-n2c5c(c(=O)n2B4n2c(=O)c4c(n2-3)C2CC3CC(CC4C3)C2)C2CC3CC(C2)CC5C3)c(C)c1] | 78 |
| 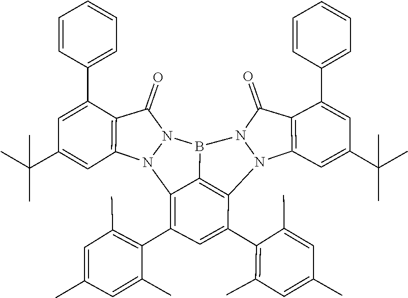 [SMILES: Cc1cc(C)c(-c2cc(-c3c(C)cc(C)cc3C)c3c4c2-n2c5cc(C(C)(C)C)cc(-c6ccccc6)c5c(=O)n2B4n2c(=O)c4c(-c5ccccc5)cc(C(C)(C)C)cc4n2-3)c(C)c1] | 79 |
| 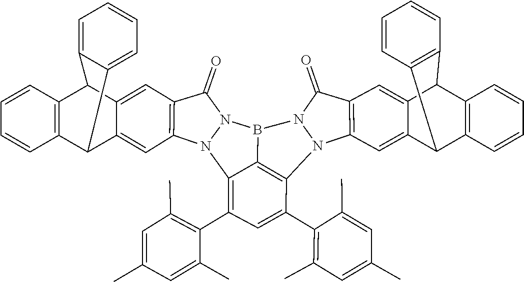 [SMILES: Cc1cc(C)c(-c2cc(-c3c(C)cc(C)cc3C)c3c4c2-n2c5cc6c(cc5c(=O)n2B4n2c(=O)c4cc5c(cc4n2-3)C2c3ccccc3C5c3ccccc32)C2c3ccccc3C6c3ccccc32)c(C)c1] | 80 |
| 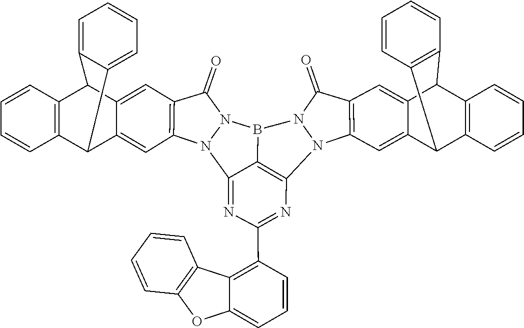 [SMILES: O=c1c2cc3c(cc2n2n1B1c4c-2nc(-c2cccc5oc6ccccc6c25)nc4-n2c4cc5c(cc4c(=O)n21)C1c2ccccc2C5c2ccccc21)C1c2ccccc2C3c2ccccc21] | 81 |
| 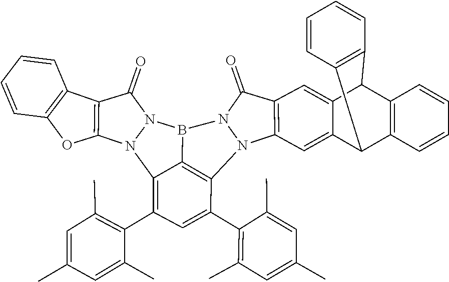 [SMILES: Cc1cc(C)c(-c2cc(-c3c(C)cc(C)cc3C)c3c4c2-n2c5cc6c(cc5c(=O)n2B4n2c(=O)c4c5ccccc5oc4n2-3)C2c3ccccc3C6c3ccccc32)c(C)c1] | 82 |
| 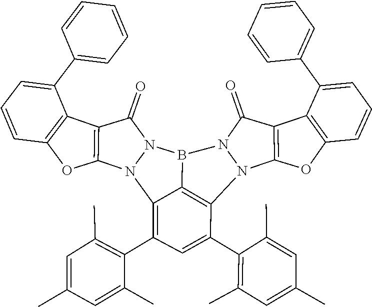 [SMILES: Cc1cc(C)c(-c2cc(-c3c(C)cc(C)cc3C)c3c4c2-n2c5oc6cccc(-c7ccccc7)c6c5c(=O)n2B4n2c(=O)c4c5c(-c6ccccc6)cccc5oc4n2-3)c(C)c1] | 83 |
| 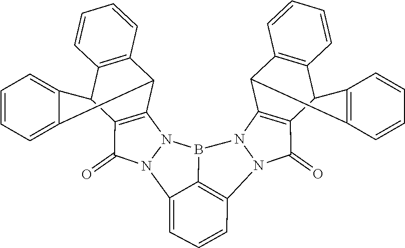 [SMILES: O=c1c2c(n3n1-c1cccc4c1B3n1c3c(c(=O)n1-4)C1c4ccccc4C3c3ccccc31)C1c3ccccc3C2c2ccccc21] | 84 |
| 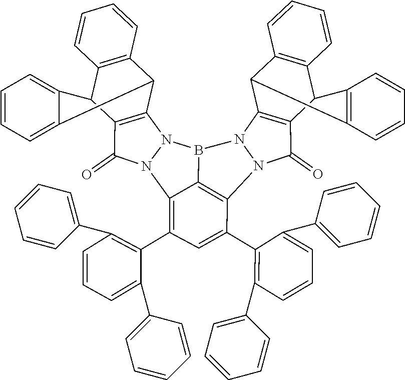 [SMILES: O=c1c2c(n3n1-c1c(-c4c(-c5ccccc5)cccc4-c4ccccc4)cc(-c4c(-c5ccccc5)cccc4-c4ccccc4)c4c1B3n1c3c(c(=O)n1-4)C1c4ccccc4C3c3ccccc31)C1c3ccccc3C2c2ccccc21] | 85 |
| 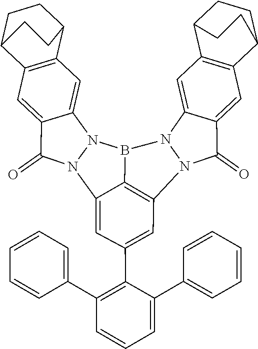 [SMILES: O=c1c2cc3c(cc2n2n1-c1cc(-c4c(-c5ccccc5)cccc4-c4ccccc4)cc4c1B2n1c2cc5c(cc2c(=O)n1-4)C1CCC5CC1)C1CCC3CC1] | 86 |
| 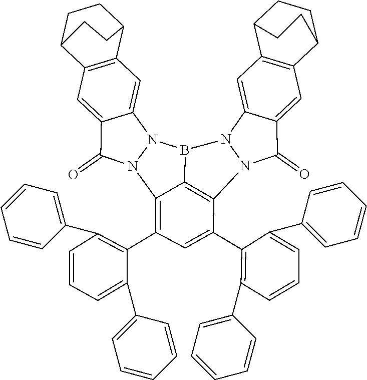 [SMILES: O=c1c2cc3c(cc2n2n1-c1c(-c4c(-c5ccccc5)cccc4-c4ccccc4)cc(-c4c(-c5ccccc5)cccc4-c4ccccc4)c4c1B2n1c2cc5c(cc2c(=O)n1-4)C1CCC5CC1)C1CCC3CC1] | 87 |

Preferred embodiments of compounds of the invention are recited in detail in the examples, these compounds being usable alone or in combination with further compounds for all purposes of the invention.

Provided that the conditions specified in claim 1 are met, the abovementioned preferred embodiments can be combined with one another as desired. In a particularly preferred embodiment of the invention, the abovementioned preferred embodiments apply simultaneously.

The compounds of the invention are preparable in principle by various processes. However, the processes described hereinafter have been found to be particularly suitable.

Therefore, the present invention further provides a process for preparing the compounds of the invention, in which a base skeleton having at least one of the W^{a} groups or a precursor of one of the W^{a} groups is synthesized, and then an aromatic or heteroaromatic radical is introduced by means of a nucleophilic aromatic substitution reaction or a coupling reaction.

Suitable compounds comprising a base skeleton having a W^{a} group are in many cases commercially available, and the starting compounds detailed in the examples are obtainable by known processes, and so reference is made thereto.

These compounds can be reacted with further compounds by known coupling reactions, the necessary conditions for this purpose being known to the person skilled in the art, and detailed specifications in the examples giving support to the person skilled in the art in conducting these reactions.

Particularly suitable and preferred coupling reactions which all lead to C—C bond formations and/or C—N bond formations are those according to BUCHWALD, SUZUKI, YAMAMOTO, STILLE, HECK, NEGISHI, SONOGASHIRA and HIYAMA. These reactions are widely known, and the examples will provide the person skilled in the art with further pointers.

The compounds of the invention may be prepared according to scheme 1 and scheme 2 inter alia. In this context, scheme 1 in particular shows the preparation of compounds of the invention proceeding from hydrazine derivatives a possible formation of a ring Ar^{b} as present in preferred compounds. Scheme 2 describes a synthesis via a carboxylic acid derivative that does not comprise a hydrazine group. Instead, this group is formed by reaction of a nitro group with an amino group.

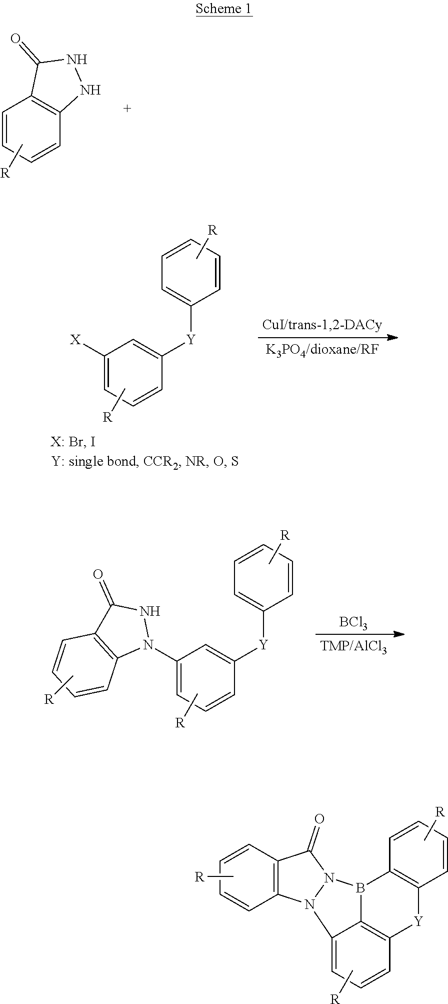

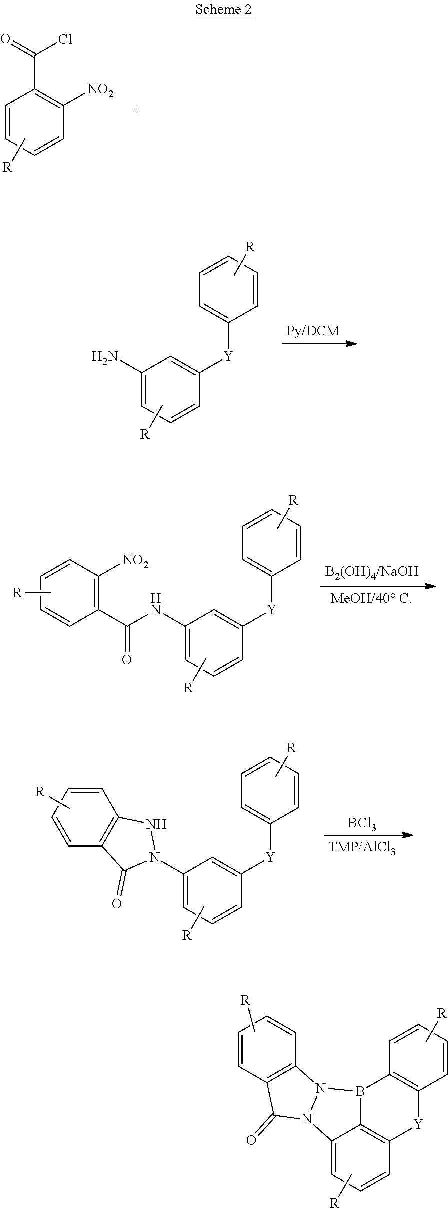

The definition of the symbols used in schemes 1 and 2 corresponds essentially to that which was defined for formula (I), or preferred embodiments of these structures, dispensing with numbering and complete representation of all symbols for reasons of clarity. In addition, for reasons of clarity, the use of symbols for representation of possible nitrogen atoms in the heteroaromatic rings has been dispensed with in many cases, as shown in particular in formulae (I), (II-1) to (II-18) and/or (III-1) to (III-48) by the symbols X, X^{a} and X^{b}. These details should therefore be understood by way of illustration; the person skilled in the art is capable of applying the syntheses set out above and hereinafter, especially in the examples, to compounds in which one or more of the symbols X, X^{a} and X^{b} are nitrogen.

The principles of the preparation processes detailed above are known in principle from the literature for similar compounds and can be adapted easily by the person skilled in the art for the preparation of the compounds of the invention. Further information can be found in the examples.

It is possible by these methods, if necessary followed by purification, for example recrystallization or sublimation, to obtain the compounds of the invention in high purity, preferably more than 99% (determined by means of ¹H NMR and/or HPLC).

The compounds of the invention may also be mixed with a polymer. It is likewise possible to incorporate these compounds covalently into a polymer. This is especially possible with compounds substituted by reactive leaving groups such as bromine, iodine, chlorine, boronic acid or boronic ester, or by reactive polymerizable groups such as olefins or oxetanes. These may find use as monomers for production of corresponding oligomers, dendrimers or polymers. The oligomerization or polymerization is preferably effected via the halogen functionality or the boronic acid functionality or via the polymerizable group. It is additionally possible to crosslink the polymers via groups of this kind. The compounds and polymers of the invention may be used in the form of a crosslinked or uncrosslinked layer.

The invention therefore further provides oligomers, polymers or dendrimers containing one or more of the above-detailed structures of the formula (I) and preferred embodiments of this formula or compounds of the invention, wherein one or more bonds of the compounds of the invention or of the structures of the formula (I) and preferred embodiments of that formula to the polymer, oligomer or dendrimer are present. According to the linkage of the structures of the formula (I) and preferred embodiments of this formula or of the compounds, these therefore form a side chain of the oligomer or polymer or are bonded within the main chain. The polymers, oligomers or dendrimers may be conjugated, partly conjugated or nonconjugated. The oligomers or polymers may be linear, branched or dendritic. For the repeat units of the compounds of the invention in oligomers, dendrimers and polymers, the same preferences apply as described above.

For preparation of the oligomers or polymers, the monomers of the invention are homopolymerized or copolymerized with further monomers. Preference is given to copolymers wherein the units of formula (I) or the preferred embodiments recited above and hereinafter are present to an extent of 0.01 to 99.9 mol %, preferably 5 to 90 mol %, more preferably 20 to 80 mol %. Suitable and preferred comonomers which form the polymer base skeleton are chosen from fluorenes (for example according to EP 842208 or WO 2000/022026), spirobifluorenes (for example according to EP 707020, EP 894107 or WO 2006/061181), paraphenylenes (for example according to WO 92/18552), carbazoles (for example according to WO 2004/070772 or WO 2004/113468), thiophenes (for example according to EP 1028136), dihydrophenanthrenes (for example according to WO 2005/014689), cis- and trans-indenofluorenes (for example according to WO 2004/041901 or WO 2004/113412), ketones (for example according to WO 2005/040302), phenanthrenes (for example according to WO 2005/104264 or WO 2007/017066) or else a plurality of these units. The polymers, oligomers and dendrimers may contain still further units, for example hole transport units, especially those based on triarylamines, and/or electron transport units.

Additionally of particular interest are compounds of the invention which feature a high glass transition temperature. In this connection, preference is given especially to compounds of the invention comprising structures of the formula (I) or the preferred embodiments recited above and hereinafter which have a glass transition temperature of at least 70° C., more preferably of at least 110° C., even more preferably of at least 125° C. and especially preferably of at least 150° C., determined in accordance with DIN 51005 (2005-08 version).

For the processing of the compounds of the invention from a liquid phase, for example by spin-coating or by printing methods, formulations of the compounds of the invention are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (-)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, 2-methylbiphenyl, 3-methylbiphenyl, 1-methylnaphthalene, 1-ethylnaphthalene, ethyl octanoate, diethyl sebacate, octyl octanoate, heptylbenzene, menthyl isovalerate, cyclohexyl hexanoate or mixtures of these solvents.

The present invention therefore further provides a formulation or a composition comprising at least one compound of the invention and at least one further compound. The further compound may, for example, be a solvent, especially one of the abovementioned solvents or a mixture of these solvents. If the further compound comprises a solvent, this mixture is referred to herein as formulation. The further compound may alternatively be at least one further organic or inorganic compound which is likewise used in the electronic device, for example an emitter and/or a matrix material, where these compounds differ from the compounds of the invention. Suitable emitters and matrix materials are listed at the back in connection with the organic electroluminescent device. The further compound may also be polymeric.

The present invention therefore still further provides a composition comprising a compound of the invention and at least one further organofunctional material. Functional materials are generally the organic or inorganic materials introduced between the anode and cathode. Preferably, the organically functional material is selected from the group consisting of fluorescent emitters, phosphorescent emitters, emitters that exhibit TADF (thermally activated delayed fluorescence), host materials, electron transport materials, electron injection materials, hole conductor materials, hole injection materials, electron blocker materials, hole blocker materials, wide bandgap materials and n-dopants.

The present invention further provides for the use of a compound of the invention in an electronic device, especially in an organic electroluminescent device, preferably as emitter, more preferably as green, red or blue emitter. In this case, compounds of the invention preferably exhibit fluorescent properties and thus provide preferentially fluorescent emitters.

It may preferably the case that structures/compounds of formulae (II-2) to (II-8), (II-17) to (II-23), (III-2) to (III-8), (III-17) to (III-23), (IV-2) to (IV-8), (IV-17) to (IV-23), (V-1), (V-2), (V-5) and/or (V-6) are used as emitter.

In addition, compounds of formula (I) or an oligomer, polymer or dendrimer comprising structures of formula (I) may be used as host materials and/or electron transport materials. It may preferably be the case that structures/compounds having an anthracene group (Ar-76) to (Ar-78), preferably (Ar-78), and/or compounds of formulae (II-9), (II-10), (II-24), (II-25), (III-9), (III-10), (III-24), (III-25), (IV-9), (IV-10), (IV-24) and/or (IV-25) are used as electron transport material and/or matrix material.

The present invention still further provides an electronic device comprising at least one compound of the invention. An electronic device in the context of the present invention is a device comprising at least one layer comprising at least one organic compound. This component may also comprise inorganic materials or else layers formed entirely from inorganic materials.

The electronic device is preferably selected from the group consisting of More preferably, the electronic device is selected from the group consisting of organic electroluminescent devices (OLEDs, sOLED, PLEDs, LECs, etc.), preferably organic light-emitting diodes (OLEDs), organic light-emitting diodes based on small molecules (sOLEDs), organic light-emitting diodes based on polymers (PLEDs), light-emitting electrochemical cells (LECs), organic laser diodes (O-laser), organic plasmon-emitting devices (D. M. Koller et al., Nature Photonics 2008, 1-4), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs) and organic electrical sensors, preferably organic electroluminescent devices (OLEDs, sOLED, PLEDs, LECs, etc.), more preferably organic light-emitting diodes (OLEDs), organic light-emitting diodes based on small molecules (sOLEDs), organic light-emitting diodes based on polymers (PLEDs), especially phosphorescent OLEDs.

The organic electroluminescent device comprises cathode, anode and at least one emitting layer. Apart from these layers, it may also comprise further layers, for example in each case one or more hole injection layers, hole transport layers, hole blocker layers, electron transport layers, electron injection layers, exciton blocker layers, electron blocker layers and/or charge generation layers. It is likewise possible for interlayers having an exciton-blocking function, for example, to be introduced between two emitting layers. However, it should be pointed out that not necessarily every one of these layers need be present. In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are systems having three emitting layers, where the three layers show blue, green and orange or red emission. The organic electroluminescent device of the invention may also be a tandem electroluminescent device, especially for white-emitting OLEDs.

The compound of the invention may be used in different layers, according to the exact structure. Preference is given to an organic electroluminescent device comprising a structure/compound of formula (I) or the above-detailed preferred embodiments in an emitting layer as emitter, preferably red, green or blue emitter. Very preferred is an organic electroluminescent device comprising a structure/compound of formula (I) or the above-detailed preferred embodiments in an emitting layer as fluorescent blue emitter. Preference is given here especially to compounds structures/compounds of the formulae (II-9) to (II-16), (III-3) to (III-14), (III-17) to (III-26), (III-47) and (III-48), particular preference to structures/compounds of the formulae (III-3), (III-5), (III-7), (III-9), (III-11), (III-13), (III-17), (III-19), (III-21), (III-23), (III-25) and (III-47).

When the compound of the invention is used as emitter in an emitting layer, preference is given to using a suitable matrix material (also called host material) which is known as such.

A preferred mixture of the compound of the invention and a matrix material contains between 99% and 1% by volume, preferably between 98% and 10% by volume, more preferably between 97% and 60% by volume and especially between 95% and 80% by volume of matrix material, based on the overall mixture of emitter and matrix material. Correspondingly, the mixture contains between 1% and 99% by volume, preferably between 2% and 90% by volume, more preferably between 3% and 40% by volume and especially between 5% and 20% by volume of the emitter, based on the overall mixture of emitter and matrix material.

Suitable matrix materials which can be used in combination with the inventive compounds are aromatic ketones, aromatic phosphine oxides or aromatic sulfoxides or sulfones, for example according to WO 2004/013080, WO 2004/093207, WO 2006/005627 or WO 2010/006680, triarylamines, carbazole derivatives, e.g. CBP (N,N-biscarbazolylbiphenyl) or the carbazole derivatives disclosed in WO 2005/039246, US 2005/0069729, JP 2004/288381, EP 1205527, WO 2008/086851 or WO 2013/041176, indolocarbazole derivatives, for example according to WO 2007/063754 or WO 2008/056746, indenocarbazole derivatives, for example according to WO 2010/136109, WO 2011/000455, WO 2013/041176 or WO 2013/056776, azacarbazole derivatives, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, triazine derivatives, for example according to WO 2007/063754, WO 2008/056746, WO 2010/015306, WO 2011/057706, WO 2011/060859 or WO 2011/060877, zinc complexes, for example according to EP 652273 or WO 2009/062578, diazasilole or tetraazasilole derivatives, for example according to WO 2010/054729, diazaphosphole derivatives, for example according to WO 2010/054730, bridged carbazole derivatives, for example according to WO 2011/042107, WO 2011/060867, WO 2011/088877 and WO 2012/143080, triphenylene derivatives, for example according to WO 2012/048781, dibenzofuran derivatives, for example according to WO 2015/169412, WO 2016/015810, WO 2016/023608, WO 2017/148564 or WO 2017/148565, or biscarbazoles, for example according to JP 3139321 B2.

In addition, the co-host used may be a compound that does not take part in charge transport to a significant degree, if at all, as described, for example, in WO 2010/108579. Especially suitable in combination with the compound of the invention as co-matrix material are compounds which have a large bandgap and themselves take part at least not to a significant degree, if any at all, in the charge transport of the emitting layer. Such materials are preferably pure hydrocarbons. Examples of such materials can be found, for example, in WO 2009/124627 or in WO 2010/006680.

In a preferred configuration, a compound containing a structure/compound of formula (I) or the above-detailed preferred embodiments which is used as emitter is preferably used in combination with one or more phosphorescent materials (triplet emitters) and/or a compound which is a TADF (thermally activated delayed fluorescence) host material. Preference is given here to forming a hyperfluorescence system as described in WO 2012/133188 and/or a hyperphosphorescence system as in US 2017271611. This combination is a preferred embodiment according to the present invention.

WO 2015/091716 A1 and WO 2016/193243 A1 disclose OLEDs containing both a phosphorescent compound and a fluorescent emitter in the emission layer, where the energy is transferred from the phosphorescent compound to the fluorescent emitter (hyperphosphorescence). In this context, the phosphorescent compound accordingly behaves as a host material. As the person skilled in the art knows, host materials have higher singlet and triplet energies as compared to the emitters in order that the energy from the host material will also be transferred to the emitter with maximum efficiency. The systems disclosed in the prior art have exactly such an energy relation.

Phosphorescence in the context of this invention is understood to mean luminescence from an excited state having higher spin multiplicity, i.e. a spin state >1, especially from an excited triplet state. In the context of this application, all luminescent complexes with transition metals or lanthanides, especially all iridium, platinum and copper complexes, shall be regarded as phosphorescent compounds.

Suitable phosphorescent compounds (═triplet emitters) are especially compounds which, when suitably excited, emit light, preferably in the visible region, and also contain at least one atom of atomic number greater than 20, preferably greater than 38 and less than 84, more preferably greater than 56 and less than 80, especially a metal having this atomic number. Preferred phosphorescence emitters used are compounds containing copper, molybdenum, tungsten, rhenium, ruthenium, osmium, rhodium, iridium, palladium, platinum, silver, gold or europium, especially compounds containing iridium or platinum.

Examples of the emitters described above can be found in applications WO 00/70655, WO 2001/41512, WO 2002/02714, WO 2002/15645, EP 1191613, EP 1191612, EP 1191614, WO 05/033244, WO 05/019373, US 2005/0258742, WO 2009/146770, WO 2010/015307, WO 2010/031485, WO 2010/054731, WO 2010/054728, WO 2010/086089, WO 2010/099852, WO 2010/102709, WO 2011/032626, WO 2011/066898, WO 2011/157339, WO 2012/007086, WO 2014/008982, WO 2014/023377, WO 2014/094961, WO 2014/094960, WO 2015/036074, WO 2015/104045, WO 2015/117718, WO 2016/015815, WO 2016/124304, WO 2017/032439, WO 2018/011186, WO 2018/001990, WO 2018/019687, WO 2018/019688, WO 2018/041769, WO 2018/054798, WO 2018/069196, WO 2018/069197, WO 2018/069273, WO 2018/178001, WO 2018/177981, WO 2019/020538, WO 2019/115423, WO 2019/158453 and WO 2019/179909. In general, all phosphorescent complexes as used for phosphorescent electroluminescent devices according to the prior art and as known to those skilled in the art in the field of organic electroluminescence are suitable, and the person skilled in the art will be able to use further phosphorescent complexes without exercising inventive skill.

A compound of the invention may preferably be used in combination with a TADF host material and/or a TADF emitter, as set out above.

The process referred to as thermally activated delayed fluorescence (TADF) is described, for example, by B. H. Uoyama et al., Nature 2012, Vol. 492, 234. In order to enable this process, a comparatively small singlet-triplet separation ΔE(S₁−T₁) of less than about 2000 cm⁻¹, for example, is needed in the emitter. In order to open up the T₁→S₁ transition which is spin-forbidden in principle, as well as the emitter, it is possible to provide a further compound in the matrix that has strong spin-orbit coupling, such that intersystem crossing is enabled via the spatial proximity and the interaction which is thus possible between the molecules, or the spin-orbit coupling is generated by means of a metal atom present in the emitter.

Sources of further valuable information relating to hyperfluorescence systems include WO2012/133188 (Idemitsu), WO2015/022974 (Kyushu Univ.), WO2015/098975 (Idemitsu), WO2020/053150 (Merck) and DE202019005189 (Merck).

Sources of further valuable information relating to hyperphosphorescence systems include WO2015/091716 A1, WO2016/193243 A1 (BASF), WO01/08230 A1 (Princeton Univ. (Mark Thompson)), US2005/0214575A1 (Fuji), WO2012/079673 (Merck), WO2020/053314 (Merck) and WO2020/053315 (Merck).

In a further embodiment of the invention, the organic electroluminescent device of the invention does not contain any separate hole injection layer and/or hole transport layer and/or hole blocker layer and/or electron transport layer, meaning that the emitting layer directly adjoins the hole injection layer or the anode, and/or the emitting layer directly adjoins the electron transport layer or the electron injection layer or the cathode, as described, for example, in WO 2005/053051. It is additionally possible to use a metal complex identical or similar to the metal complex in the emitting layer as hole transport or hole injection material directly adjoining the emitting layer, as described, for example, in WO 2009/030981.

Also preferred is an organic electroluminescent device comprising a structure/compound of formula (I) or the above-detailed preferred embodiments in an electron-conducting layer as electron transport material. Here are in particular compounds having an anthracene group, preferably a group of formulae (Ar-76) to (Ar-78), preferably (Ar-78).

In the further layers of the organic electroluminescent device of the invention, it is possible to use any materials as typically used according to the prior art. The person skilled in the art will therefore be able, without exercising inventive skill, to use any materials known for organic electroluminescent devices in combination with the structure/compound of formula (I) or the above-recited preferred embodiments.

Additionally preferred is an organic electroluminescent device, characterized in that one or more layers are coated by a sublimation process. In this case, the materials are applied by vapor deposition in vacuum sublimation systems at an initial pressure of less than 10⁻⁵ mbar, preferably less than 10⁻⁶ mbar. However, it is also possible that the initial pressure is even lower, for example less than 10⁻⁷ mbar.

Preference is likewise given to an organic electroluminescent device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured.

Preference is additionally given to an organic electroluminescent device, characterized in that one or more layers are produced from solution, for example by spin-coating, or by any printing method, for example screen printing, flexographic printing, offset printing, LITI (light-induced thermal imaging, thermal transfer printing), inkjet printing or nozzle printing. For this purpose, soluble compounds are needed, which are obtained, for example, through suitable substitution.

Formulations for applying a compound of formula (I) or the preferred embodiments thereof detailed above are novel. The present invention therefore further provides formulations containing at least one solvent and a compound according to formula (I) or the preferred embodiments thereof detailed above.

In addition, hybrid methods are possible, in which, for example, one or more layers are applied from solution and one or more further layers are applied by vapor deposition.

Those skilled in the art are generally aware of these methods and are able to apply them without exercising inventive skill to organic electroluminescent devices comprising the compounds of the invention.

The compounds of the invention and the organic electroluminescent devices of the invention have the particular feature of an improved lifetime over the prior art. At the same time, the further electronic properties of the electroluminescent devices, such as efficiency or operating voltage, remain at least equally good. In a further variant, the compounds of the invention and the organic electroluminescent devices of the invention especially feature improved efficiency and/or operating voltage and higher lifetime compared to the prior art.

The electronic devices of the invention, especially organic electroluminescent devices, are notable for one or more of the following surprising advantages over the prior art:
1. Electronic devices, especially organic electroluminescent devices comprising structures/compounds of formula (I) or the preferred embodiments as emitters that have been recited above and hereinafter have very narrow emission bands having very low FWHM (Full Width Half Maximum) values, and lead to particularly pure-color emission, recognizable by the low CIE y values. What is particularly surprising here is that both blue emitters having low FWHM values and emitters having low FWHM that emit in the green, yellow or red region of the color spectrum are provided.
2. The inventive structures/compounds of formula (I) or the preferred embodiments recited above and hereinafter exhibit very high stability and lifetime.
3. With structures/compounds of formula (I) or the preferred embodiments recited above and hereinafter, it is possible to avoid the formation of optical loss channels in electronic devices, especially organic electroluminescent devices. As a result, these devices feature a high PL efficiency and hence high EL efficiency of emitters, and excellent energy transmission of the matrices to dopants.
   Exciton energy is transmitted from a matrix or hosting the emission layer to the emitter, typically either via what is called Dexter transfer or via Förster transfer. Förster energy transfer (FRET) from a host or matrix to the emitter of the invention is particularly preferred here, since it is particularly efficient, which leads to electronic devices having particularly good performance data (for example efficiency, voltage and lifetime). It is found that energy is preferably transferred from a host or matrix to the compounds of the invention via Förster transfer.

These abovementioned advantages are not accompanied by an inordinately high deterioration in the further electronic properties.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Thus, any feature disclosed in the present invention, unless stated otherwise, should be considered as an example of a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

It should also be pointed out that many of the features, and especially those of the preferred embodiments of the present invention, should themselves be regarded as inventive and not merely as some of the embodiments of the present invention. For these features, independent protection may be sought in addition to or as an alternative to any currently claimed invention.

The technical teaching disclosed with the present invention may be abstracted and combined with other examples.

The invention is illustrated in detail by the examples which follow, without any intention of restricting it thereby. The person skilled in the art will be able to use the information given to execute the invention over the entire scope disclosed and to prepare further compounds of the invention without exercising inventive skill and to use them in electronic devices or to employ the process of the invention.

### EXAMPLES

The syntheses which follow, unless stated otherwise, are conducted under a protective gas atmosphere in dried solvents. The metal complexes are additionally handled with exclusion of light or under yellow light. The solvents and reagents can be purchased, for example, from Sigma-ALDRICH or ABCR. The respective figures in square brackets or the numbers quoted for individual compounds relate to the CAS numbers of the compounds known from the literature. In the case of compounds that can have multiple enantiomeric, diastereomeric or tautomeric forms, one form is shown in a representative manner.

Synthons Known from the Literature:

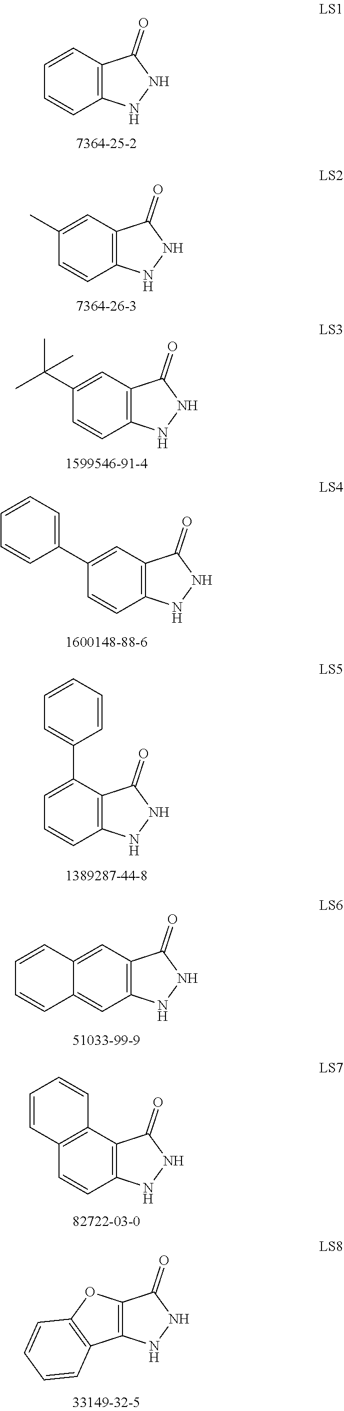

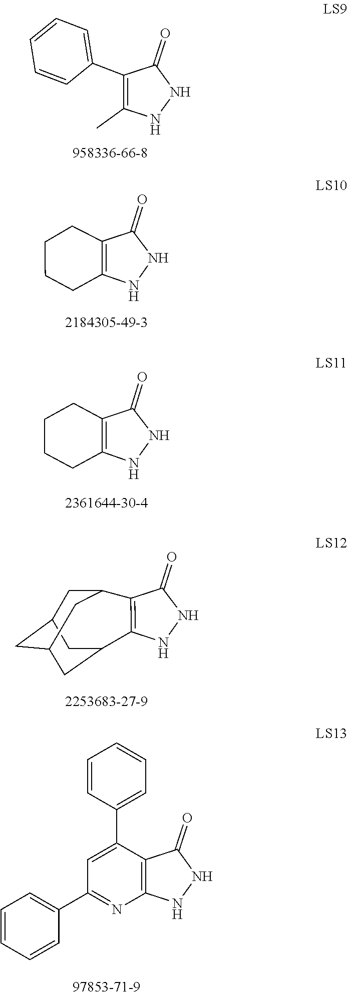 [SMILES: Cc1[nH][nH]c(=O)c1-c1ccccc1 ; O=c1[nH][nH]c2c1CCCC2 ; O=c1[nH][nH]c2c1CCCC2 ; O=c1[nH][nH]c2c1C1CC3CC(CC2C3)C1 ; O=c1[nH][nH]c2nc(-c3ccccc3)cc(-c3ccccc3)c12]

### Synthesis of Synthons S

### Example B1

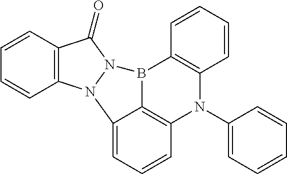 [SMILES: O=c1c2ccccc2n2n1B1c3ccccc3N(c3ccccc3)c3cccc-2c31]

### Stage A):

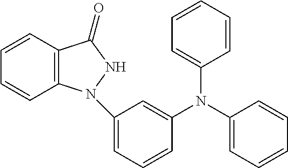 [SMILES: O=c1[nH]n(-c2cccc(N(c3ccccc3)c3ccccc3)c2)c2ccccc12]

Synthesis analogous to V. Bodmer-Narkevitch et al., Bioorg. Med. Chem. Lett. 2010, (20) 7011. A mixture of 37.1 g (100 mmol) of 3-iodophenyidiphenylamine [1287245-66-2], 14.8 g (110 mmol) of indazolinone, LS1 [7364-25-2], 68.2 g (220 mmol) of tripotassium phosphate, 952 mg (5 mmol) of copper iodide, 1.14 g (10 mmol) of rac-trans-1,2-diaminocyclohexane [1121-22-8], 100 g of glass beads (diameter 3 mm) and 500 ml of dioxane is heated under reflux for 24 h. The mixture is filtered while still hot through a Celite bed in the form of a dioxane slurry, the filtrate is concentrated under reduced pressure, and the residue is taken up in 500 ml of dichloromethane (DCM), washed three times with 200 ml of 5% aqueous EDTA solution and once with 300 ml of saturated sodium chloride solution, and dried over magnesium sulfate. The desiccant is filtered off by means of a silica gel bed in the form of a DCM slurry, and the filtrate is concentrated gradually under reduced pressure, while continuously replacing the DCM distilled off with 100 ml of methanol. The crystallized product is filtered off with suction, washed twice with 50 ml each time of methanol and dried under reduced pressure. Purification is effected by flash chromatography (CombiFlash Torrent automated column system from A. Semrau, silica gel, cyclohexane/ethyl acetate (EA)). Yield: 20.5 g (54 mmol), 54%; purity: about 98% by ¹H NMR.

### Stage B): B1

Added dropwise to a well-stirred suspension, cooled to −78° C., of 18.9 g (50 mmol) B1 of stage A) in 300 ml of toluene is 31.3 ml (50 mmol) of n-BuLi (1.6 M in n-hexane), the mixture is stirred for 30 min, then allowed to warm up to 0° C. over the course of 30 min, stirred for another 30 min and cooled again to −78° C. With very good stirring, 50 ml (50 mmol) of boron trichloride 1 N in n-heptane is added dropwise, the mixture is allowed to warm up to room temperature and stirred for another 1 h, and the solvent is removed under reduced pressure. The residue is taken up in 300 ml of o-dichlorobenzene, 18.7 ml (110 mmol) of 2,2,6,6-tetramethylpiperidine and 40.0 g (300 mmol) of aluminum trichloride, anhydrous, are added and the mixture is stirred at 150° C. for 20 h. After cooling, a mixture of 29.6 ml (300 mmol) of 1,4-diazabicyclo[2.2.2.]octane and 100 ml of o-dichlorobenzene is added, the mixture is stirred for another 1 h, filtered through a Celite bed in the form of an o-dichlorobenzene slurry and washed through with o-dichlorobenzene, and the filtrate is concentrated to dryness. Further purification is effected by continuous hot extraction (standard organic solvents or a combination thereof, preferably acetonitrile/DCM 3:1 to 1:3) or by flash chromatography (CombiFlash Torrent automated column system from A. Semrau, silica gel, RP silica gels, aluminum oxide, eluent: toluene/n-heptane/triethylamine, acetonitrile/THF or DCM) and final fractional sublimation or heat treatment under high vacuum (typically T about 200-400° C., p about 10⁻⁵ to 10⁻⁶ mbar). Yield: 3.2 g (8.3 mmol), 16.6%; purity: about 99.9% by ¹H NMR.

The following compounds can be prepared analogously:

| Ex. | Reactant | Product | Yield |
|---|---|---|---|
| B2 | 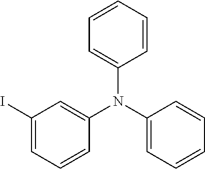 [SMILES: Ic1cccc(N(c2ccccc2)c2ccccc2)c1] | 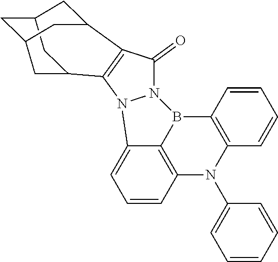 [SMILES: O=c1c2c(n3n1B1c4ccccc4N(c4ccccc4)c4cccc-3c41)C1CC3CC(CC2C3)C1] | 20% |
| | 1287245-66-2 | | |
| | LS12 | | |
| B3 | 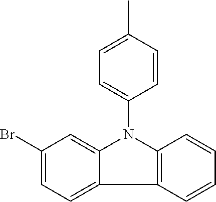 [SMILES: Cc1ccc(-n2c3ccccc3c3ccc(Br)cc32)cc1] | 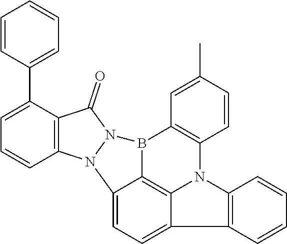 [SMILES: Cc1ccc2c(c1)B1c3c(ccc4c5ccccc5n-2c34)-n2c3cccc(-c4ccccc4)c3c(=O)n21] | 18% |
| | 1801609-87-9 | | |
| | LS5 | | |
| B4 | 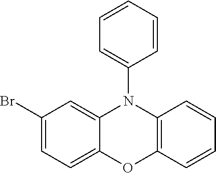 [SMILES: Brc1ccc2c(c1)N(c1ccccc1)c1ccccc1O2] | 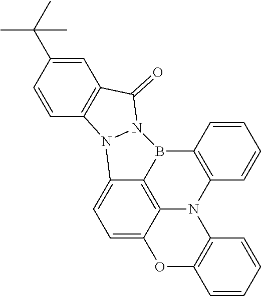 [SMILES: CC(C)(C)c1ccc2c(c1)c(=O)n1n2-c2ccc3c4c2B1c1ccccc1N4c1ccccc1O3] | 21% |
| | 1825341-72-7 | | |
| | LS3 | | |
| B5 | 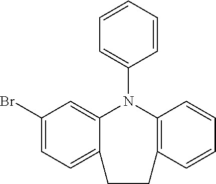 [SMILES: Brc1ccc2c(c1)N(c1ccccc1)c1ccccc1CC2] | 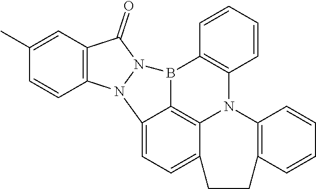 [SMILES: Cc1ccc2c(c1)c(=O)n1n2-c2ccc3c4c2B1c1ccccc1N4c1ccccc1CC3] | 16% |
| | 1306616-39-6 | | |
| | LS2 | | |
| B6 | 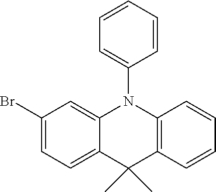 [SMILES: CC1(C)c2ccccc2N(c2ccccc2)c2cc(Br)ccc21] | 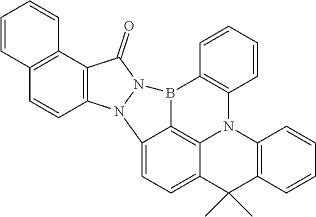 [SMILES: CC1(C)c2ccccc2N2c3ccccc3B3c4c(ccc1c42)-n1c2ccc4ccccc4c2c(=O)n13] | 17% |
| | 1306616-38-5 | | |
| | LS7 | | |
| B7 | 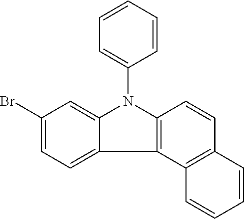 [SMILES: Brc1ccc2c3c4ccccc4ccc3n(-c3ccccc3)c2c1] | 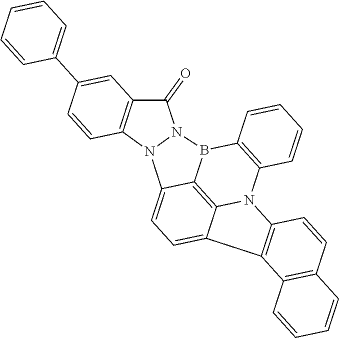 [SMILES: O=c1c2cc(-c3ccccc3)ccc2n2n1B1c3ccccc3-n3c4ccc5ccccc5c4c4ccc-2c1c43] | 15% |
| | 1357572-67-8 | | |
| | LS4 | | |
| B8 | 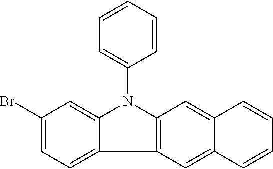 [SMILES: Brc1ccc2c3cc4ccccc4cc3n(-c3ccccc3)c2c1] | 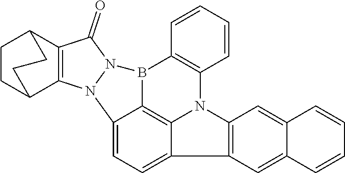 [SMILES: O=c1c2c(n3n1B1c4ccccc4-n4c5cc6ccccc6cc5c5ccc-3c1c54)C1CCC2CC1] | 19% |
| | 1686100-23-1 | | |
| | LS11 | | |
| B9 | 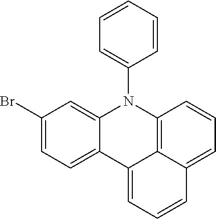 [SMILES: Brc1ccc2c(c1)N(c1ccccc1)c1cccc3cccc-2c13] | 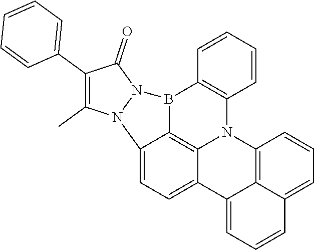 [SMILES: Cc1c(-c2ccccc2)c(=O)n2n1-c1ccc3c4c1B2c1ccccc1N4c1cccc2cccc-3c12] | 15% |
| | 1705586-11-7 | | |
| | LS9 | | |
| B10 | 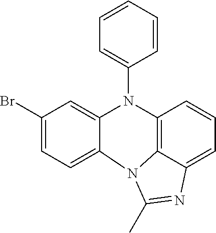 [SMILES: Cc1nc2cccc3c2n1-c1ccc(Br)cc1N3c1ccccc1] | 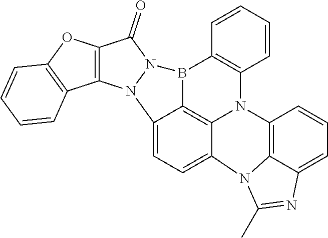 [SMILES: Cc1nc2cccc3c2n1-c1ccc2c4c1N3c1ccccc1B4n1c(=O)c3oc4ccccc4c3n1-2] | 14% |
| | 1689530-24-2 | | |
| | LS8 | | |
| B11 | 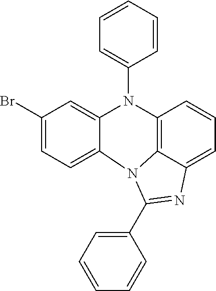 [SMILES: Brc1ccc2c(c1)N(c1ccccc1)c1cccc3nc(-c4ccccc4)n-2c13] | 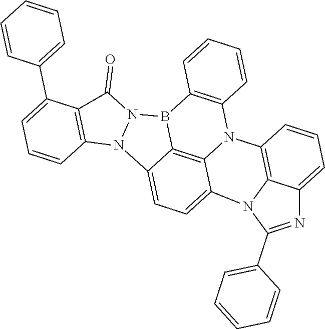 [SMILES: O=c1c2c(-c3ccccc3)cccc2n2n1B1c3ccccc3N3c4c(ccc-2c41)-n1c(-c2ccccc2)nc2cccc3c21] | 16% |
| | 1689530-26-4 | | |
| | LS5 | | |
| B12 | 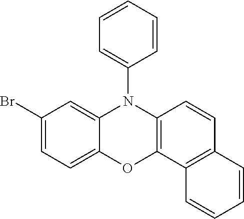 [SMILES: Brc1ccc2c(c1)N(c1ccccc1)c1ccc3ccccc3c1O2] | 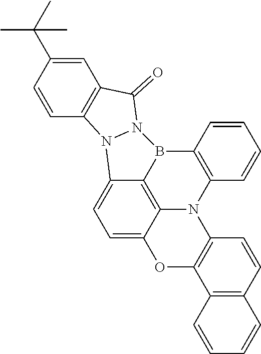 [SMILES: CC(C)(C)c1ccc2c(c1)c(=O)n1n2-c2ccc3c4c2B1c1ccccc1N4c1ccc2ccccc2c1O3] | 20% |
| | 2598066-40-9 | | |
| | LS3 | | |
| B13 | 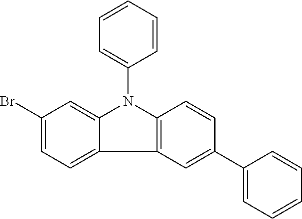 [SMILES: Brc1ccc2c3cc(-c4ccccc4)ccc3n(-c3ccccc3)c2c1] | 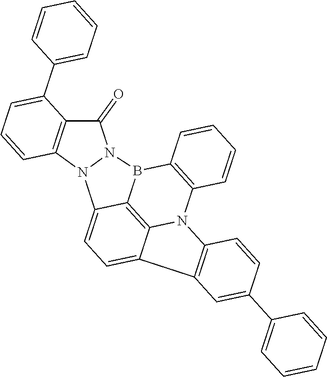 [SMILES: O=c1c2c(-c3ccccc3)cccc2n2n1B1c3ccccc3-n3c4ccc(-c5ccccc5)cc4c4ccc-2c1c43] | 19% |
| | 1644466-58-9 | | |
| | LS5 | | |
| B14 | 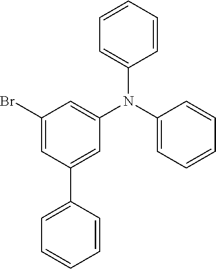 [SMILES: Brc1cc(-c2ccccc2)cc(N(c2ccccc2)c2ccccc2)c1] | 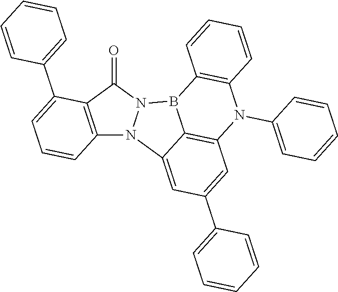 [SMILES: O=c1c2c(-c3ccccc3)cccc2n2n1B1c3ccccc3N(c3ccccc3)c3cc(-c4ccccc4)cc-2c31] | 22% |
| | 1537218-86-2 | | |
| | LS5 | | |
| B15 | 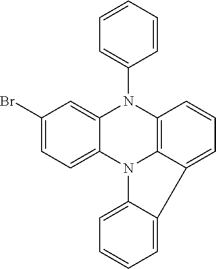 [SMILES: Brc1ccc2c(c1)N(c1ccccc1)c1cccc3c4ccccc4n-2c13] | 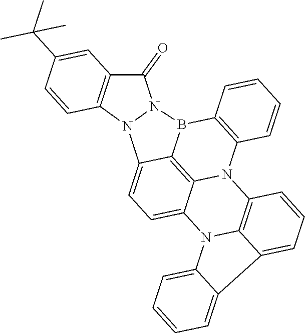 [SMILES: CC(C)(C)c1ccc2c(c1)c(=O)n1n2-c2ccc3c4c2B1c1ccccc1N4c1cccc2c4ccccc4n-3c12] | 17% |
| | 2252311-13-8 | | |
| | LS3 | | |
| B16 | 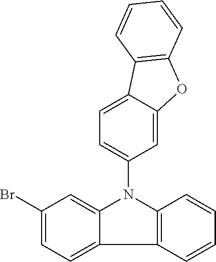 [SMILES: Brc1ccc2c3ccccc3n(-c3ccc4c(c3)oc3ccccc34)c2c1] | 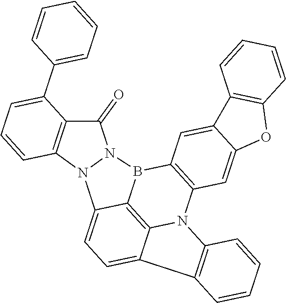 [SMILES: O=c1c2c(-c3ccccc3)cccc2n2n1B1c3cc4c(cc3-n3c5ccccc5c5ccc-2c1c53)oc1ccccc14] | 17% |
| | 1613370-82-3 | | |
| | LS5 | | |
| B17 | 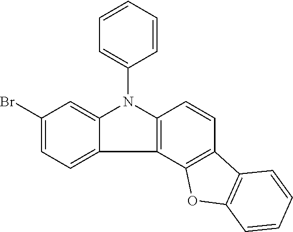 [SMILES: Brc1ccc2c3c4oc5ccccc5c4ccc3n(-c3ccccc3)c2c1] | 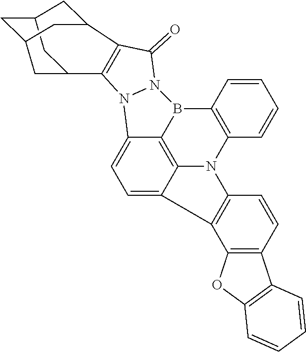 [SMILES: O=c1c2c(n3n1B1c4ccccc4-n4c5ccc6c7ccccc7oc6c5c5ccc-3c1c54)C1CC3CC(CC2C3)C1] | 19% |
| | 834600-31-5 | | |
| | LS12 | | |
| B18 | 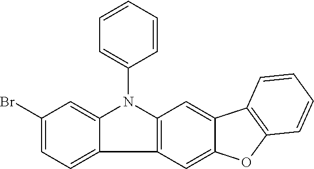 [SMILES: Brc1ccc2c3cc4oc5ccccc5c4cc3n(-c3ccccc3)c2c1] | 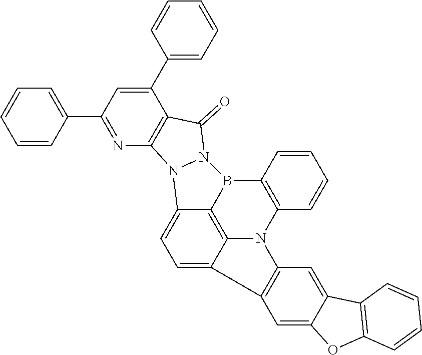 [SMILES: O=c1c2c(-c3ccccc3)cc(-c3ccccc3)nc2n2n1B1c3ccccc3-n3c4cc5c(cc4c4ccc-2c1c43)oc1ccccc15] | |
| | 2088740-35-4 | | |
| | LS13 | | |
| B19 | 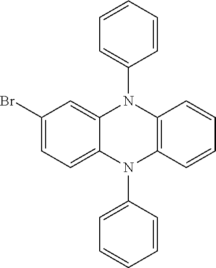 [SMILES: Brc1ccc2c(c1)N(c1ccccc1)c1ccccc1N2c1ccccc1] | 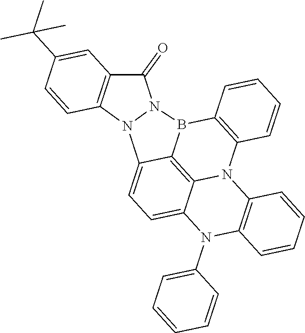 [SMILES: CC(C)(C)c1ccc2c(c1)c(=O)n1n2-c2ccc3c4c2B1c1ccccc1N4c1ccccc1N3c1ccccc1] | 16% |
| | 1320278-50-9 | | |
| | LS3 | | |
| B20 | 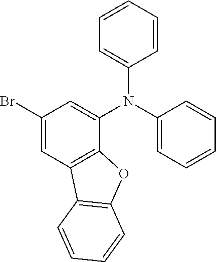 [SMILES: Brc1cc(N(c2ccccc2)c2ccccc2)c2oc3ccccc3c2c1] | 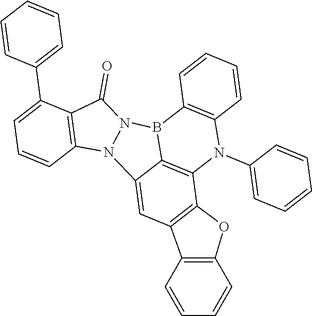 [SMILES: O=c1c2c(-c3ccccc3)cccc2n2n1B1c3ccccc3N(c3ccccc3)c3c1c-2cc1c3oc2ccccc21] | 18% |
| | 1801610-95-6 | | |
| | LS5 | | |
| B21 | 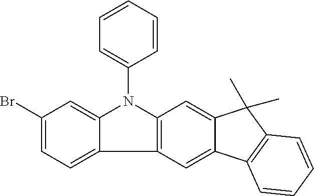 [SMILES: CC1(C)c2ccccc2-c2cc3c4ccc(Br)cc4n(-c4ccccc4)c3cc21] | 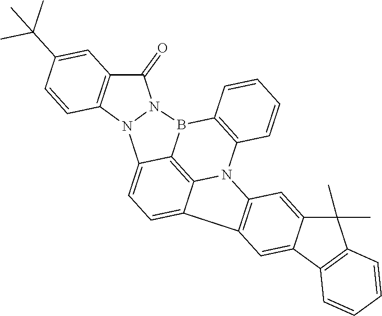 [SMILES: CC(C)(C)c1ccc2c(c1)c(=O)n1n2-c2ccc3c4cc5c(cc4n4c3c2B1c1ccccc1-4)C(C)(C)c1ccccc1-5] | 20% |
| | 2396477-58-8 | | |
| | LS3 | | |
| B22 | 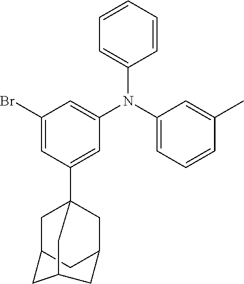 [SMILES: Cc1cccc(N(c2ccccc2)c2cc(Br)cc(C34CC5CC(CC(C5)C3)C4)c2)c1] | 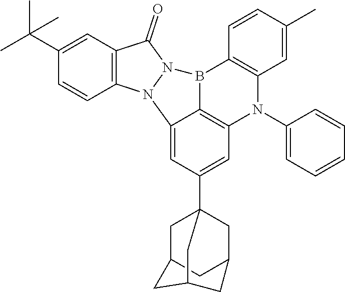 [SMILES: Cc1ccc2c(c1)N(c1ccccc1)c1cc(C34CC5CC(CC(C5)C3)C4)cc3c1B2n1c(=O)c2cc(C(C)(C)C)ccc2n1-3] | 12% |
| | 2558183-01-8 | | |
| | LS3 | | |
| B23 | 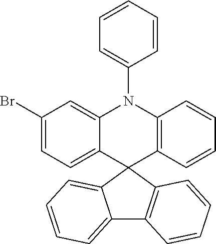 [SMILES: Brc1ccc2c(c1)N(c1ccccc1)c1ccccc1C21c2ccccc2-c2ccccc21] | 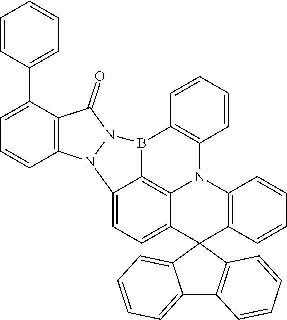 [SMILES: O=c1c2c(-c3ccccc3)cccc2n2n1B1c3ccccc3N3c4ccccc4C4(c5ccccc5-c5ccccc54)c4ccc-2c1c43] | 21% |
| | 2086293-14-1 | | |
| | LS5 | | |
| B24 | 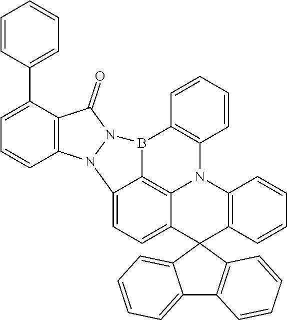 [SMILES: O=c1c2c(-c3ccccc3)cccc2n2n1B1c3ccccc3N3c4ccccc4C4(c5ccccc5-c5ccccc54)c4ccc-2c1c43] | 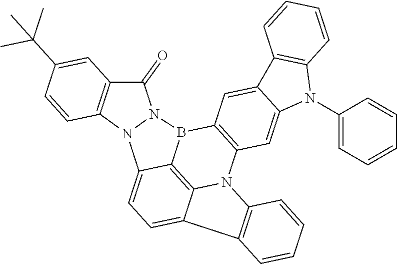 [SMILES: CC(C)(C)c1ccc2c(c1)c(=O)n1n2-c2ccc3c4ccccc4n4c3c2B1c1cc2c3ccccc3n(-c3ccccc3)c2cc1-4] | 14% |
| | 2639695-70-6 | | |
| | LS3 | | |
| B25 | 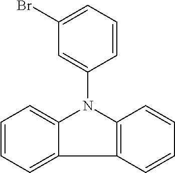 [SMILES: Brc1cccc(-n2c3ccccc3c3ccccc32)c1] | 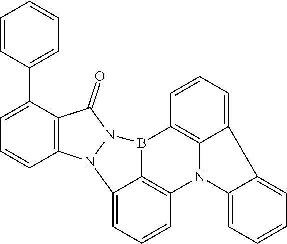 [SMILES: O=c1c2c(-c3ccccc3)cccc2n2n1B1c3c(cccc3-2)-n2c3ccccc3c3cccc1c32] | 19% |
| | 185112-62-2 | | |
| | LS5 | | |
| B26 | 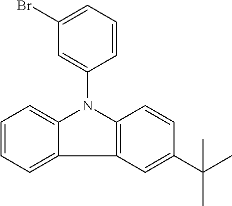 [SMILES: CC(C)(C)c1ccc2c(c1)c1ccccc1n2-c1cccc(Br)c1] | 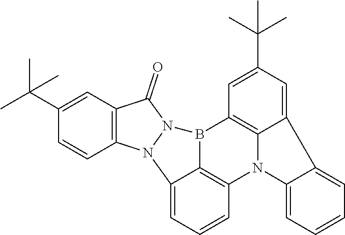 [SMILES: CC(C)(C)c1ccc2c(c1)c(=O)n1n2-c2cccc3c2B1c1cc(C(C)(C)C)cc2c4ccccc4n-3c12] | 11% |
| | 1353573-69-9 | | |
| | LS3 | | |
| B27 | 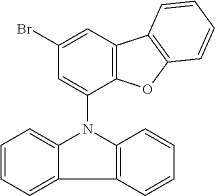 [SMILES: Brc1cc(-n2c3ccccc3c3ccccc32)c2oc3ccccc3c2c1] | 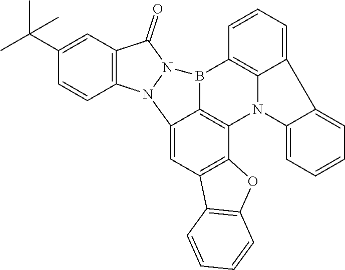 [SMILES: CC(C)(C)c1ccc2c(c1)c(=O)n1n2-c2cc3c(oc4ccccc43)c3c2B1c1cccc2c4ccccc4n-3c12] | 18% |
| | 2152624-01-4 | | |
| | LS3 | | |
| B28 | 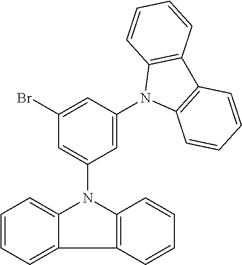 [SMILES: Brc1cc(-n2c3ccccc3c3ccccc32)cc(-n2c3ccccc3c3ccccc32)c1] | 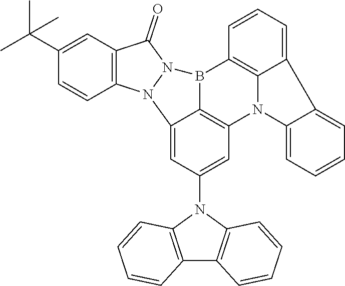 [SMILES: CC(C)(C)c1ccc2c(c1)c(=O)n1n2-c2cc(-n3c4ccccc4c4ccccc43)cc3c2B1c1cccc2c4ccccc4n-3c12] | 18% |
| | 750573-24-1 | | |
| | LS3 | | |
| B29 | 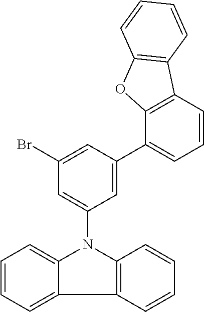 [SMILES: Brc1cc(-c2cccc3c2oc2ccccc23)cc(-n2c3ccccc3c3ccccc32)c1] | 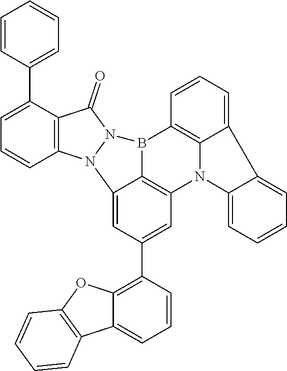 [SMILES: O=c1c2c(-c3ccccc3)cccc2n2n1B1c3c(cc(-c4cccc5c4oc4ccccc45)cc3-2)-n2c3ccccc3c3cccc1c32] | 17% |
| | 1699755-95-7 | | |
| | LS5 | | |
| B30 | 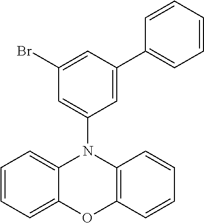 [SMILES: Brc1cc(-c2ccccc2)cc(N2c3ccccc3Oc3ccccc32)c1] | 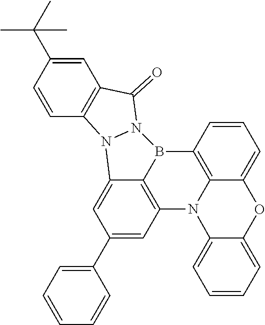 [SMILES: CC(C)(C)c1ccc2c(c1)c(=O)n1n2-c2cc(-c3ccccc3)cc3c2B1c1cccc2c1N3c1ccccc1O2] | 24% |
| | 1313412-22-4 | | |
| | LS3 | | |
| B31 | 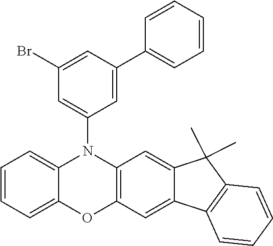 [SMILES: CC1(C)c2ccccc2-c2cc3c(cc21)N(c1cc(Br)cc(-c2ccccc2)c1)c1ccccc1O3] | 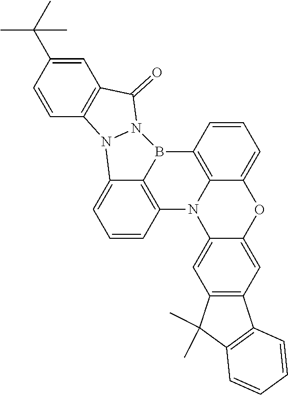 [SMILES: CC(C)(C)c1ccc2c(c1)c(=O)n1n2-c2cccc3c2B1c1cccc2c1N3c1cc3c(cc1O2)-c1ccccc1C3(C)C] | 16% |
| | 2134579-54-5 | | |
| | LS3 | | |
| B32 | 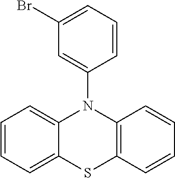 [SMILES: Brc1cccc(N2c3ccccc3Sc3ccccc32)c1] | 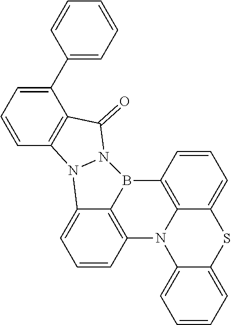 [SMILES: O=c1c2c(-c3ccccc3)cccc2n2n1B1c3cccc4c3N(c3ccccc3S4)c3cccc-2c31] | 13% |
| | 345924-30-3 | | |
| | LS5 | | |
| B33 | 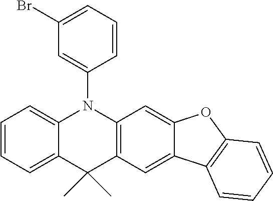 [SMILES: CC1(C)c2ccccc2N(c2cccc(Br)c2)c2cc3oc4ccccc4c3cc21] | 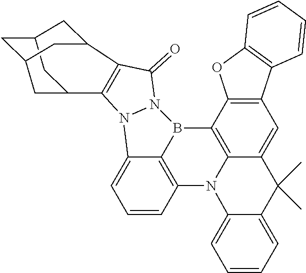 [SMILES: CC1(C)c2ccccc2N2c3cccc4c3B(c3c2c1cc1c3oc2ccccc21)n1c(=O)c2c(n1-4)C1CC3CC(CC2C3)C1] | 15% |
| | 2408582-90-9 | | |
| | LS12 | | |
| B34 | 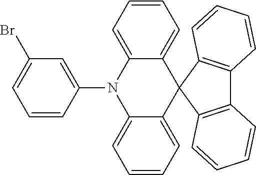 [SMILES: Brc1cccc(N2c3ccccc3C3(c4ccccc4-c4ccccc43)c3ccccc32)c1] | 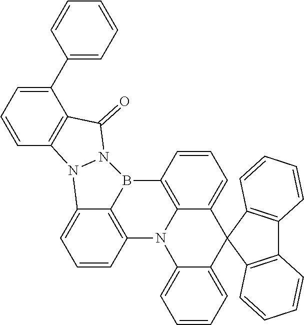 [SMILES: O=c1c2c(-c3ccccc3)cccc2n2n1B1c3cccc4c3N(c3ccccc3C43c4ccccc4-c4ccccc43)c3cccc-2c31] | 20% |
| | 2098479-76-4 | | |
| | LS5 | | |
| B35 | 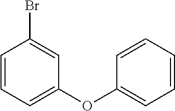 [SMILES: Brc1cccc(Oc2ccccc2)c1] | 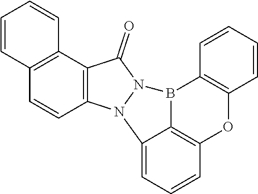 [SMILES: O=c1c2c3ccccc3ccc2n2n1B1c3ccccc3Oc3cccc-2c31] | 16% |
| | 6876-00-2 | | |
| | LS7 | | |
| B36 | 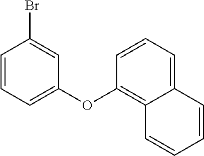 [SMILES: Brc1cccc(Oc2cccc3ccccc23)c1] | 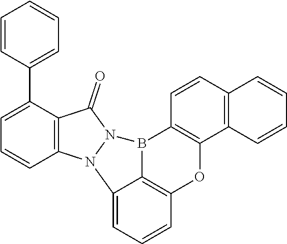 [SMILES: O=c1c2c(-c3ccccc3)cccc2n2n1B1c3ccc4ccccc4c3Oc3cccc-2c31] | 18% |
| | 2053644-32-7 | | |
| | LS5 | | |
| B37 | 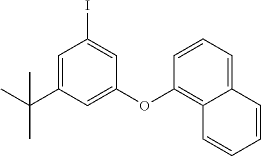 [SMILES: CC(C)(C)c1cc(I)cc(Oc2cccc3ccccc23)c1] | 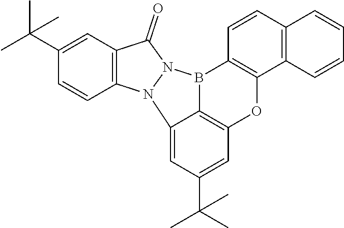 [SMILES: CC(C)(C)c1cc2c3c(c1)-n1c4ccc(C(C)(C)C)cc4c(=O)n1B3c1ccc3ccccc3c1O2] | 17% |
| | 2440166-44-7 | | |
| | LS3 | | |
| B38 | 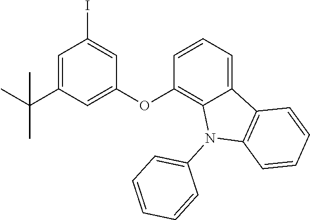 [SMILES: CC(C)(C)c1cc(I)cc(Oc2cccc3c4ccccc4n(-c4ccccc4)c23)c1] | 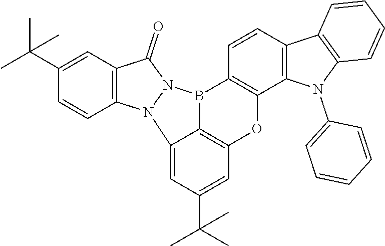 [SMILES: CC(C)(C)c1cc2c3c(c1)-n1c4ccc(C(C)(C)C)cc4c(=O)n1B3c1ccc3c4ccccc4n(-c4ccccc4)c3c1O2] | 17% |
| | 2440166-46-9 | | |
| | LS3 | | |
| B39 | 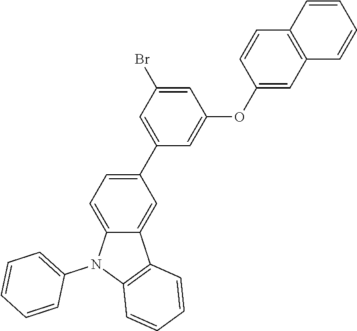 [SMILES: Brc1cc(Oc2ccc3ccccc3c2)cc(-c2ccc3c(c2)c2ccccc2n3-c2ccccc2)c1] | 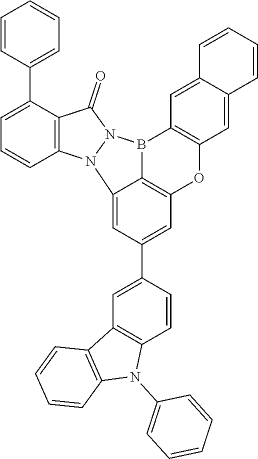 [SMILES: O=c1c2c(-c3ccccc3)cccc2n2n1B1c3cc4ccccc4cc3Oc3cc(-c4ccc5c(c4)c4ccccc4n5-c4ccccc4)cc-2c31] | 21% |
| | 1894186-07-2 | | |
| | LS5 | | |
| B40 | 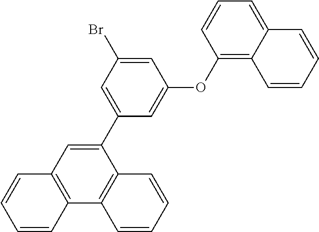 [SMILES: Brc1cc(Oc2cccc3ccccc23)cc(-c2cc3ccccc3c3ccccc23)c1] | 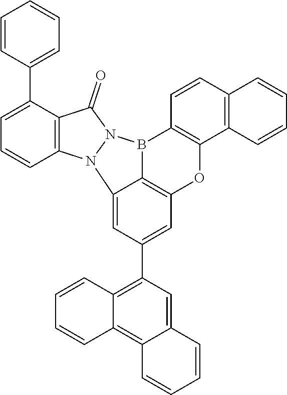 [SMILES: O=c1c2c(-c3ccccc3)cccc2n2n1B1c3ccc4ccccc4c3Oc3cc(-c4cc5ccccc5c5ccccc45)cc-2c31] | 16% |
| | 2242423-27-2 | | |
| | LS5 | | |
| B41 | 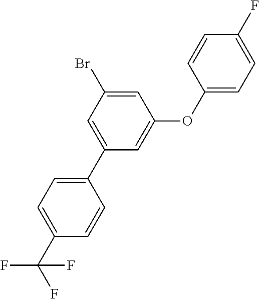 [SMILES: Fc1ccc(Oc2cc(Br)cc(-c3ccc(C(F)(F)F)cc3)c2)cc1] | 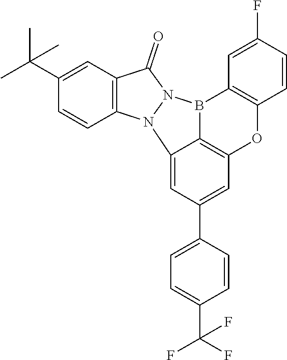 [SMILES: CC(C)(C)c1ccc2c(c1)c(=O)n1n2-c2cc(-c3ccc(C(F)(F)F)cc3)cc3c2B1c1cc(F)ccc1O3] | 13% |
| | 1579852-37-1 | | |
| | LS3 | | |
| B42 | 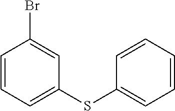 [SMILES: Brc1cccc(Sc2ccccc2)c1] | 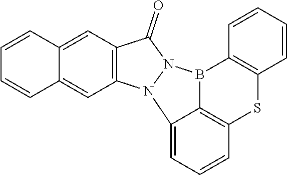 [SMILES: O=c1c2cc3ccccc3cc2n2n1B1c3ccccc3Sc3cccc-2c31] | 9% |
| | 52089-10-8 | | |
| | LS6 | | |
| B43 | 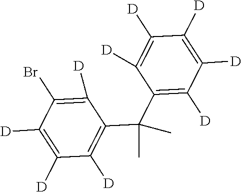 [SMILES: [2H]c1c([2H])c([2H])c(C(C)(C)c2c([2H])c([2H])c([2H])c(Br)c2[2H])c([2H])c1[2H]] | 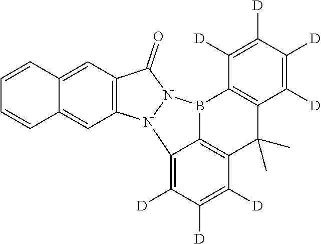 [SMILES: [2H]c1c([2H])c([2H])c2c(c1[2H])B1c3c(c([2H])c([2H])c([2H])c3C2(C)C)-n2c3cc4ccccc4cc3c(=O)n21] | 13% |
| | 2648147-34-4 | | |
| | LS6 | | |
| B44 | 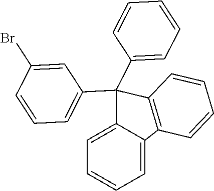 [SMILES: Brc1cccc(C2(c3ccccc3)c3ccccc3-c3ccccc32)c1] | 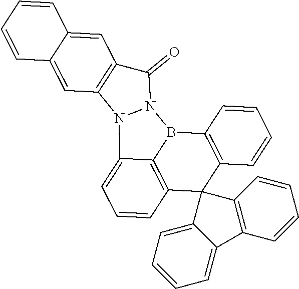 [SMILES: O=c1c2cc3ccccc3cc2n2n1B1c3ccccc3C3(c4ccccc4-c4ccccc43)c3cccc-2c31] | 15% |
| | 1257251-75-4 | | |
| | LS6 | | |
| B45 | 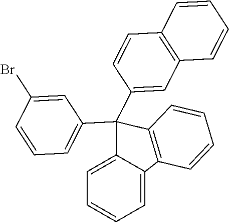 [SMILES: Brc1cccc(C2(c3ccc4ccccc4c3)c3ccccc3-c3ccccc32)c1] | 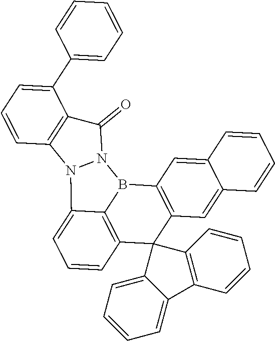 [SMILES: O=c1c2c(-c3ccccc3)cccc2n2n1B1c3cc4ccccc4cc3C3(c4ccccc4-c4ccccc43)c3cccc-2c31] | 12% |
| | 2416771-53-2 | | |
| | LS5 | | |
| B46 | 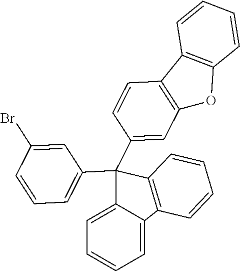 [SMILES: Brc1cccc(C2(c3ccc4c(c3)oc3ccccc34)c3ccccc3-c3ccccc32)c1] | 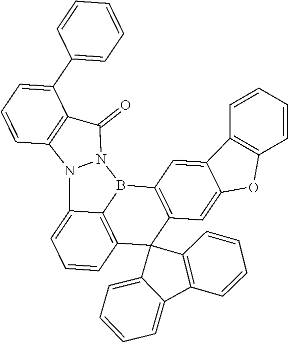 [SMILES: O=c1c2c(-c3ccccc3)cccc2n2n1B1c3cc4c(cc3C3(c5ccccc5-c5ccccc53)c3cccc-2c31)oc1ccccc14] | 17% |
| | 2416771-62-3 | | |
| | LS5 | | |
| B47 | 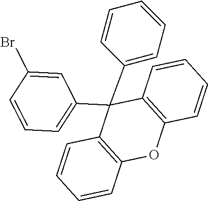 [SMILES: Brc1cccc(C2(c3ccccc3)c3ccccc3Oc3ccccc32)c1] | 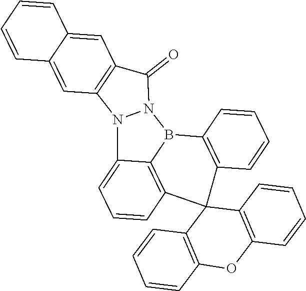 [SMILES: O=c1c2cc3ccccc3cc2n2n1B1c3ccccc3C3(c4ccccc4Oc4ccccc43)c3cccc-2c31] | 14% |
| | 1609484-24-3 | | |
| | LS6 | | |
| B48 | 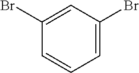 | 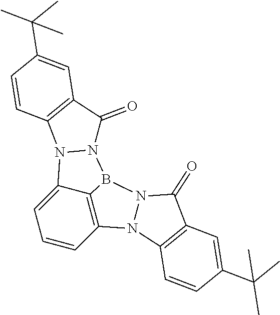 [SMILES: CC(C)(C)c1ccc2c(c1)c(=O)n1n2-c2cccc3c2B1n1c(=O)c2cc(C(C)(C)C)ccc2n1-3] | 25% |
| | 108-36-1 | | |
| | 50 mmol in stage A) | | |
| | LS3 | | |
| | Use of 25 mmol of | | |
| | stage A) in stage B) | | |
| B49 | 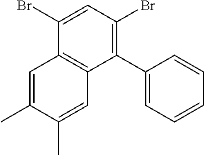 [SMILES: Cc1cc2c(Br)cc(Br)c(-c3ccccc3)c2cc1C] | 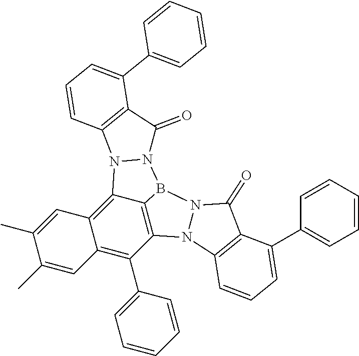 [SMILES: Cc1cc2c(-c3ccccc3)c3c4c(c2cc1C)-n1c2cccc(-c5ccccc5)c2c(=O)n1B4n1c(=O)c2c(-c4ccccc4)cccc2n1-3] | 20% |
| | 1680203-50-2 | | |
| | 50 mmol in stage A) | | |
| | LS5 | | |
| | Use of 25 mmol of | | |
| | stage A) in stage B) | | |
| B50 | 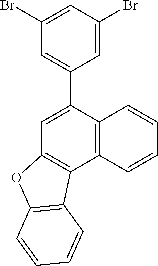 [SMILES: Brc1cc(Br)cc(-c2cc3oc4ccccc4c3c3ccccc23)c1] | 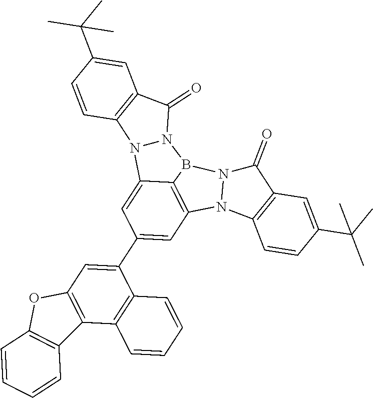 [SMILES: CC(C)(C)c1ccc2c(c1)c(=O)n1n2-c2cc(-c3cc4oc5ccccc5c4c4ccccc34)cc3c2B1n1c(=O)c2cc(C(C)(C)C)ccc2n1-3] | 19% |
| | 2059982-89-5 | | |
| | 50 mmol in stage A) | | |
| | LS3 | | |
| | Use of 25 mmol of | | |
| | stage A) in stage B) | | |
| B51 | 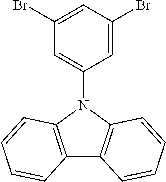 [SMILES: Brc1cc(Br)cc(-n2c3ccccc3c3ccccc32)c1] | 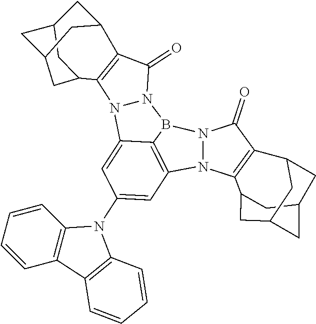 [SMILES: O=c1c2c(n3n1B1c4c-3cc(-n3c5ccccc5c5ccccc53)cc4-n3c4c(c(=O)n31)C1CC3CC(C1)CC4C3)C1CC3CC(CC2C3)C1] | 24% |
| | 750573-26-3 | | |
| | 50 mmol in stage A) | | |
| | LS10 | | |
| | Use of 25 mmol of | | |
| | stage A) in stage B) | | |

### Example B100

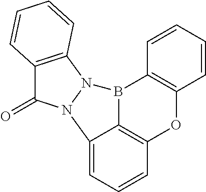 [SMILES: O=c1c2ccccc2n2n1-c1cccc3c1B2c1ccccc1O3]

### Stage A):

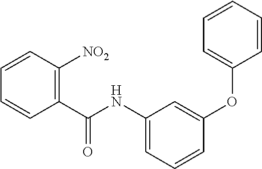 [SMILES: O=C(Nc1cccc(Oc2ccccc2)c1)c1ccccc1[N+](=O)[O-]]

Preparation analogous to K. J. Wicht et al., J. Med. Chem. 2016, 59, 6512. Added dropwise to a well-stirred solution, cooled to 0° C., of 1.85 g (10 mmol) of 3-phenoxyaniline [3586-12-7] in a mixture of 50 ml of DCM and 10 ml of pyridine is a solution of 1.86 g (10 mmol) of 2-nitrobenzoyl chloride [610-14-0] in 50 ml of DCM. The reaction mixture is allowed to warm up to room temperature and stirred until conversion is complete (about 6 h). The reaction mixture is poured on to 200 ml of ice water, and the organic phase is separated off, washed twice with 100 ml each time of water and once with 100 ml of saturated sodium chloride solution, and dried over sodium sulfate. The desiccant is filtered off, the filtrate is concentrated under reduced pressure, and the residue is subjected to hot extraction by stirring with 30 ml of methanol. Yield: 3.0 g (9.0 mmol), 90%; purity: about 97% by ¹H NMR.

### Stage B): B100

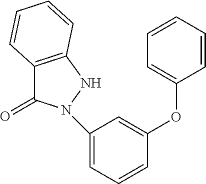 [SMILES: O=c1c2ccccc2[nH]n1-c1cccc(Oc2ccccc2)c1]

Procedure analogous to Y. Bao et al., Org. Lett. 2020, 22, 6277. Added dropwise to a well-stirred mixture, cooled to 0° C., of 3.34 g (10 mmol) of 2-nitro-N-(3-phenoxyphenyl)benzamide [1286040-75-2] stage A), 4.48 g (50 mmol) of tetrahydroxydiboron [13675-18-8] and 150 ml of methanol is a solution of 2.40 g (100 mmol) of NaOH in a mixture of 140 ml of methanol and 10 ml of water. The mixture is stirred at 0° C. for a further 30 min, then allowed to warm up to room temperature and stirred at 40° C. for a further 16 h. Then 200 ml of 0.5 N aqueous acetic acid is added dropwise and the mixture is concentrated under reduced pressure to about 100 ml. The precipitated product is filtered off, washed three times with 30 ml each time of water and twice dried azeotropically with 100 ml each time of toluene, and residues of toluene are removed by drying under reduced pressure. Yield: 2.54 g (8.4 mmol), 84%; purity: about 98% by ¹H NMR.

### C) B100

Procedure analogous to examples B1 stage B). Starting materials: 3.02 g (10 mmol) of stage B). Yield: 440 mg (1.41 mmol), 14%; purity: about 99.9% by ¹H NMR.

The following compounds can be prepared analogously:

| Ex. | Reactant | Product | Yield |
|---|---|---|---|
| B101 | 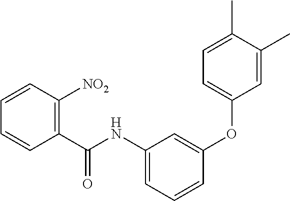 [SMILES: Cc1ccc(Oc2cccc(NC(=O)c3ccccc3[N+](=O)[O-])c2)cc1C] | 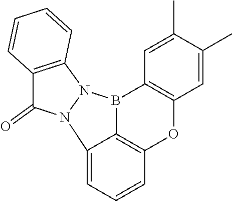 [SMILES: Cc1cc2c(cc1C)B1c3c(cccc3-n3c(=O)c4ccccc4n31)O2] | 19% |
| | 1030588-95-4 | | |
| | from stage B) | | |
| B102 | 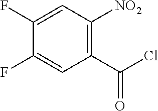 [SMILES: O=C(Cl)c1cc(F)c(F)cc1[N+](=O)[O-]] | 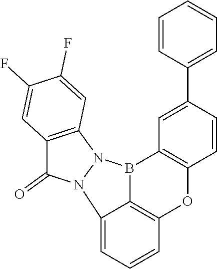 [SMILES: O=c1c2cc(F)c(F)cc2n2n1-c1cccc3c1B2c1cc(-c2ccccc2)ccc1O3] | 15% |
| | 129951-46-8 | | |
| | 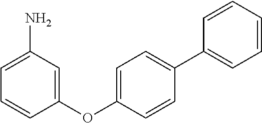 [SMILES: Nc1cccc(Oc2ccc(-c3ccccc3)cc2)c1] | | |
| | 887580-43-0 | | |
| B103 | 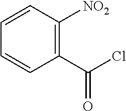 [SMILES: O=C(Cl)c1ccccc1[N+](=O)[O-]] | 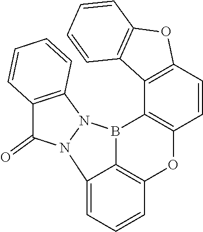 [SMILES: O=c1c2ccccc2n2n1-c1cccc3c1B2c1c(ccc2oc4ccccc4c12)O3] | 10% |
| | 610-14-0 | | |
| | 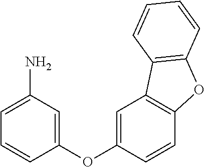 [SMILES: Nc1cccc(Oc2ccc3oc4ccccc4c3c2)c1] | | |
| | 625107-12-2 | | |
| B104 | 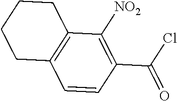 [SMILES: O=C(Cl)c1ccc2c(c1[N+](=O)[O-])CCCC2] | 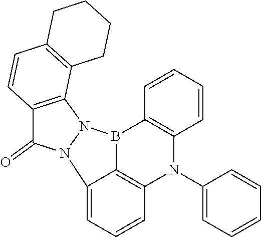 [SMILES: O=c1c2ccc3c(c2n2n1-c1cccc4c1B2c1ccccc1N4c1ccccc1)CCCC3] | 18% |
| | 832151-90-3 | | |
| | 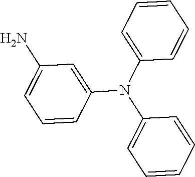 [SMILES: Nc1cccc(N(c2ccccc2)c2ccccc2)c1] | | |
| | 116724-06-2 | | |
| B105 | 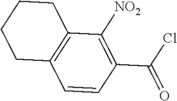 [SMILES: O=C(Cl)c1ccc2c(c1[N+](=O)[O-])CCCC2] | 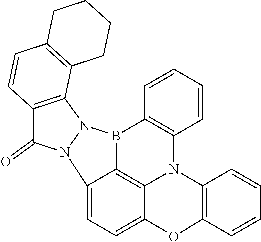 [SMILES: O=c1c2ccc3c(c2n2n1-c1ccc4c5c1B2c1ccccc1N5c1ccccc1O4)CCCC3] | 17% |
| | 832151-90-3 | | |
| | 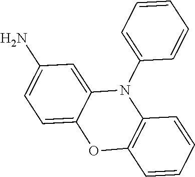 [SMILES: Nc1ccc2c(c1)N(c1ccccc1)c1ccccc1O2] | | |
| | 2222100-10-7 | | |
| B106 | 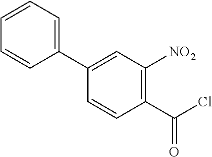 [SMILES: O=C(Cl)c1ccc(-c2ccccc2)cc1[N+](=O)[O-]] | 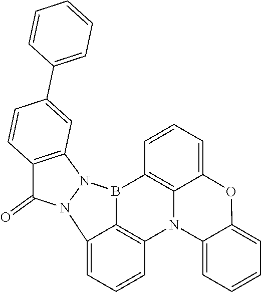 [SMILES: O=c1c2ccc(-c3ccccc3)cc2n2n1-c1cccc3c1B2c1cccc2c1N3c1ccccc1O2] | 15% |
| | 99847-46-8 | | |
| | 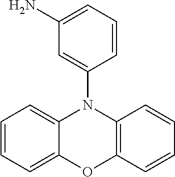 [SMILES: Nc1cccc(N2c3ccccc3Oc3ccccc32)c1] | | |
| | 58737-02-3 | | |
| B107 | 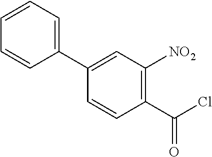 [SMILES: O=C(Cl)c1ccc(-c2ccccc2)cc1[N+](=O)[O-]] | 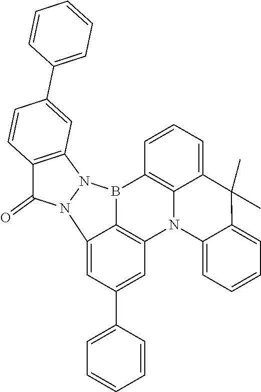 [SMILES: CC1(C)c2ccccc2N2c3cc(-c4ccccc4)cc4c3B(c3cccc1c32)n1c2cc(-c3ccccc3)ccc2c(=O)n1-4] | 21% |
| | 99847-46-8 | | |
| | 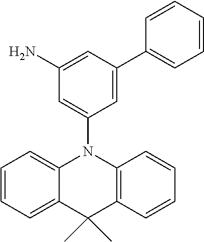 [SMILES: CC1(C)c2ccccc2N(c2cc(N)cc(-c3ccccc3)c2)c2ccccc21] | | |
| | 2459228-95-4 | | |
| B108 | 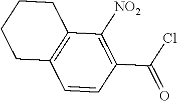 [SMILES: O=C(Cl)c1ccc2c(c1[N+](=O)[O-])CCCC2] | 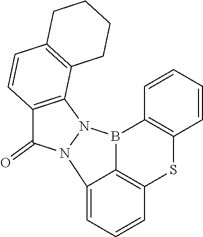 [SMILES: O=c1c2ccc3c(c2n2n1-c1cccc4c1B2c1ccccc1S4)CCCC3] | 11% |
| | 832151-90-3 | | |
| | 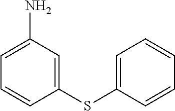 [SMILES: Nc1cccc(Sc2ccccc2)c1] | | |
| | 3985-12-4 | | |
| B109 | 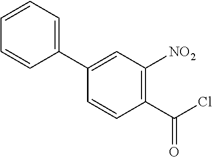 [SMILES: O=C(Cl)c1ccc(-c2ccccc2)cc1[N+](=O)[O-]] | 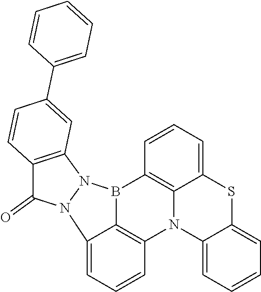 [SMILES: O=c1c2ccc(-c3ccccc3)cc2n2n1-c1cccc3c1B2c1cccc2c1N3c1ccccc1S2] | 12% |
| | 99847-46-8 | | |
| | 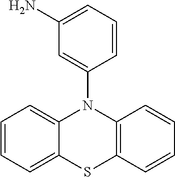 [SMILES: Nc1cccc(N2c3ccccc3Sc3ccccc32)c1] | | |
| | 58736-39-3 | | |
| B110 | 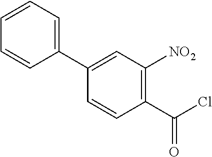 [SMILES: O=C(Cl)c1ccc(-c2ccccc2)cc1[N+](=O)[O-]] | 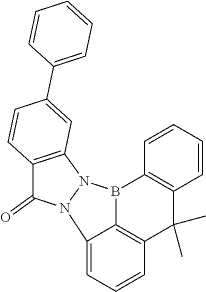 [SMILES: CC1(C)c2ccccc2B2c3c(cccc31)-n1c(=O)c3ccc(-c4ccccc4)cc3n12] | 10% |
| | 99847-46-8 | | |
| | 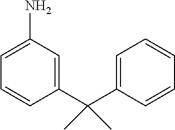 [SMILES: CC(C)(c1ccccc1)c1cccc(N)c1] | | |
| | 1786434-59-0 | | |
| B111 | 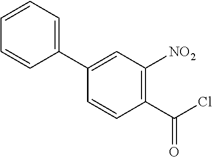 [SMILES: O=C(Cl)c1ccc(-c2ccccc2)cc1[N+](=O)[O-]] | 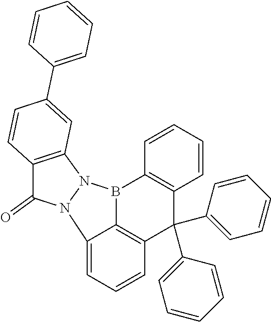 [SMILES: O=c1c2ccc(-c3ccccc3)cc2n2n1-c1cccc3c1B2c1ccccc1C3(c1ccccc1)c1ccccc1] | 8% |
| | 99847-46-8 | | |
| | 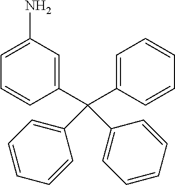 [SMILES: Nc1cccc(C(c2ccccc2)(c2ccccc2)c2ccccc2)c1] | | |
| | 114999-33-6 | | |
| B112 | 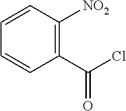 [SMILES: O=C(Cl)c1ccccc1[N+](=O)[O-]] | 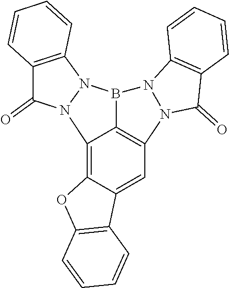 [SMILES: O=c1c2ccccc2n2n1-c1cc3c(oc4ccccc43)c3c1B2n1c2ccccc2c(=O)n1-3] | 12% |
| | 610-14-0 | | |
| | 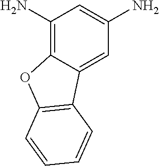 [SMILES: Nc1cc(N)c2oc3ccccc3c2c1] | | |
| | 866362-01-8 | | |
| | 5 mmol in stage A) | | |
| | Use of 5 mmol of | | |
| | stage A) in stage B) | | |

### Example: Production of the OLEDs

### 1) Vacuum-Processed Devices:

OLEDs of the invention and OLEDs according to the prior art are produced by a general method according to WO 2004/058911, which is adapted to the circumstances described here (variation in layer thickness, materials used).

In the examples which follow, the results for various OLEDs are presented. Cleaned glass plates (cleaning in Miele laboratory glass washer, Merck Extran detergent) coated with structured ITO (indium tin oxide) of thickness 50 nm are pretreated with UV ozone for 25 minutes (PR-100 UV ozone generator from UVP) and, within 30 min, for improved processing, coated with 20 nm of PEDOT:PSS (poly(3,4-ethylenedioxythiophene) poly(styrenesulfonate), purchased as CLEVIOS™ P VP Al 4083 from Heraeus Precious Metals GmbH Deutschland, spun on from aqueous solution) and then baked at 180° C. for 10 min. These coated glass plates form the substrates to which the OLEDs are applied.

### 1a) Blue and Green Fluorescence OLED Components—BF and GF:

All materials are applied by thermal vapor deposition in a vacuum chamber. The emission layer (EML) here always consists of at least one matrix material (host material) SMB (see table 1) and an emitting dopant (dopant, emitter) B, which is added to the matrix material(s) in a particular proportion by volume by co-evaporation. Details given in such a form as SMB:B (97:3%) mean here that the material SMB is present in the layer in a proportion by volume of 97% and the dopant B in a proportion of 3%. Analogously, the electron transport layer may also consist of a mixture of two materials; see table 1. The materials used for production of the OLEDs are shown in table 5.

The OLEDs are characterized in a standard manner. For this purpose, the electroluminescence spectra, the current efficiency (measured in cd/A), the power efficiency (measured in lm/W) and the external quantum efficiency (EQE, measured in percent) as a function of luminance, calculated from current-voltage-luminance characteristics (IUL characteristics) assuming Lambertian emission characteristics, and also the lifetime are determined. Electroluminescence spectra are determined at a luminance of 1000 cd/m², and these are used to determine the color and the FWHM (full width at half maximum).

The OLEDs have the following layer structure:
Substrate
Hole injection layer 1 (HIL1) composed of HTM1 doped with 5% NDP-9 (commercially available from Novaled), 20 nm
Hole transport layer 1 (HTL1) composed of HTM1, 140 nm
Hole transport layer 2 (HTL2) composed of HTM2, 10 nm
Emission layer (EML), see table 1
Electron transport layer (ETL2), see table 1
Electron transport layer (ETL1), see table 1

TABLE 1
Structure of blue and green fluorescent OLED components

| Ex. | EML | ETL2 | ETL1 |
|---|---|---|---|
| BF1 | SMB1:B3 (97:3%) | — | ETM1:ETM2 (50:50%) |
| | 20 nm | | 30 nm |
| BF2 | SMB2:B5 (97:3%) | — | ETM1:ETM2 (50:50%) |
| | 20 nm | | 30 nm |
| BF3 | SMB3:B8 (97:3%) | — | ETM1:ETM2 (50:50%) |
| | 20 nm | | 30 nm |
| BF4 | SMB1:B14 (97:3%) | — | ETM1:ETM2 (50:50%) |
| | 20 nm | | 30 nm |
| BF5 | SMB1:B16 (97:3%) | — | ETM1:ETM2 (50:50%) |
| | 20 nm | | 30 nm |
| BF6 | SMB1:B23 (97:3%) | — | ETM1:ETM2 (50:50%) |
| | 20 nm | | 30 nm |
| BF7 | SMB1:B24 (97:3%) | ETM1 | ETM1:ETM2 (50:50%) |
| | 20 nm | 5 nm | 30 nm |
| BF8 | SMB1:B26 (97:3%) | ETM1 | ETM1:ETM2 (50:50%) |
| | 20 nm | 5 nm | 30 nm |
| BF9 | SMB1:B28 (97:3%) | — | ETM1:ETM2 (50:50%) |
| | 20 nm | | 30 nm |
| BF10 | SMB1:B33 (97:3%) | — | ETM1:ETM2 (50:50%) |
| | 20 nm | | 30 nm |
| BF11 | SMB1:B35 (97:3%) | — | ETM1:ETM2 (50:50%) |
| | 20 nm | | 30 nm |
| BF12 | SMB1:B45 (97:3%) | — | ETM1:ETM2 (50:50%) |
| | 20 nm | | 30 nm |
| BF13 | SMB1:B48 (95:5%) | — | ETM1:ETM2 (50:50%) |
| | 20 nm | | 30 nm |
| BF14 | SMB1:B51 (97:3%) | — | ETM1:ETM2 (50:50%) |
| | 20 nm | | 30 nm |
| BF15 | SMB1:B107 (97:3%) | — | ETM1:ETM2 (60:40%) |
| | 20 nm | | 30 nm |
| GF1 | SMB1:B7 (97:3%) | — | ETM1:ETM2 (50:50%) |
| | 20 nm | | 30 nm |
| GF2 | SMB1:B12 (97:3%) | — | ETM1:ETM2 (50:50%) |
| | 20 nm | | 30 nm |

Electron injection layer (EIL) composed of ETM2, 1 nm
Cathode composed of aluminum, 100 nm

TABLE 2
Results for blue (420-499 nm) and green
(500-540 nm) fluorescent OLED components

| | EQE (%) | Voltage [V] | | |
|---|---|---|---|---|
| Ex. | 1000 cd/m² | 1000 cd/m² | Color | FWHM [eV] |
| BF1 | 8.8 | 3.7 | blue | 0.20 |
| BF2 | 7.9 | 3.6 | blue | 0.16 |
| BF3 | 7.7 | 3.5 | blue | 0.17 |
| BF4 | 7.2 | 3.7 | blue | 0.22 |
| BF5 | 8.5 | 3.5 | blue | 0.18 |
| BF6 | 8.3 | 3.7 | blue | 0.16 |
| BF7 | 8.8 | 3.5 | blue | 0.16 |
| BF8 | 8.6 | 3.5 | blue | 0.15 |
| BF9 | 9.1 | 3.8 | blue | 0.16 |
| BF10 | 7.9 | 3.6 | blue | 0.18 |
| BF11 | 8.4 | 3.8 | blue | 0.16 |
| BF12 | 8.1 | 3.6 | blue | 0.17 |
| BF13 | 8.8 | 3.8 | blue | 0.21 |
| BF14 | 9.4 | 3.6 | blue | 0.19 |
| BF15 | 7.0 | 3.7 | blue | 0.24 |
| GF1 | 9.1 | 3.3 | green | 0.23 |
| GF2 | 10.3 | 3.3 | green | 0.20 |

### 1 b) Hyperphosphorescent OLED Components:

All materials are applied by thermal vapor deposition in a vacuum chamber. The emission layer(s) (EML) always consist(s) of at least one matrix material (host material) TMM, a (phosphorescent) sensitizer PS and a fluorescent emitter B. Sensitizer PS and fluorescent emitter B are added to the host material TMM in a particular proportion by volume by coevaporation. Details given in such a form as TMM:PS(8%):B(1%) mean here that the material TMM is present in the layer in a proportion by volume of 91%, PS in a proportion of 8% and fluorescent emitter B in a proportion of 1%.

### Blue Hyperphosphorescence OLED Components BH:

The OLEDs basically have the following layer structure:
Substrate
Hole injection layer 1 (HIL1) composed of HTM2 doped with 5% NDP-9 (commercially available from Novaled), 20 nm
Hole transport layer 1 (HTL1) composed of HTM2, 30 nm
Hole transport layer 2 (HTL2), see table 3
Emission layer (EML), see table 3
Electron transport layer (ETL2), see table 3
Electron transport layer (ETL1) composed of ETM1 (50%) and ETM2 (50%), 20 nm
Electron injection layer (EIL) composed of ETM2, 1 nm
Cathode composed of aluminum, 100 nm

TABLE 3
Construction of blue hyperphosphorescence OLED components

| Ex. | HTL2 | EML | ETL2 |
|---|---|---|---|
| BH1 | HTM3 | TMM1:PS1(8%):B21(1%) | ETM3 |
| | 10 nm | 25 nm | 10 nm |
| BH2 | HTM3 | TMM1:PS1(8%):B34(1%) | ETM3 |
| | 10 nm | 25 nm | 10 nm |

TABLE 4
Results

| | EQE (%) | Voltage (V) | | EL-FWHM |
|---|---|---|---|---|
| Ex. | 100 cd/m² | 100 cd/m² | Color | [eV] |
| BH1 | 15.9 | 3.6 | blue | 0.23 |
| BH2 | 17.0 | 3.7 | blue | 0.19 |

TABLE 5
Structural formulae of the materials used

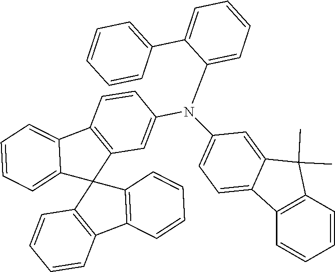 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM1
136463-07-5

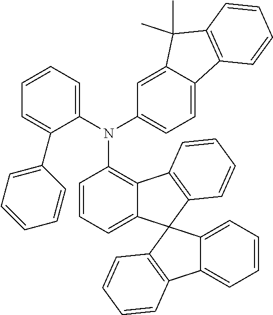 [SMILES: CC1(C)c2ccccc2-c2ccc(N(c3ccccc3-c3ccccc3)c3cccc4c3-c3ccccc3C43c4ccccc4-c4ccccc43)cc21]

HTM2
1450933-44-4

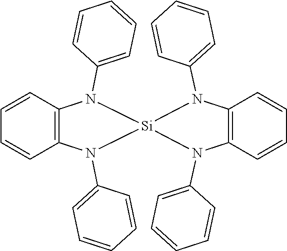 [SMILES: c1ccc(N2c3ccccc3N(c3ccccc3)[Si]23N(c2ccccc2)c2ccccc2N3c2ccccc2)cc1]

HTM3
1206465-62-4

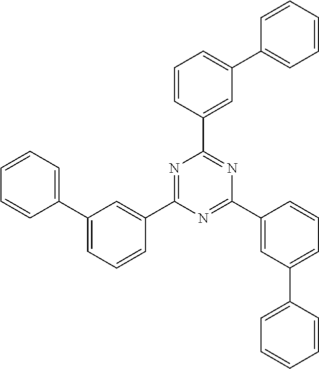 [SMILES: c1ccc(-c2cccc(-c3nc(-c4cccc(-c5ccccc5)c4)nc(-c4cccc(-c5ccccc5)c4)n3)c2)cc1]

TMM1 = ETM3
1201800-83-0

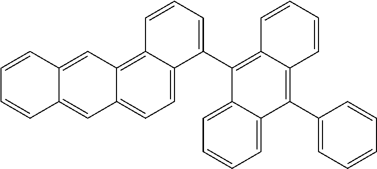 [SMILES: c1ccc(-c2c3ccccc3c(-c3cccc4c3ccc3cc5ccccc5cc34)c3ccccc23)cc1]

SMB1
[1087346-88-0]

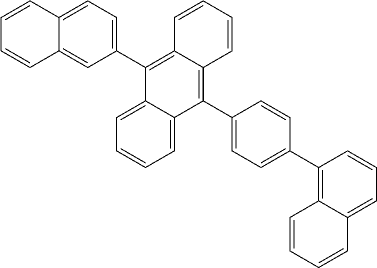 [SMILES: c1ccc2cc(-c3c4ccccc4c(-c4ccc(-c5cccc6ccccc56)cc4)c4ccccc34)ccc2c1]

SMB2
[667940-34-3]

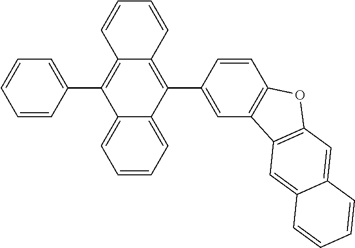 [SMILES: c1ccc(-c2c3ccccc3c(-c3ccc4oc5cc6ccccc6cc5c4c3)c3ccccc23)cc1]

SMB3
[1627916-48-6]

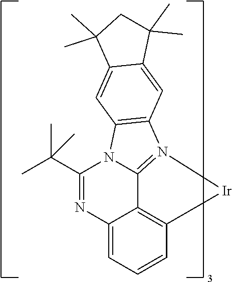

PS1
1541114-98-0

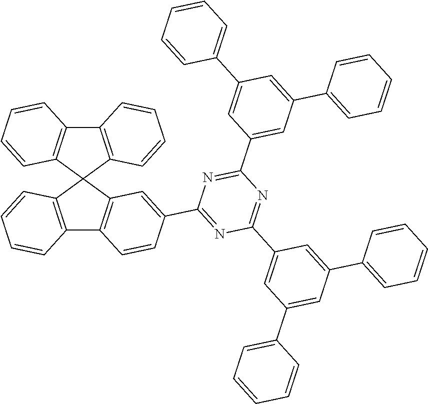 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM1
1233200-52-6

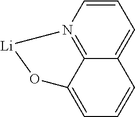

ETM2
25387-93-3

The abbreviations shown in tables 1 and 3 in relation to the materials of the invention, for example B3, B5, B7, B8, B12, B14, B16, B21, B34, B23, B24, B26, B28, B33, B35, B45, B48, B51 and B107 etc., relate to the compounds set out in detail above in the synthesis examples.

The compounds of the invention shown narrow electroluminescence spectra, recognizable by the relatively small EL-FWHM values (ELectroluminescence—Full Width Half Maximum—width of the EL emission spectra in eV at half the peak height). Narrow electroluminescence spectra lead to a distinct improvement in color purity (lower CIE y values). Moreover, very good EQE values (External Quantum Efficiencies) are achieved at low operating voltages, which leads to a distinct improvement in power efficiencies of the device and hence to lower power consumption.

1.-17. (canceled)

18. A compound including at least one structure of the formula (I) 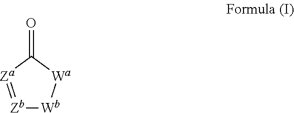
where the further symbols used are as follows:
Z^{a}, Z^{b} is the same or different at each instance and is N, CR, or the Z^{a}, Z^{b} groups form a ring Ar^{a}, where the ring Ar^{a} is the same or different at each instance and is an aromatic or heteroaromatic ring system which has 5 to 60 aromatic ring atoms and may be substituted by one or more Ar or R^{a} radicals, where the ring Ar^{a} together with the CO group and the W^{a}, W^{b} groups forms a 5-membered ring;
W^{a}, W^{b} is the same or different at each instance and is NR, NAr, NB(R)₂ or NB(Ar)₂, where exactly one of the W^{a}, W^{b} groups is NB(R)₂, NB(Ar)₂, and exactly one of the W^{a}, W^{b} groups is NR, NAr, or the W^{a}, W^{b} groups form a ring of the formula 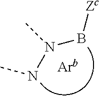
where Z^{c} is R or Ar, the ring Ar^{b} is the same or different at each instance and is an aromatic or heteroaromatic ring system which has 5 to 60 aromatic ring atoms and may be substituted by one or more Ar or R^{b} radicals, where the ring Ar^{b} may form a ring system with an R, Ar or Z^{c} group or the rings Ar^{a} and Ar^{b} together may form a ring system, and the dotted lines represent the bonds to the CO group or Z^{b} group;
Ar is the same or different at each instance and is an aromatic or heteroaromatic ring system which has 5 to 60 aromatic ring atoms and may be substituted by one or more R radicals; the Ar group here may form a ring system with at least one Ar, R, R^{a}, R^{b} group or a further group;
R, R^{a}, R^{b} is the same or different at each instance and is H, D, OH, F, Cl, Br, I, CN, NO₂, N(Ar′)₂, N(R¹)₂, C(═O)N(Ar′)₂, C(═O)N(R¹)₂, C(Ar′)₃, C(R¹)₃, Si(Ar′)₃, Si(R¹)₃, B(Ar′)₂, B(R¹)₂, C(═O)Ar′, C(═O)R¹, P(═O)(Ar′)₂, P(═O)(R¹)₂, P(Ar′)₂, P(R¹)₂, S(═O)Ar′, S(═O)R¹, S(═O)₂Ar′, S(═O)₂R¹, OSO₂Ar′, OSO₂R¹, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 20 carbon atoms, where the alkyl, alkoxy, thioalkoxy, alkenyl or alkynyl group may in each case be substituted by one or more R¹ radicals, where one or more nonadjacent CH₂ groups may be replaced by R¹C═CR¹, C≡C, Si(R¹)₂, C═O, C═S, C═Se, C═NR¹, —C(═O)O—, —C(═O)NR¹—, NR¹, P(═O)(R¹), —O—, —S—, SO or SO₂, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals; or heteroarylthio group which has 5 to 60 aromatic ring atoms and may be substituted by one or more R¹ radicals, or a diarylamino, arylheteroarylamino, diheteroarylamino group which has 5 to 60 aromatic ring atoms and may be substituted by one or more R¹ radicals, or an aralkyl or heteroarylalkyl group which has 5 to 60 aromatic ring atoms and 1 to 10 carbon atoms in the alkyl radical and may be substituted by one or more R¹ radicals; at the same time, two R, R^{a}, R^{b} radicals together or with a further group may also form a ring system;
Ar′ is the same or different at each instance and is an aromatic or heteroaromatic ring system which has 5 to 60 aromatic ring atoms and may be substituted by one or more R¹ radicals; at the same time, it is possible for two Ar′ radicals bonded to the same carbon atom, silicon atom, nitrogen atom, phosphorus atom or boron atom also to be joined together via a bridge by a single bond or a bridge selected from B(R¹), C(R¹)₂, Si(R¹)₂, C═O, C═NR¹, C═C(R¹)₂, O, S, S═O, SO₂, N(R¹), P(R¹) and P(═O)R¹;
R¹ is the same or different at each instance and is H, D, F, Cl, Br, I, CN, NO₂, N(Ar″)₂, N(R²)₂, C(═O)Ar″, C(═O)R², P(═O)(Ar″)₂, P(Ar″)₂, B(Ar″)₂, B(R²)₂, C(Ar″)₃, C(R²)₃, Si(Ar″)₃, Si(R²)₃, a straight-chain alkyl, alkoxy or thioalkoxy group having 1 to 40 carbon atoms or a branched or cyclic alkyl, alkoxy or thioalkoxy group having 3 to 40 carbon atoms or an alkenyl group having 2 to 40 carbon atoms, each of which may be substituted by one or more R² radicals, where one or more nonadjacent CH₂ groups may be replaced by —R²C═CR²—, —C≡C—, Si(R²)₂, C═O, C═S, C═Se, C═NR², —C(═O)O—, —C(═O)NR²—, NR², P(═O)(R²), —O—, —S—, SO or SO₂ and where one or more hydrogen atoms may be replaced by D, F, Cl, Br, I, CN or NO₂, or an aromatic or heteroaromatic ring system which has 5 to 60 aromatic ring atoms, each of which may be substituted by one or more R² radicals, or an aryloxy or heteroaryloxy group which has 5 to 60 aromatic ring atoms and may be substituted by one or more R² radicals, or an aralkyl or heteroaralkyl group which has 5 to 60 aromatic ring atoms and may be substituted by one or more R² radicals, or a combination of these systems; at the same time, two or more R¹ radicals together may form a ring system; at the same time, one or more R¹ radicals may form a ring system with a further part of the compound;
Ar″ is the same or different at each instance and is an aromatic or heteroaromatic ring system which has 5 to 30 aromatic ring atoms and may be substituted by one or more R² radicals; at the same time, it is possible for two Ar″ radicals bonded to the same carbon atom, silicon atom, nitrogen atom, phosphorus atom or boron atom also to be joined together via a bridge by a single bond or a bridge selected from B(R²), C(R²)₂, Si(R²)₂, C═O, C═NR², C═C(R²)₂, O, S, S═O, SO₂, N(R²), P(R²) and P(═O)R²;
R² is the same or different at each instance and is selected from the group consisting of H, D, F, CN, an aliphatic hydrocarbyl radical having 1 to 20 carbon atoms or an aromatic or heteroaromatic ring system which has 5 to 30 aromatic ring atoms and in which one or more hydrogen atoms may be replaced by D, F, Cl, Br, I or CN and which may be substituted by one or more alkyl groups each having 1 to 4 carbon atoms; at the same time, two or more substituents R² together may form a ring system.

19. A compound as claimed in claim 18, characterized in that the W^{a}, W^{b} groups form a ring of the formula 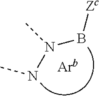
where the symbols Ar^{b} and Z^{c} have the definition given above.

20. A compound as claimed in claim 18, including at least one structure of the formula (II-1) to (II-18): 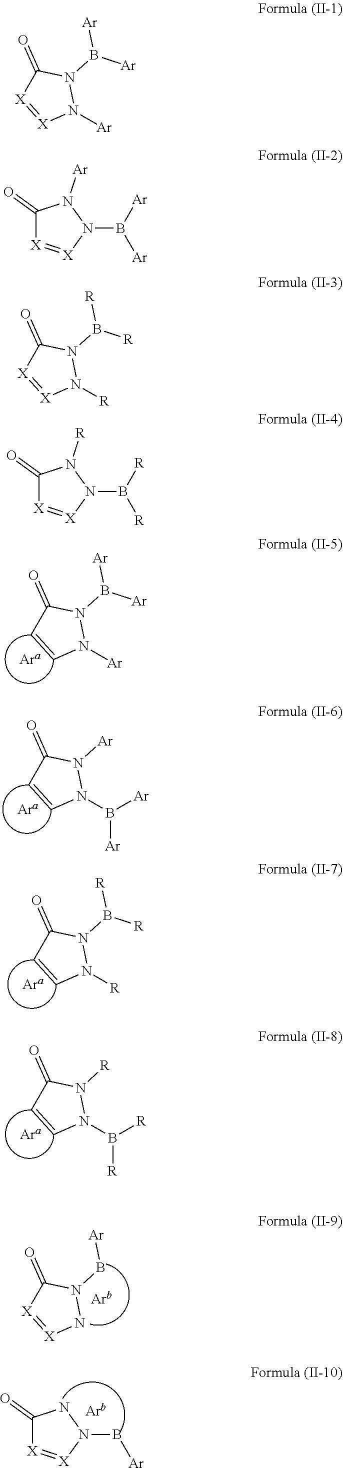 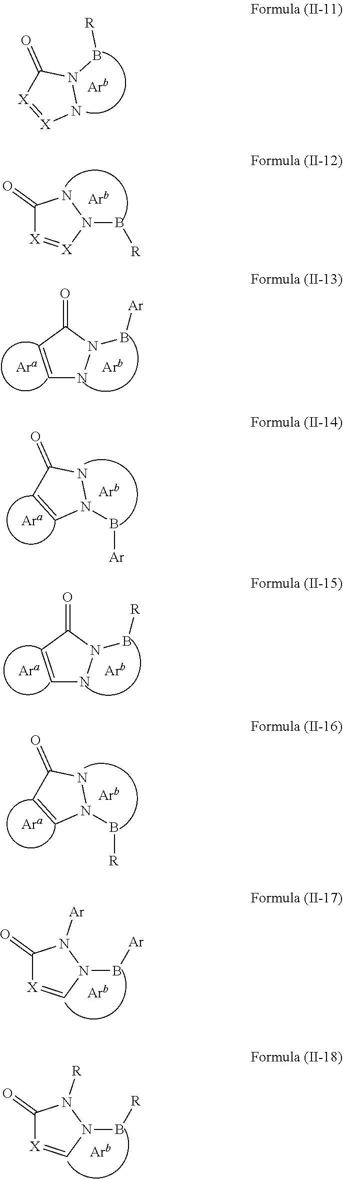
where the symbols R, Ar, Ar^{a} and Ar^{b} have the definitions given in claim 18 and X is the same or different at each instance and is N or CR.

21. A compound as claimed in claim 18, comprising at least one structure of the formulae (III-1) to (III-48): 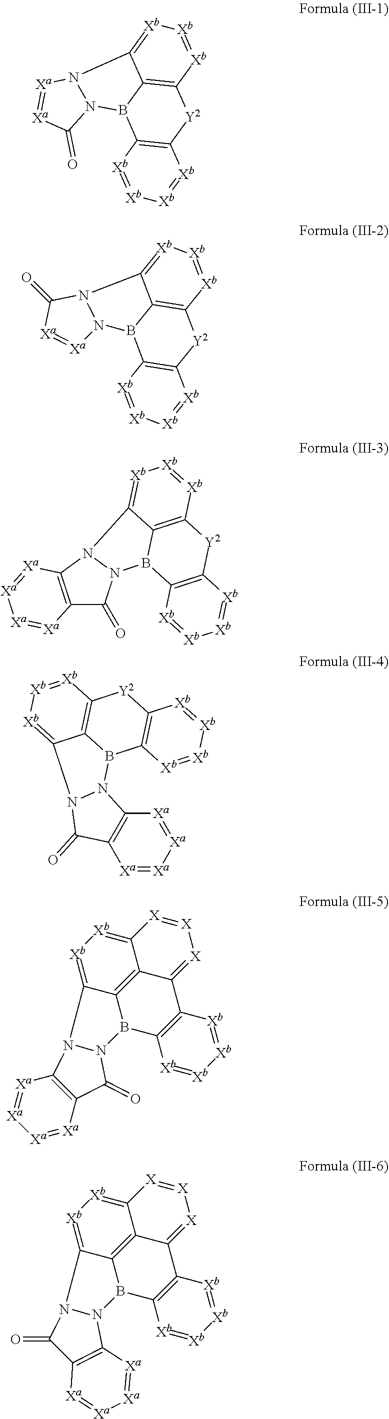 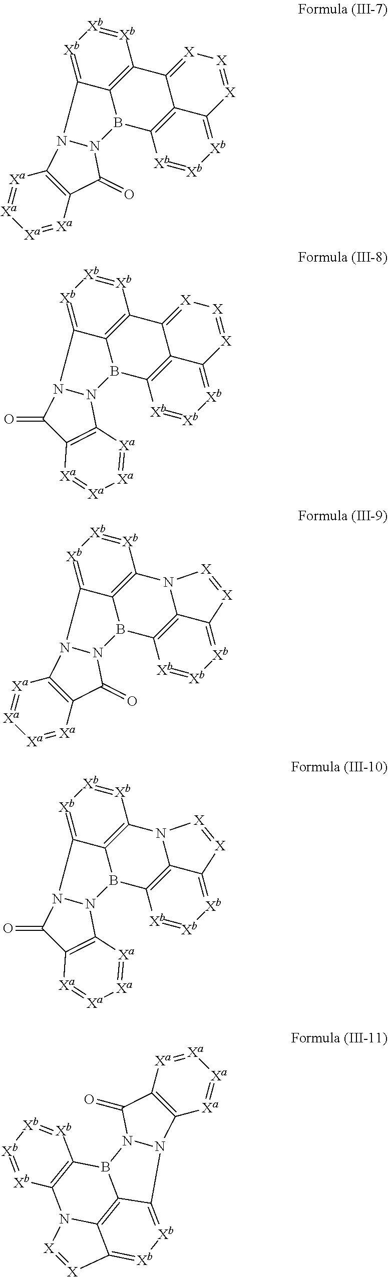 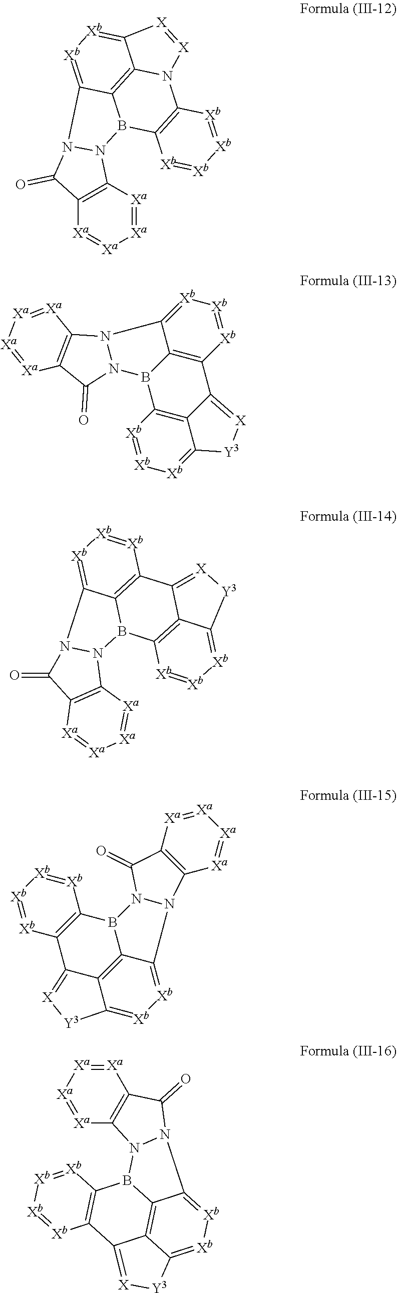 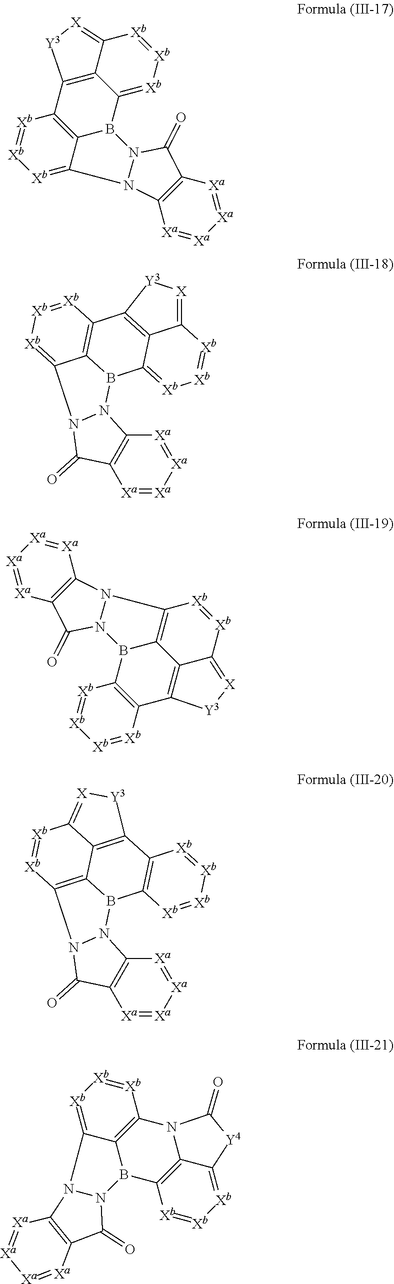 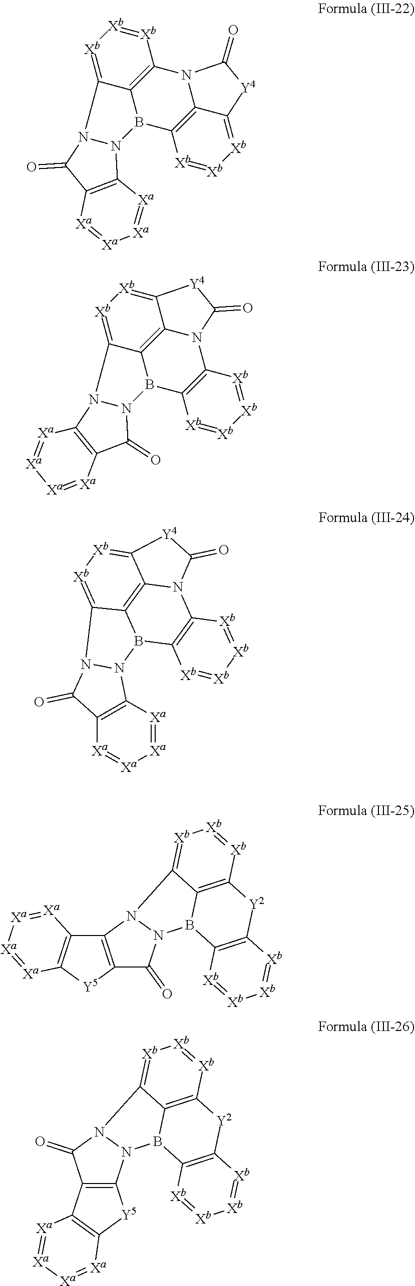 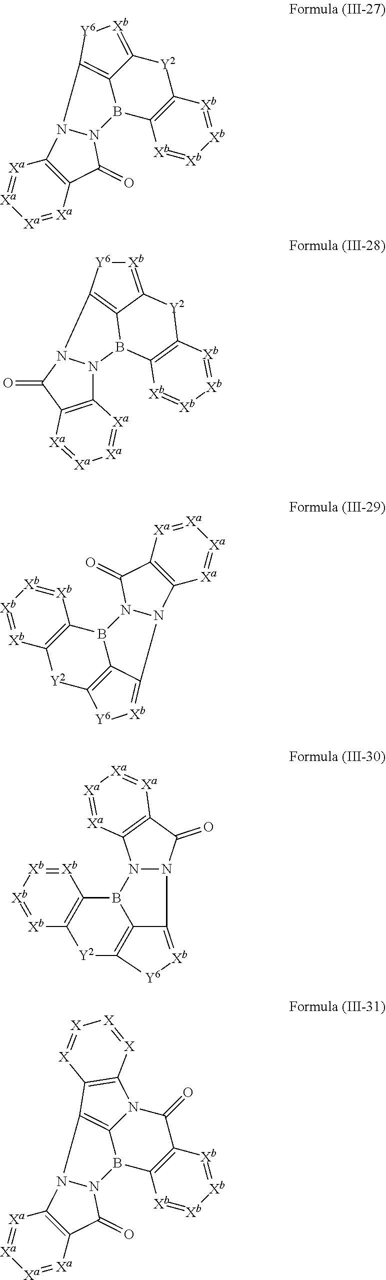 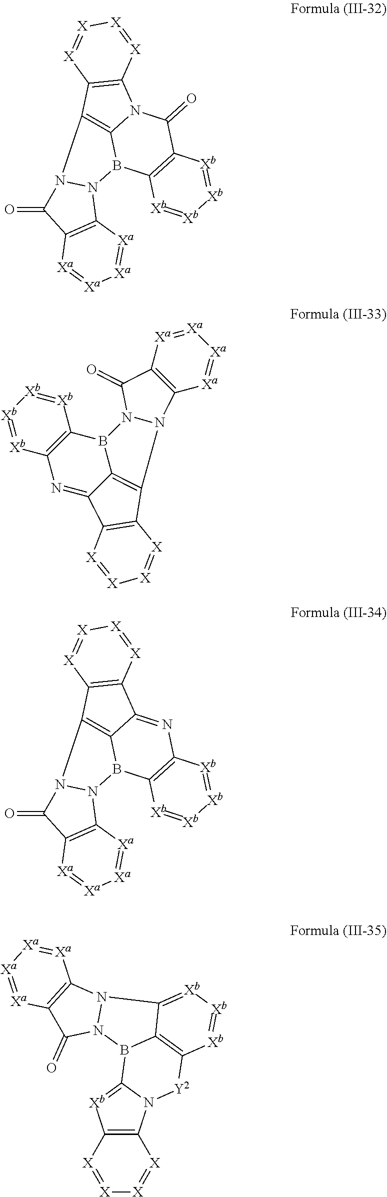 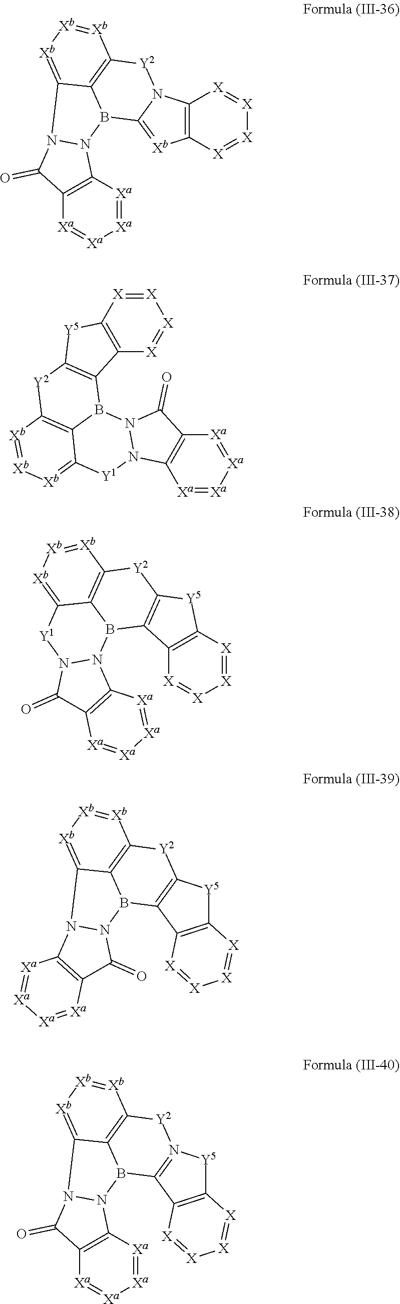 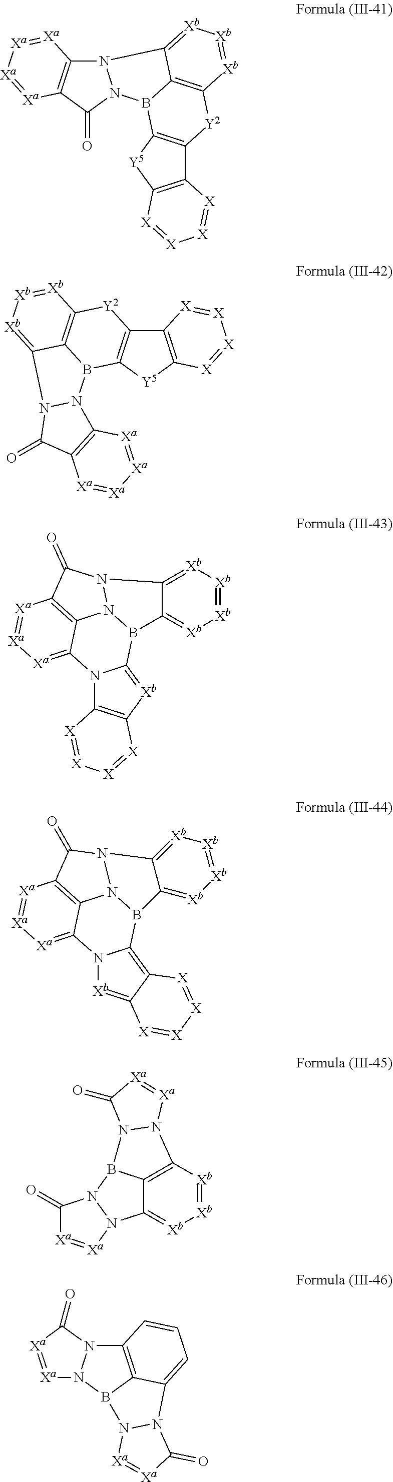 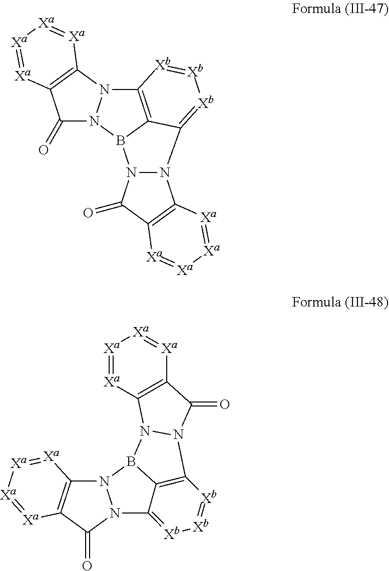
where the symbols Ar and R have the definitions given in claim 18 and the further symbols are as follows:
X is the same or different at each instance and is N or CR, with the proviso that not more than two of the X groups in one cycle are N, where R has the definition detailed in claim 18;
X^{a} is the same or different at each instance and is N or CR^{a}, with the proviso that not more than two of the X^{a} groups in one cycle are N, where R^{a} has the definition detailed in claim 18;
X^{b} is the same or different at each instance and is N or CR^{b}, with the proviso that not more than two of the X^{b} groups in one cycle are N, where R^{b} has the definition detailed in claim 18,
Y¹ is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y² is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y³ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y⁴ is the same or different at each instance and is N(Ar), N(R), P(Ar), P(R), P(═O)Ar, P(═O)R, P(═S)Ar, P(═S)R, C(R)₂, Si(R)₂, O or S, where R has the definition detailed in claim 18;
Y⁵ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y⁶ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18.

22. A compound as claimed in claim 18, comprising at least one structure of the formulae (IV-1) to (IV-48): 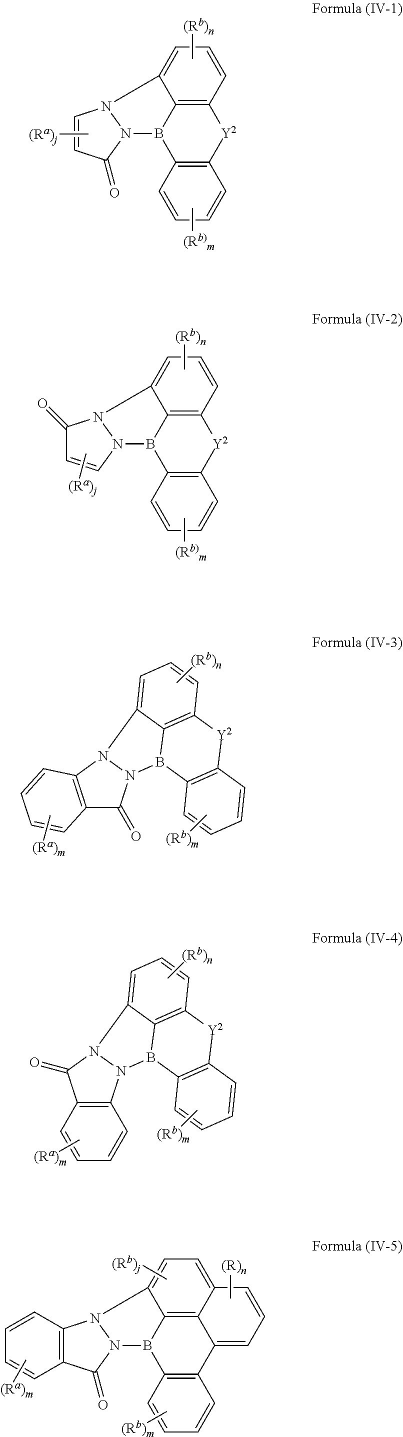 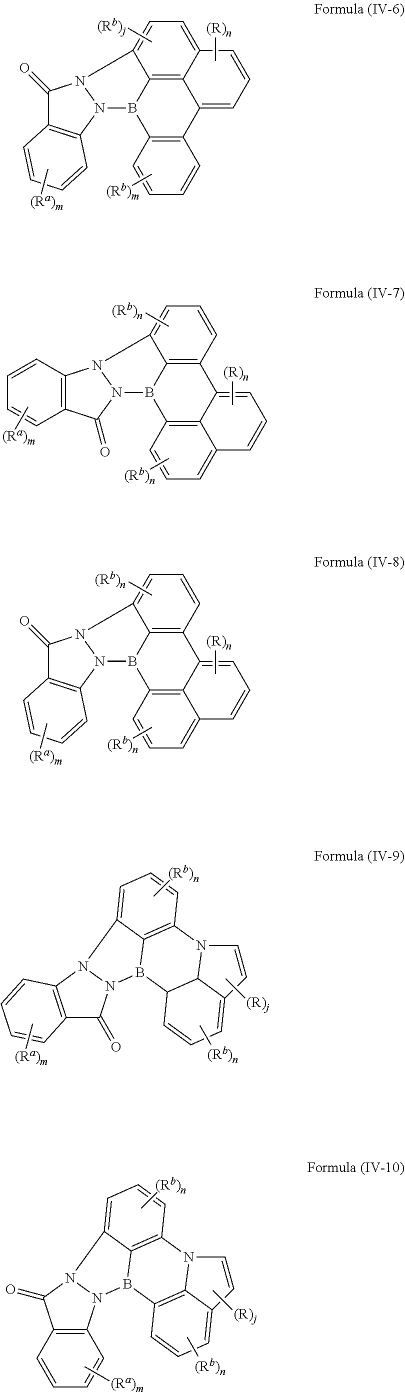 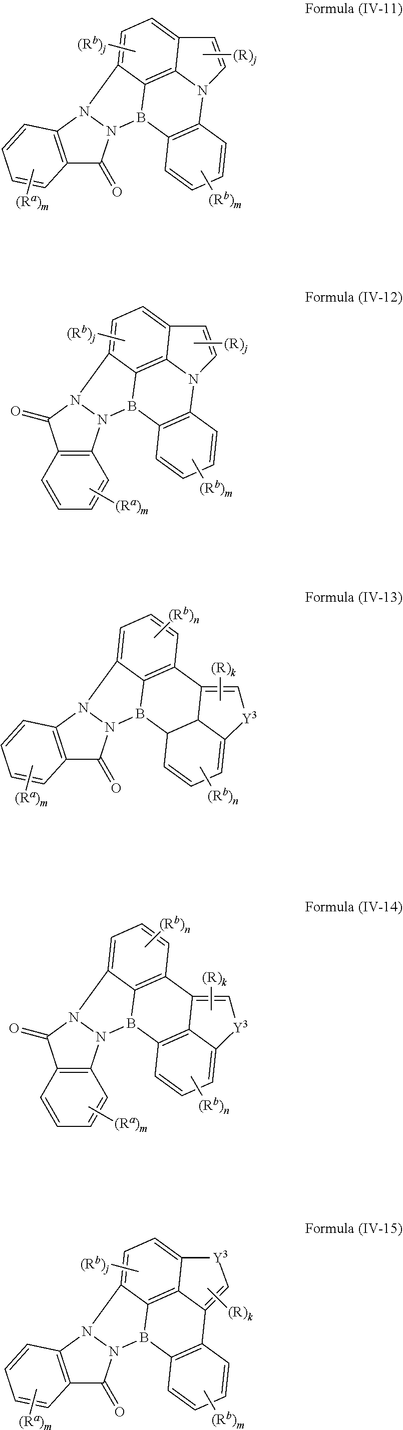 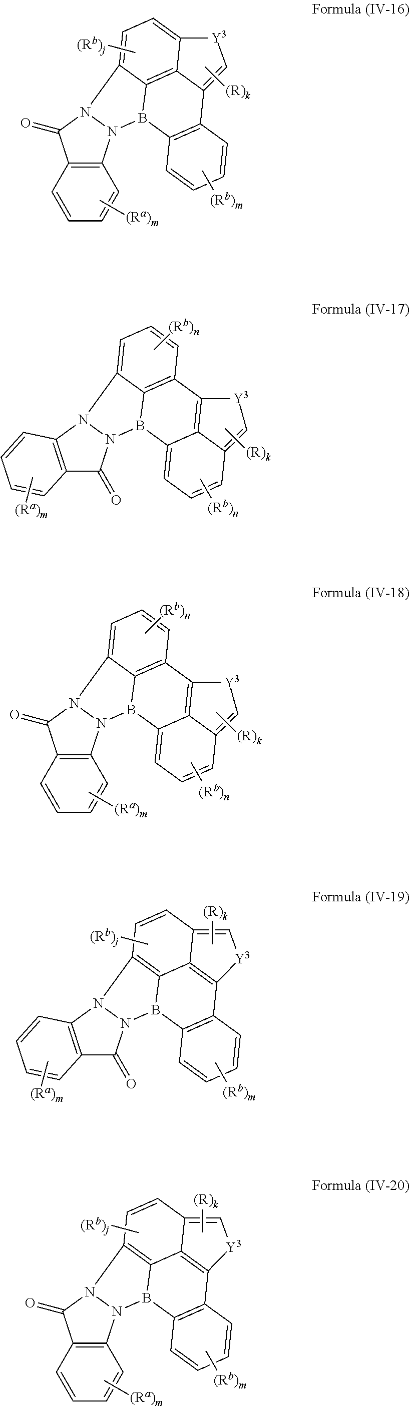 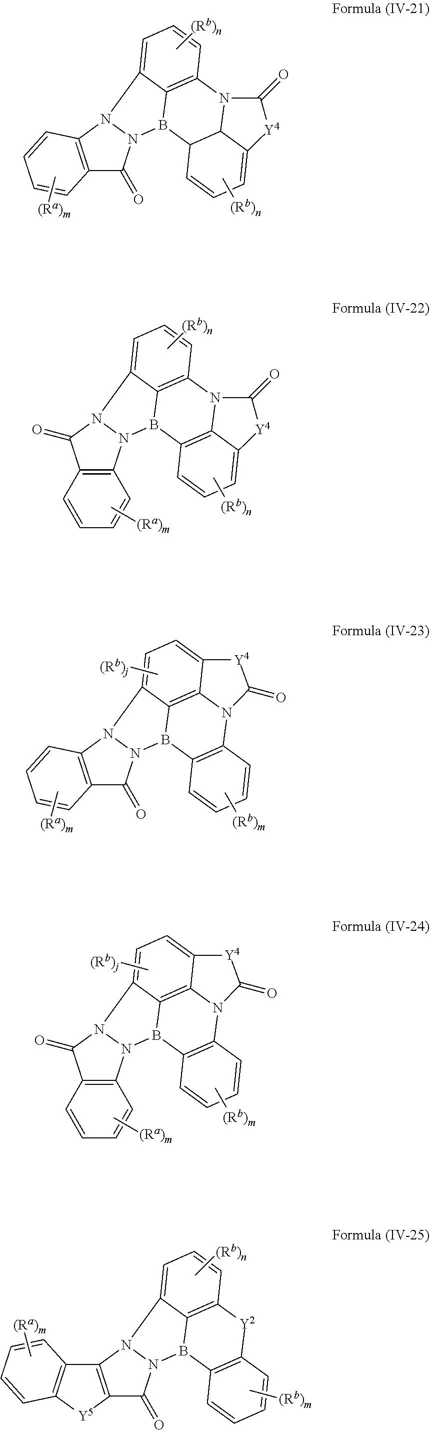 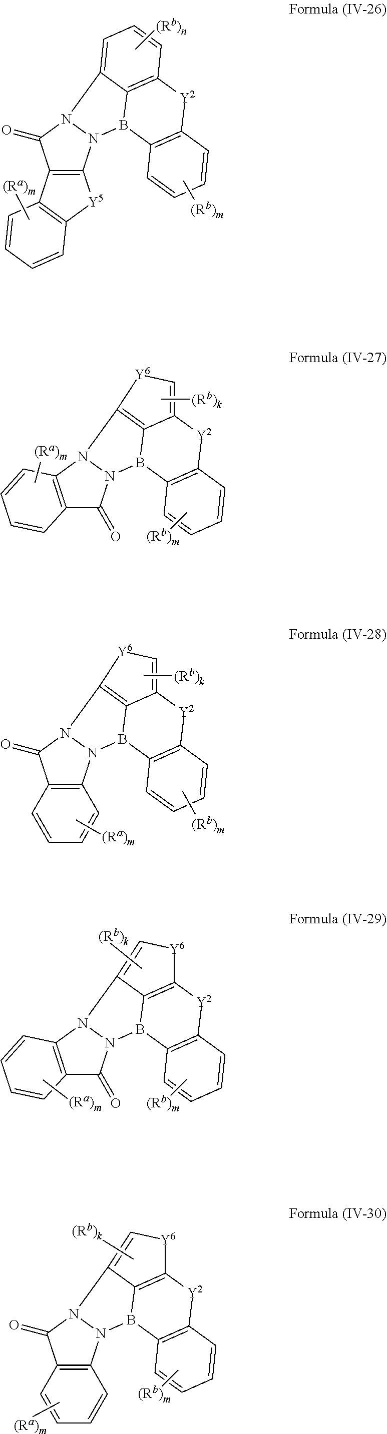 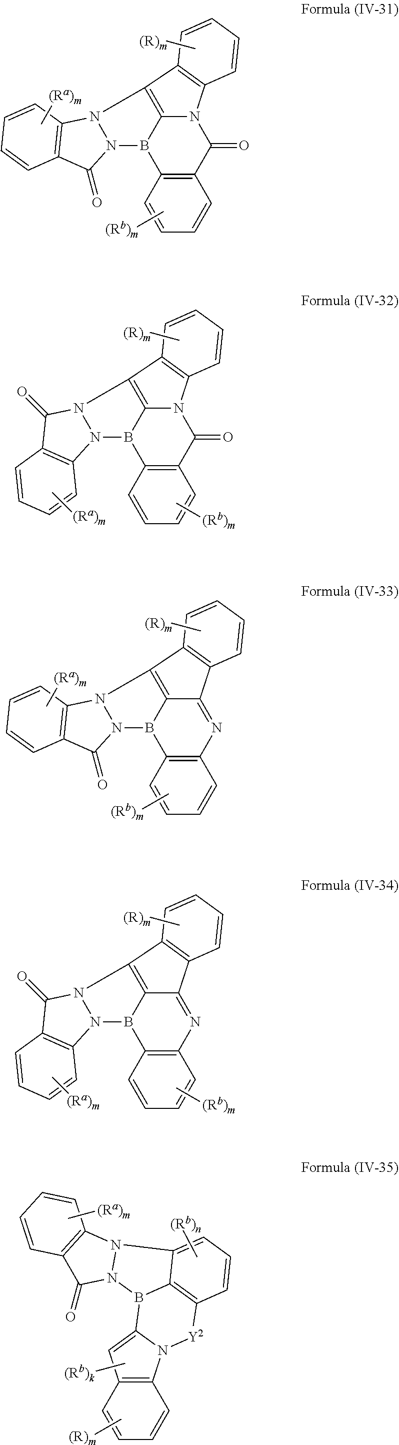 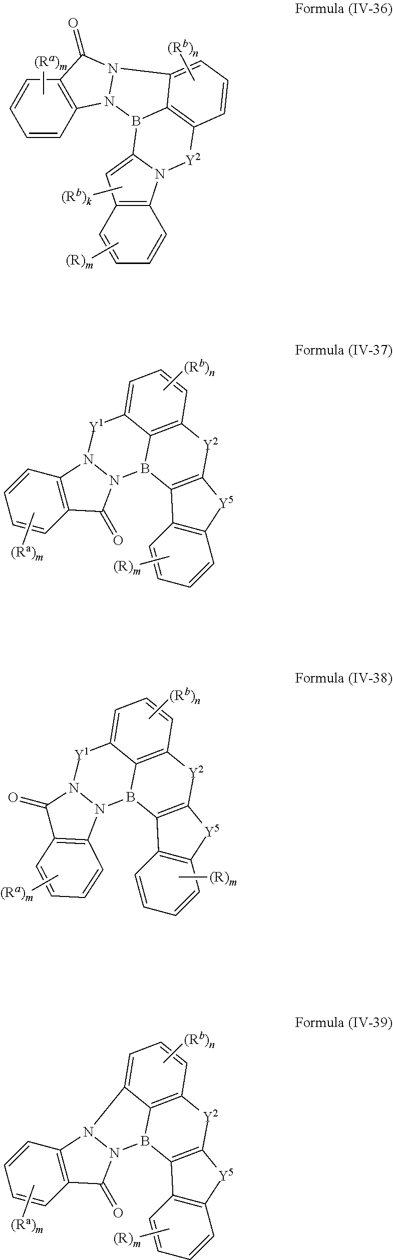 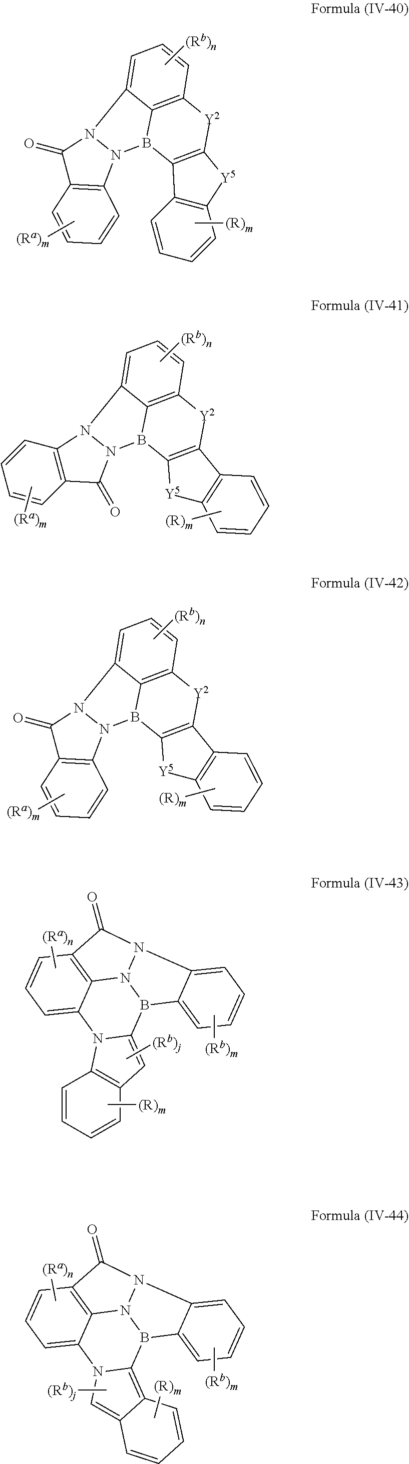 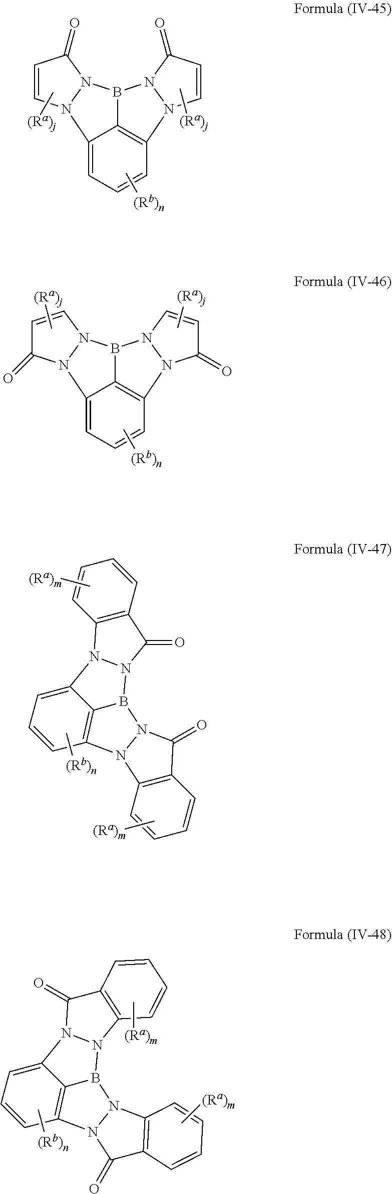
where the symbols R, R^{a} and R^{b} have the definitions given in claim 18, and the further symbols are as follows:
Y¹ is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y² is the same or different at each instance and is a bond, N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y³ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y⁴ is the same or different at each instance and is N(Ar), N(R), P(Ar), P(R), P(═O)Ar, P(═O)R, P(═S)Ar, P(═S)R, C(R)₂, Si(R)₂, O or S, where R has the definition detailed in claim 18;
Y⁵ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
Y⁶ is the same or different at each instance and is N(Ar), N(R), P(Ar), P(R), P(═O)Ar, P(═O)R, P(═S)Ar, P(═S)R, B(Ar), B(R), Al(Ar), Al(R), Ga(Ar), Ga(R), C═O, C(R)₂, Si(R)₂, Ge(R)₂, C═NR, C═NAr, C═C(R)₂, C═C(R)(Ar), O, S, Se, S═O, or SO₂, where R has the definition detailed in claim 18;
m is 0, 1, 2, 3 or 4;
n is 0, 1, 2 or 3;
j is 0, 1 or 2;
k is 0 or 1.

23. A compound as claimed in claim 18, characterized in that the structures/compounds of the formulae (I), (II-1) to (II-18), (III-1) to (III-48) and/or (IV-1) to (IV-48) have not more than one olefinic double bond.

24. A compound as claimed in claim 18, characterized in that at least two R, R^{a}, R^{b} radicals together with the further groups to which the two R, R^{a}, R^{b} radicals bind form a fused ring, where the two R, R^{a}, R^{b} radicals form at least one structure of the formulae (RA-1) to (RA-12): 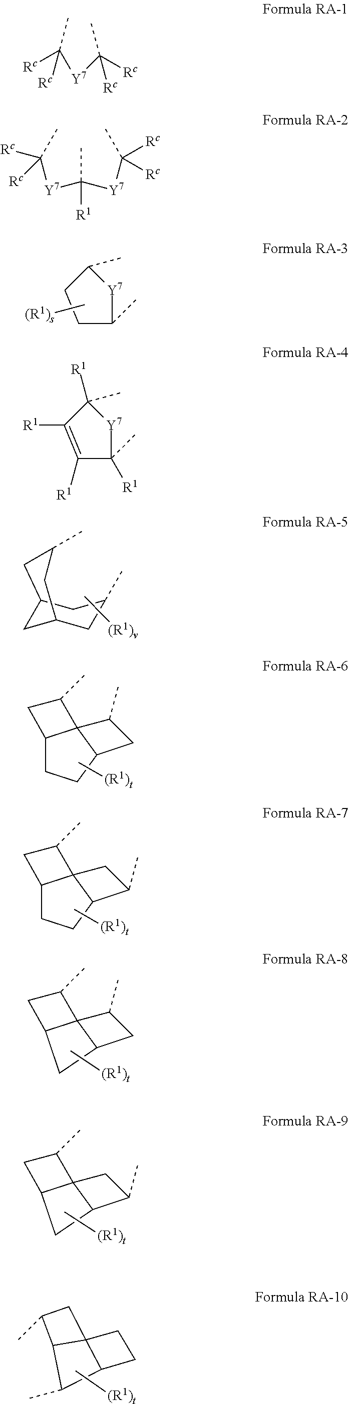 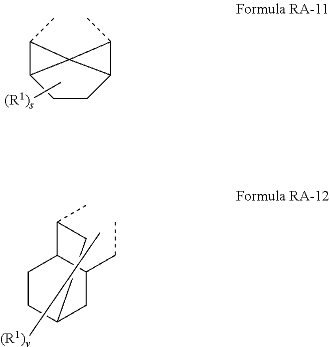
where R¹ has the definition set out above, the dotted bonds represent the sites of attachment to the atoms of the groups to which the two R, R^{a}, R^{b} radicals bind, and the further symbols are defined as follows:
Y⁷ is the same or different at each instance and is C(R¹)₂, (R¹)₂C—C(R¹)₂, (R¹)C═C(R), NR¹, NAr′, O or S;
R^{c} is the same or different at each instance and is F, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 20 carbon atoms, where the alkyl, alkoxy, thioalkoxy, alkenyl or alkynyl group may be substituted in each case by one or more R² radicals, where one or more nonadjacent CH₂ groups may be replaced by R²C═CR², C≡C, Si(R²)₂, C═O, C═S, C═Se, C═NR², —C(═O)O—, —C(═O)NR²—, NR², P(═O)(R¹), —O—, —S—, SO or SO₂, or an aromatic or heteroaromatic ring system which has 5 to 60 aromatic ring atoms and may be substituted in each case by one or more R² radicals, or an aryloxy or heteroaryloxy group which has 5 to 60 aromatic ring atoms and may be substituted by one or more R² radicals; at the same time, it is also possible for two R^{c} radicals together or one R^{c} radical together with an R¹ radical or together with a further group to form a ring system;
s is 0, 1, 2, 3, 4, 5 or 6;
t is 0, 1, 2, 3, 4, 5, 6, 7 or 8;
v is 0, 1, 2, 3, 4, 5, 6, 7, 8 or 9.

25. A compound as claimed in claim 18, characterized in that at least two R, R^{a}, R^{b} radicals together with the further groups to which the two R, R^{a}, R^{b} radicals bind form a fused ring, where the two R, R^{a}, R^{b} radicals of the form structures of the formula (RB): 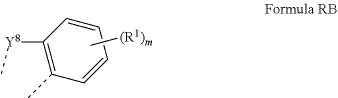
where R¹ has the definition detailed in claim 18, the dotted bonds represent the sites of attachment via which the two R, R^{a}, R^{b}, R^{c}, R^{d} radicals bind to the further groups, the index m is 0, 1, 2, 3 or 4 and Y⁸ is C(R¹)₂, NR¹, NAr′, BR¹, BAr′, O or S.

26. A compound as claimed in claim 18, comprising at least one structure of the formulae (V-1) to (V-12), where the compounds have at least one fused ring, 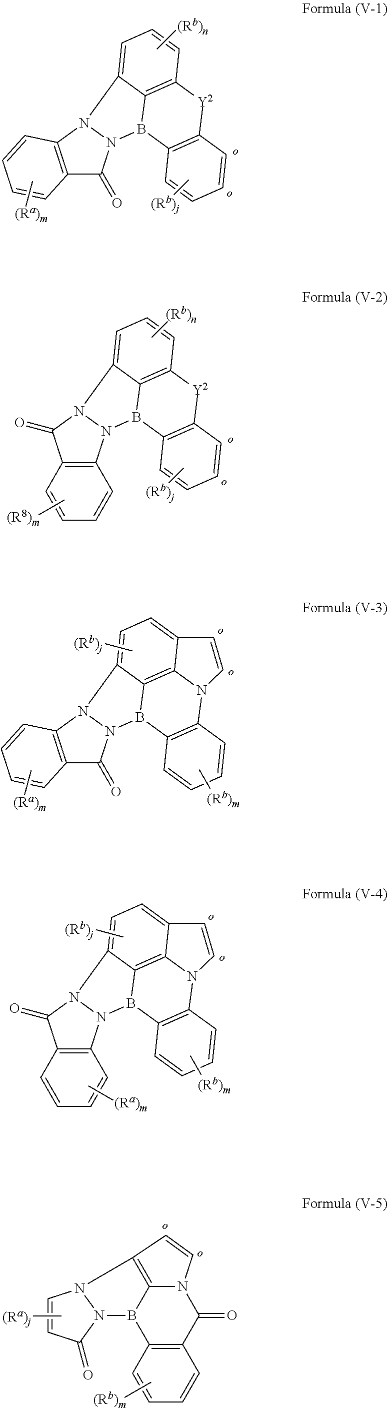 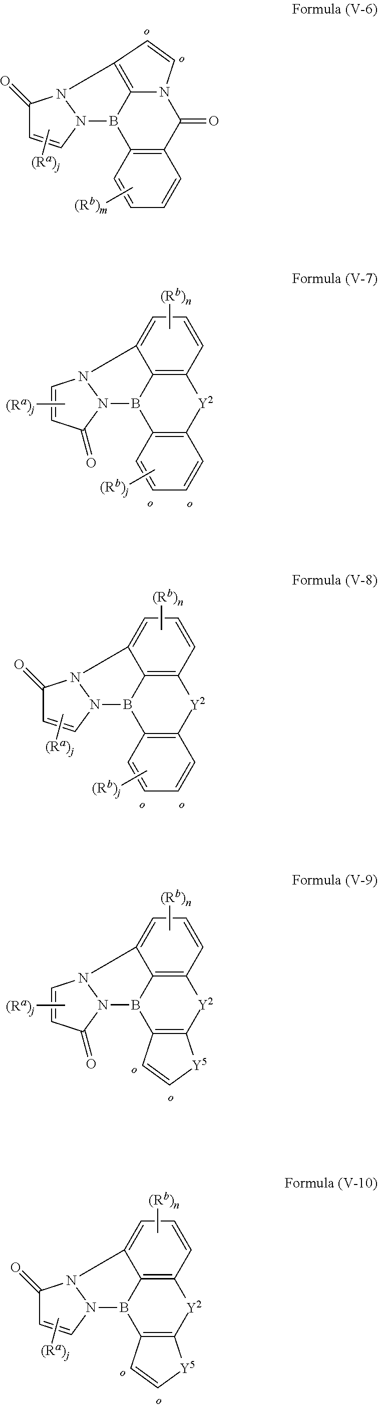 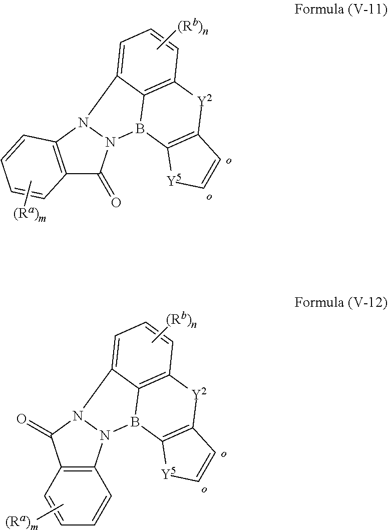
where the symbols R^{a}, R^{b}, Y¹, Y² and Y⁵ have the definitions given in claim 18, the symbol o represents the sites of attachment, and the further symbols have the following definition:
m is 0, 1, 2, 3 or 4;
n is 0, 1, 2 or 3;
j is 0, 1 or 2.

27. A compound as claimed in claim 18, characterized in that at least one substituent R, R^{a}, R^{b} is the same or different at each instance and is selected from the group consisting of H, D, a branched or cyclic alkyl, alkoxy or thioalkoxy group having 3 to 20 carbon atoms or an aromatic or heteroaromatic ring system selected from the groups of the following formulae Ar-1 to Ar-78: 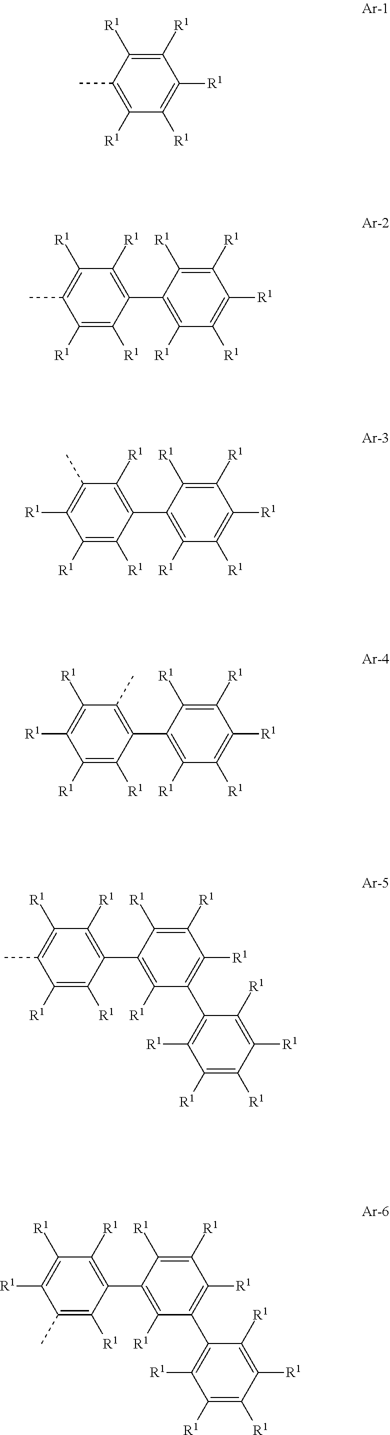 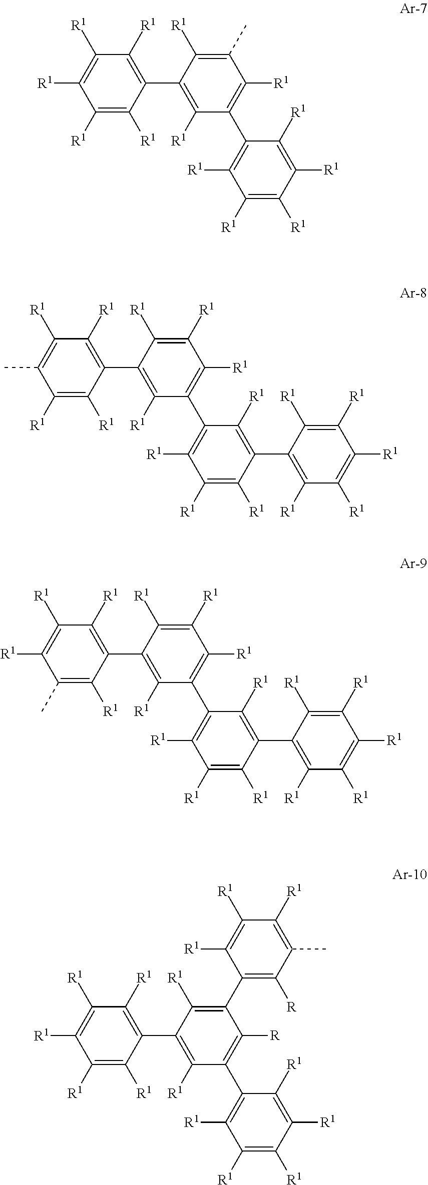 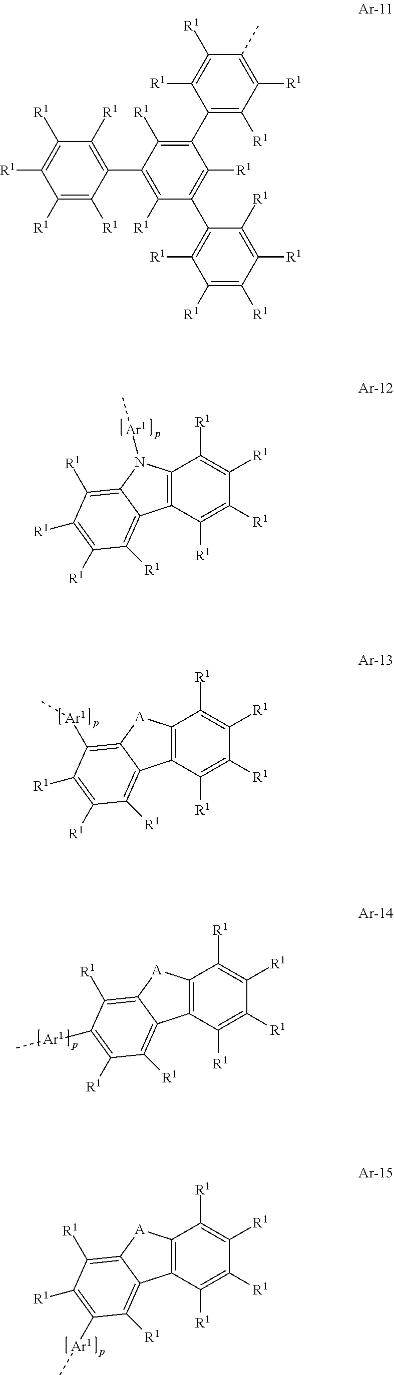 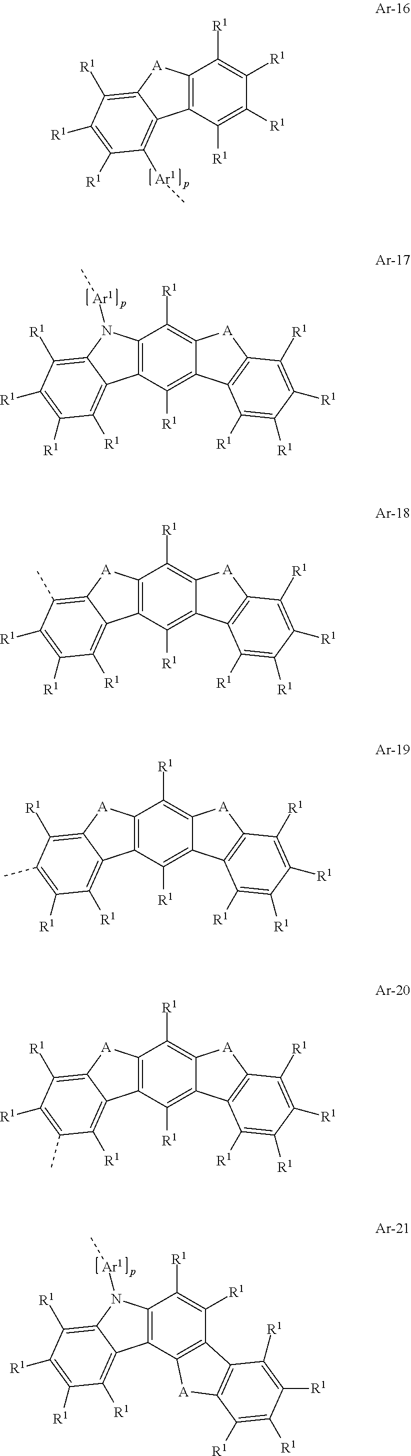 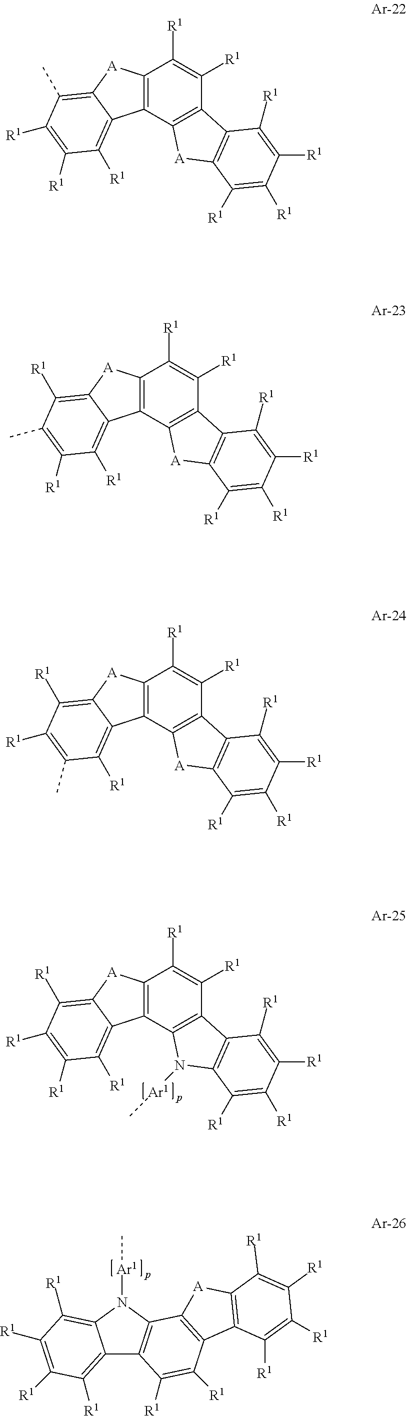 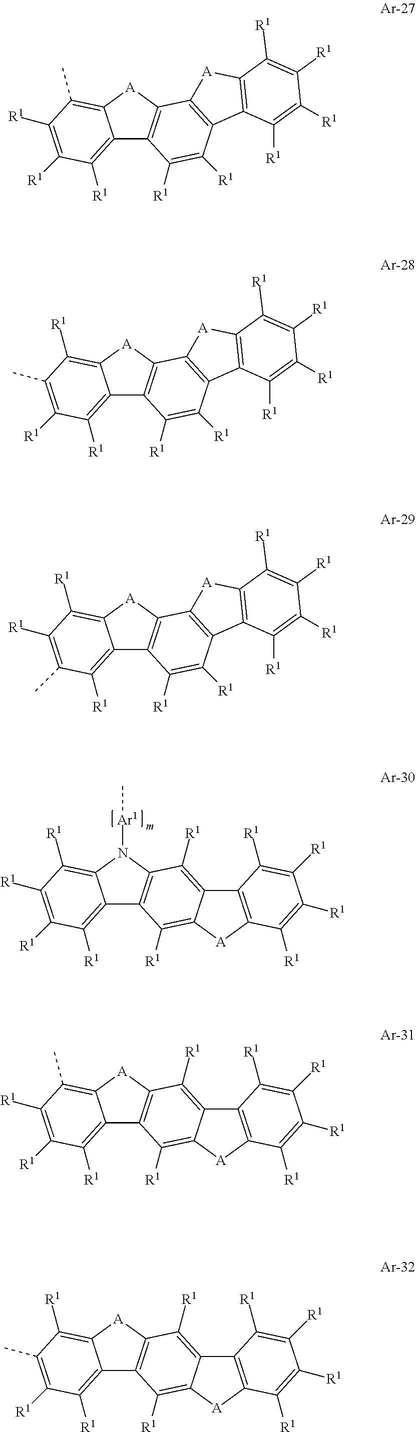 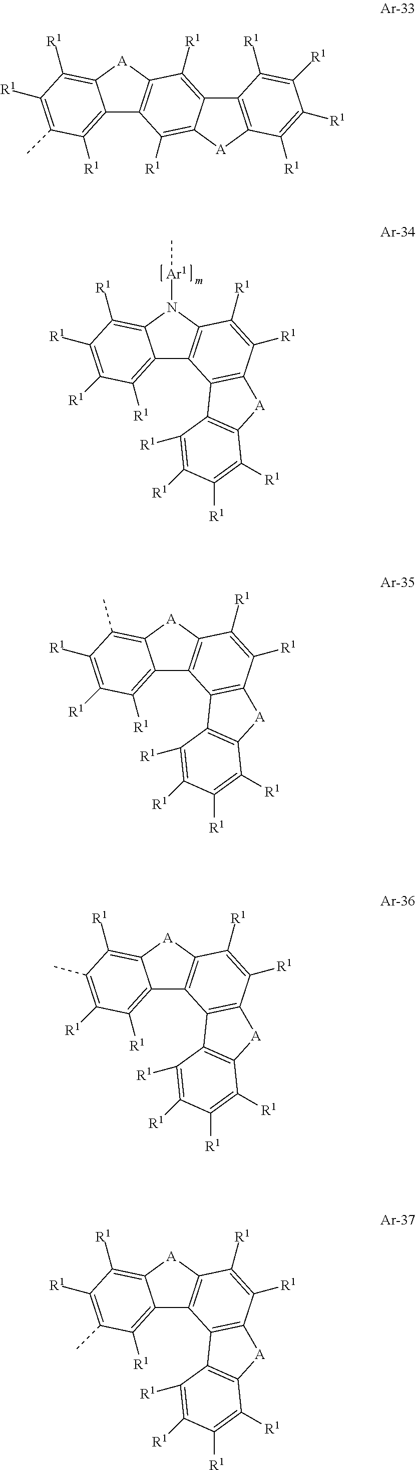 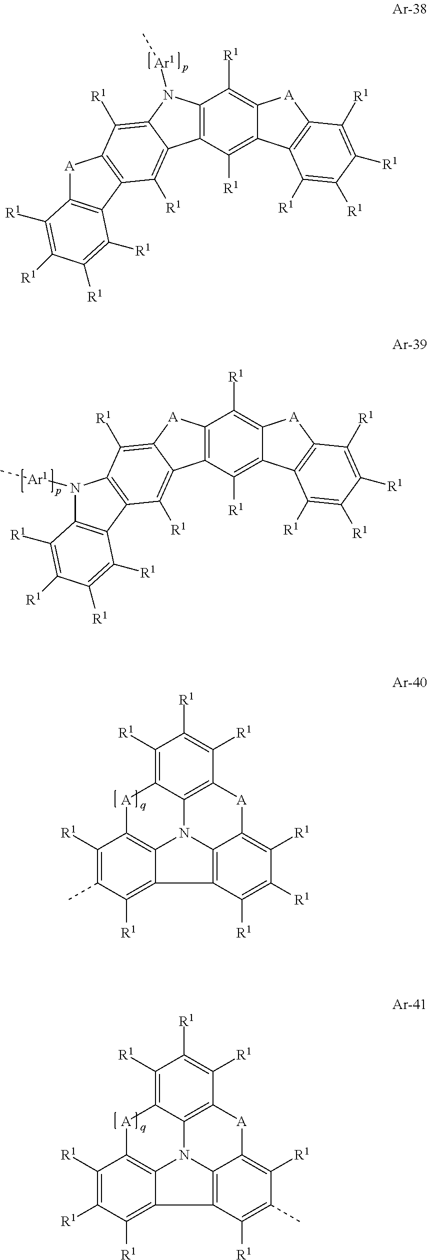 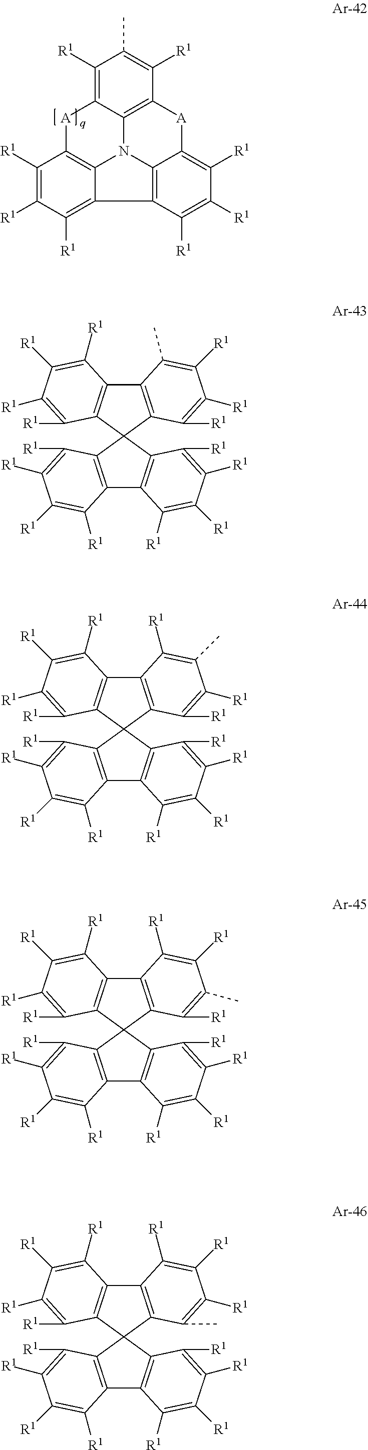 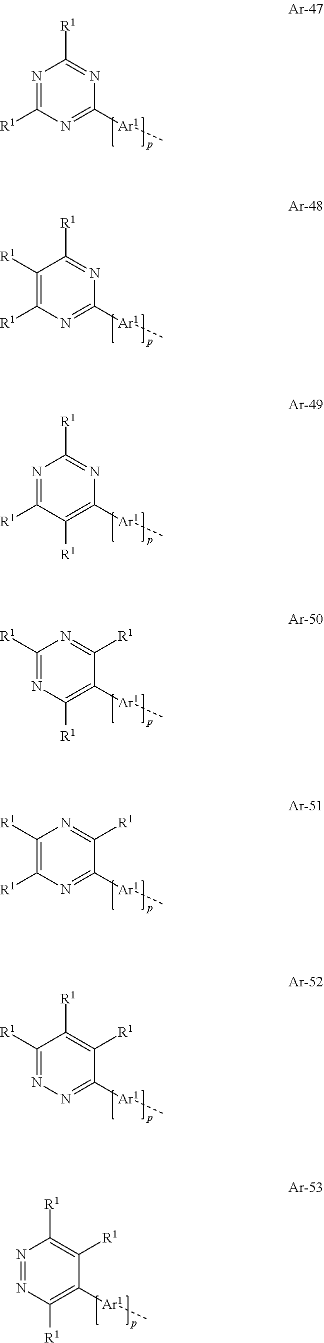 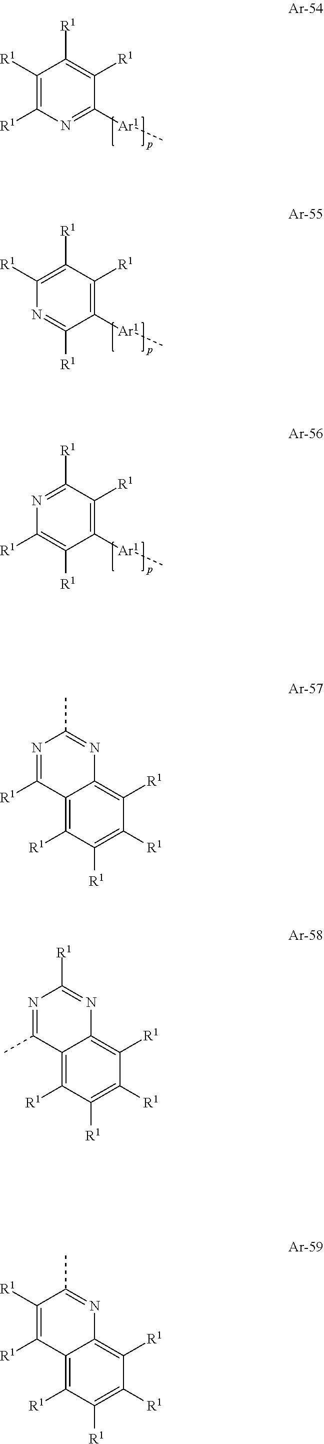 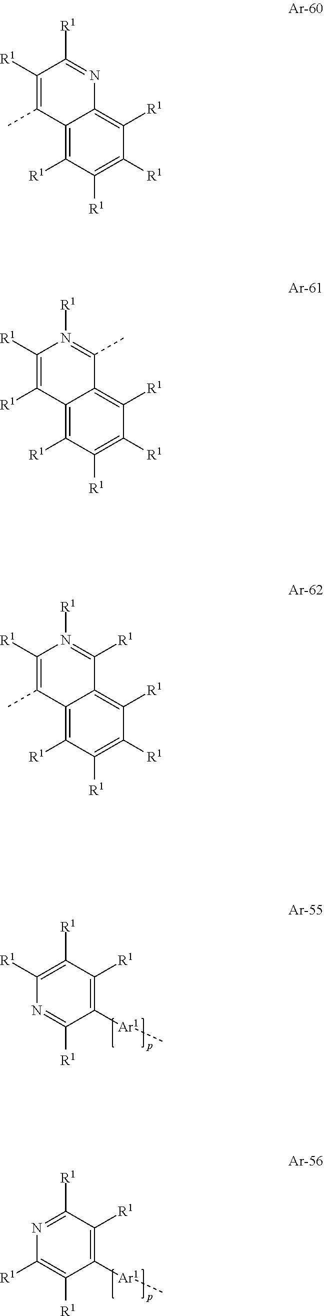 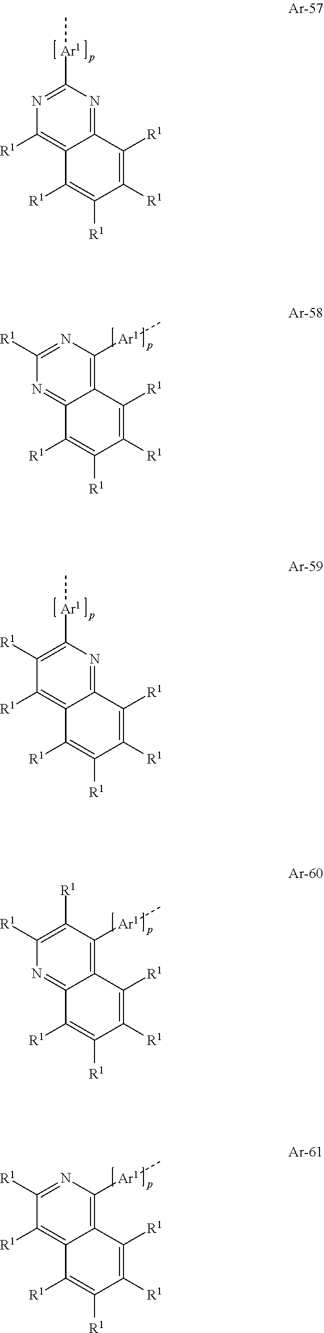 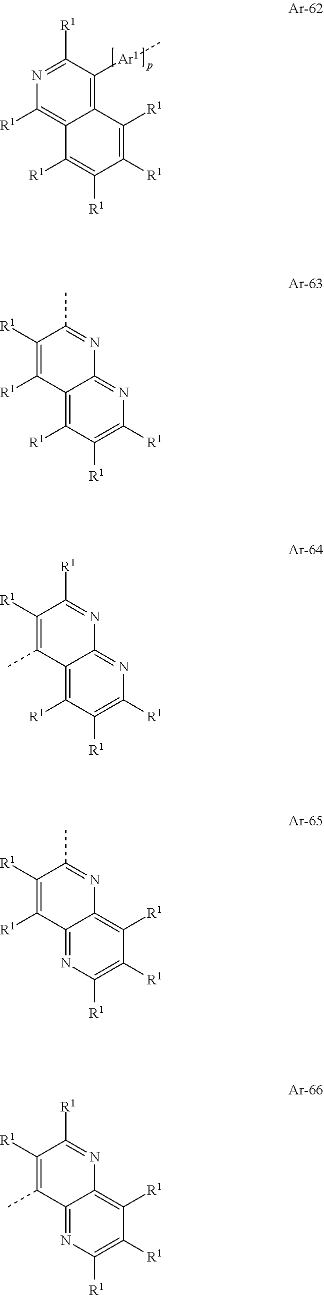 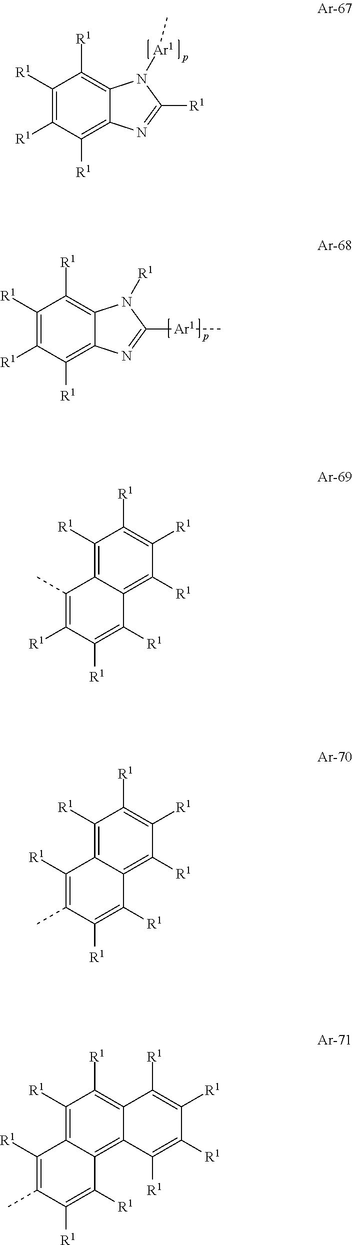 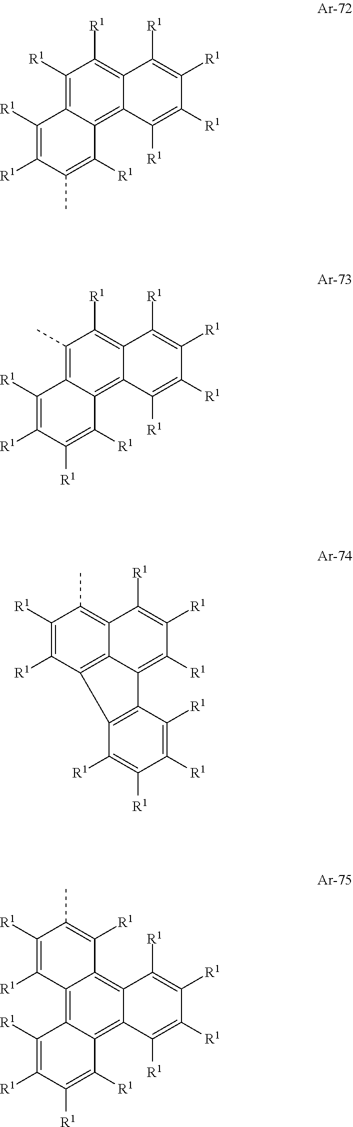 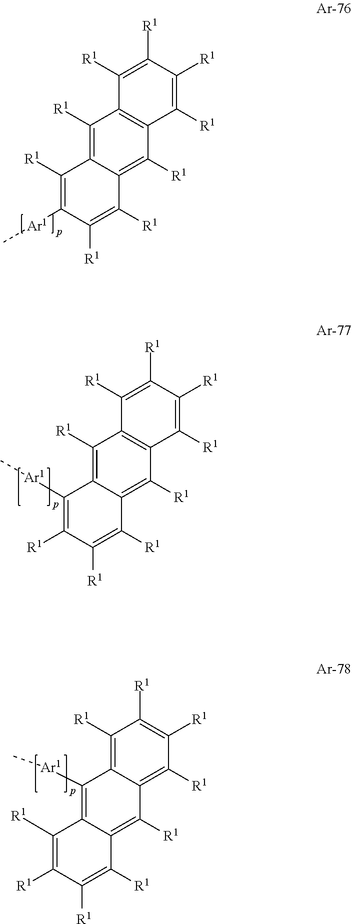
where R¹ has the definitions given above, the dotted bond represents the bond to the corresponding group and in addition:
Ar¹ is the same or different at each instance and is a bivalent aromatic or heteroaromatic ring system which has 6 to 18 aromatic ring atoms and may be substituted in each case by one or more R¹ radicals;
A is the same or different at each instance and is C(R¹)₂, NR¹, O or S;
p is 0 or 1, where p=0 means that the Ar¹ group is absent and that the corresponding aromatic or heteroaromatic group is bonded directly to the corresponding radical;
q is 0 or 1, where q=0 means that no A group is bonded at this position and R¹ radicals are bonded to the corresponding carbon atoms instead.

28. A compound as claimed in claim 18, characterized in that the compound includes exactly two or exactly three structures of formula (I), (II-1) to (II-18), (III-1) to (III-48), (IV-1) to (IV-48) and/or (V-1) to (V-12).

29. An oligomer, polymer or dendrimer containing one or more compounds as claimed in claim 18, wherein, in place of a hydrogen atom or a substituent, there are one or more bonds of the compounds to the polymer, oligomer or dendrimer.

30. A formulation comprising at least one compound as claimed in claim 18 and at least one further compound, where the further compound is selected from one or more solvents.

31. A composition comprising at least one compound as claimed in claim 18 and at least one further compound selected from the group consisting of fluorescent emitters, phosphorescent emitters, emitters that exhibit TADF, host materials, electron transport materials, electron injection materials, hole conductor materials, hole injection materials, electron blocker materials and hole blocker materials.

32. A process for preparing a compound as claimed in claim 18, characterized in that a base skeleton having at least one of the W^{a} groups or a precursor of one of the W^{a} groups is synthesized, and an aromatic or heteroaromatic radical is introduced by means of a nucleophilic aromatic substitution reaction or a coupling reaction.

33. A method for making an electronic device comprising the use of a compound as claimed in claim 18.

34. An electronic device comprising at least one compound as claimed in claim 18.
